(19) United States
(12) Patent Application Publication
(10) Pub. No.: US 2010/0151380 A1
(43) Pub. Date: Jun. 17, 2010

(54) RESIST COMPOSITION

(75) Inventors: Nobuo ANDO, Osaka (JP); Ichiki TAKEMOTO, Kawanishi-shi (JP)

Correspondence Address: BIRCH STEWART KOLASCH & BIRCH, PO BOX 747, FALLS CHURCH, VA, 22040-0747, US

(73) Assignee: SUMITOMO CHEMICAL COMPANY, LIMITED, Tokyo (JP)

(21) Appl. No.: 12/633,285

(22) Filed: Dec. 8, 2009

(30) Foreign Application Priority Data
Dec. 11, 2008 (JP) 2008-315990
Feb. 9, 2009 (JP) 2009-026980

(51) Int. Cl. G03F 7/004

(52) U.S. Cl. 430/270.1

(57) ABSTRACT

A resist composition comprising:
(A) a resin being insoluble or poorly soluble in an alkali aqueous solution but becoming soluble in an alkali aqueous solution by the action of an acid,
(B) a polyhydric phenol compound represented by the formula (1):

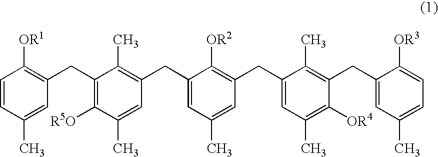

wherein at least one selected from the group consisting of R¹, R², R³, R⁴, and R⁵ is a group represented by the formula (2):

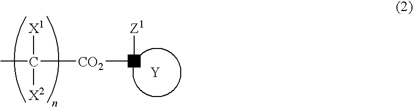

wherein X¹ and X² each independently represent a hydrogen atom etc., n represents an integer of 1 to 4, Z¹ represents a C1-C6 alkyl group etc., and ring Y represents an alicyclic hydrocarbon group,
and the others are hydrogen atoms, and
(C) an acid generator.

This nonprovisional application claims priority under 35 U.S.C. §119(a) on Patent Application No. 2008-315990 filed in JAPAN on Dec. 11, 2008 and on Patent Application No. 2009-026980 filed in JAPAN on Feb. 9, 2009, the entire contents of which are hereby incorporated by reference.

### FIELD OF THE INVENTION

The present invention relates to a resist composition.

### BACKGROUND OF THE INVENTION

A resist composition used for semiconductor microfabrication employing a lithography process contains a resin having an acid-labile group and an acid generator.

In semiconductor microfabrication, it is desirable to form patterns having high sensitivity and high resolution and good pattern profile such as shape of the pattern, and it is expected for a chemically amplified resist composition to give such patterns.

US 2003/0099900 A1 discloses a resist composition comprising a resin having a structural unit derived from 2-ethyl-2-adamantyl methacrylate and a structural unit derived from p-hydroxystyrene, and an acid generator. JP 2005-274877 A also discloses a resist composition for EUV lithography comprising a resin having a structural unit derived from 2-ethyl-2-adamantyl methacrylate and a structural unit derived from p-hydroxystyrene, and an acid generator.

U.S. Pat. No. 7,494,763 B2 discloses a polyhydric phenol compound and a chemically amplified resist composition containing the same.

### SUMMARY OF THE INVENTION

The present invention is to provide a resist composition.

The resent invention relates to the followings:

<1> A resist composition comprising:
(A) a resin being insoluble or poorly soluble in an alkali aqueous solution but becoming soluble in an alkali aqueous solution by the action of an acid,
(B) a polyhydric phenol compound represented by the formula (1):

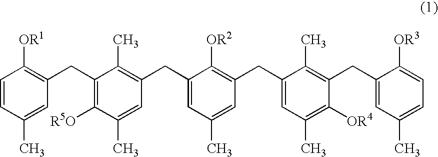

wherein at least one selected from the group consisting of R¹, R², R³, R⁴, and R⁵ is a group represented by the formula (2):

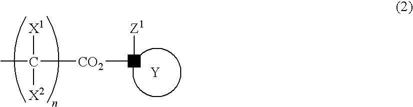

wherein X¹ and X² each independently represent a hydrogen atom or a C1-C4 alkyl group, n represents an integer of 1 to 4, Z¹ represents a C1-C6 alkyl group or a C3-C12 cycloalkyl group, and ring Y represents an alicyclic hydrocarbon group,
   and the others are hydrogen atoms, and
   (C) an acid generator;
   <2> The resist composition according to <1>, wherein X¹ and X² represent hydrogen atoms and n is 1 in the formula (2);
   <3> The resist composition according to <1> or <2>, wherein a weight ratio of the resin (A) to the polyhydric phenol compound represented by the formula (1) (the resin (A)/the polyhydric phenol compound represented by the formula (1)) is 1/99 to 99/1;
   <4> The resist composition according to <1> or <2>, wherein a weight ratio of the resin (A) to the polyhydric phenol compound represented by the formula (1) (the resin (A)/the polyhydric phenol compound represented by the formula (1)) is 1/9 to 50/1;
   <5> The resist composition according to <1> or <2>, wherein a weight ratio of the resin (A) to the polyhydric phenol compound represented by the formula (1) (the resin (A)/the polyhydric phenol compound represented by the formula (1)) is 1/1 to 9/1;
   <6> The resist composition according to any one of <1> to <5>, wherein the resin (A) is a resin (A1) comprising a structural unit having an acid-labile group in its side chain and a structural unit represented by the formula (I):

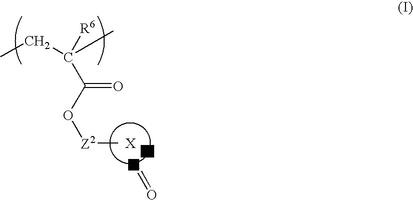

wherein R⁶ represents a hydrogen atom or a methyl group, Z² represents a single bond or —(CH₂)ₖ—CO—O—, k represents an integer of 1 to 4, and ring X represents an unsubstituted or substituted C3-C30 cyclic hydrocarbon group having —COO—;
<7> The resist composition according to any one of <1> to <5>, wherein the resin (A) is a resin (A2) comprising a structural unit having an acid-labile group in its side chain and a structural unit represented by the formula (III):

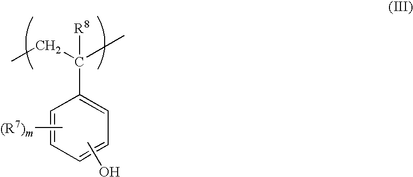

wherein R⁸ represents a hydrogen atom or a methyl group, R⁷ is independently in each occurrence a linear or branched chain C1-C6 alkyl group and m represents an integer of 0 to 4;
<8> The resist composition according to any one of <1> to <5>, wherein the resin (A) contains the resin (A1) and the resin (A2);
<9> The resist composition according to <8>, wherein the weight ratio of the resin (A1) to the resin (A2) (the resin (A1)/the resin (A2)) is 1/10 to 10/1;
<10> The resist composition according to <8>, wherein the weight ratio of the resin (A1) to the resin (A2) (the resin (A1)/the resin (A2)) is 1/3 to 3/1;
<11> The resist composition according to any one of <1> to <10>, wherein the molecular weight of the polyhydric phenol compound represented by the formula (I) is 730 to 5000;
<12> The resist composition according to any one of <1> to <11>, wherein the composition contains at least two kinds of the polyhydric phenol compound represented by the formula (I);
<13> The resist composition according to any one of <1> to <12>, wherein the composition further contains a compound represented by the formula (3):

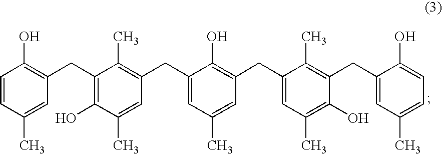

<14> The resist composition according to any one of <1> to <13>, wherein the acid generator is a salt represented by the formula (V):

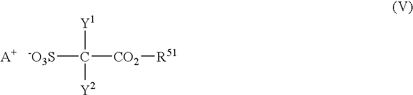

wherein A⁺ represents an organic counter ion, Y¹ and Y² each independently represent a fluorine atom or a C1-C6 perfluoroalkyl group, R⁵¹ represents a C1-C30 hydrocarbon group which may have one or more substituents selected from the group consisting of a C1-C6 alkoxy group, a C1-C4 perfluoroalkyl group, a C1-C6 hydroxyalkyl group, a hydroxyl group and a cyano group, and in which one or more —CH₂— may be replace by —CO— or —O—;
<15> Use of the resist composition according to any one of <1> to <14> for extreme ultraviolet lithography or electron beam lithography.

### DESCRIPTION OF PREFERRED EMBODIMENTS

The resist composition of the present invention comprises

(A) a resin being insoluble or poorly soluble in an alkali aqueous solution but becoming soluble in an alkali aqueous solution by the action of an acid (hereinafter, simply referred to as the resin (A)),
(B) a polyhydric phenol compound represented by the formula (1):

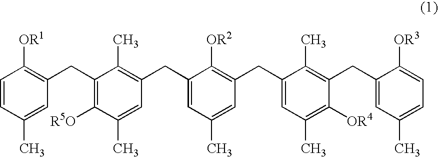

wherein at least one selected from the group consisting of R¹, R², R³, R⁴, and R⁵ is a group represented by the formula (2):

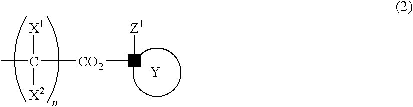

wherein X¹ and X² each independently represent a hydrogen atom or a C1-C4 alkyl group, n represents an integer of 1 to 4, Z¹ represents a C1-C6 alkyl group or a C3-C12 cycloalkyl group, and ring Y represents an alicyclic hydrocarbon group,
   and the others are hydrogen atoms (hereinafter, simply referred to as the polyhydric phenol compound (1)), and
   (C) an acid generator.

The resin (A) itself is insoluble or poorly soluble in an alkali aqueous solution but becomes soluble in an alkali aqueous solution by the action of an acid.

The resin (A) contains a structural unit having an acid-labile group in its side chain.

The resin (A) may have two or more kinds of the structural unit having an acid-labile group in its side chain.

In the present specification, “acid-labile group” means a group cleaved by contacting with an acid to be converted to a hydrophilic group such as a hydroxyl group and a carboxyl group.

Examples of the acid-labile group include a group represented by the formula (10):

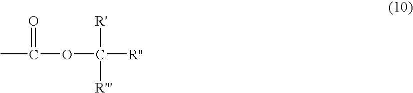

wherein R′, R″ and R′″ each independently represents a linear or branched chain C1-C30 aliphatic hydrocarbon group and R′ and R″ may be bonded to form a ring (hereinafter, simply referred to as the acid-labile group (10)) . Examples of the acid-labile group (10) include a 1,1-dialkylalkoxycarbonyl group such as a tert-butoxycarbonyl group; a 2-alkyl-2-adamantyloxycarbonyl group such as a 2-methyl-2-adamantyloxycarbonyl group, a 2-ethyl-2-adamantyloxycarbonyl group and a 2-isopropyl-2-adamantyloxycarbonyl group; a 1-alkylcycloalkoxycarbonyl group such as a 1-ethylcyclohexyloxycarbonyl group; and a 1-(1-adamantyl)-1-alkylalkoxycarbonyl group.

The structural units having an acid-labile group is derived from a monomer having a carbon-carbon double bond and an acid-labile group, and preferable examples of the monomer include an acrylate having an acid-labile group and a methacrylate having an acid-labile group. The monomer having an acid-labile group containing a C5-C20 alicyclic hydrocarbon group is preferable because excellent resolution is obtained when the resin obtained is used in the present composition. Examples of the C5-C20 alicyclic hydrocarbon group include a monocyclic saturated aliphatic hydrocarbon group having a cycloalkane ring such as a cyclopentane ring, a cyclohexane ring, a cycloheptane ring and a cyclooctane ring; and a polycyclic aliphatic hydrocarbon group having a bridged hydrocarbon ring such as an adamantane ring and a norbornane ring.

Examples of the structural unit having an acid-labile group in its side chain include structural units represented by the formulae (IIa) and (IIb):

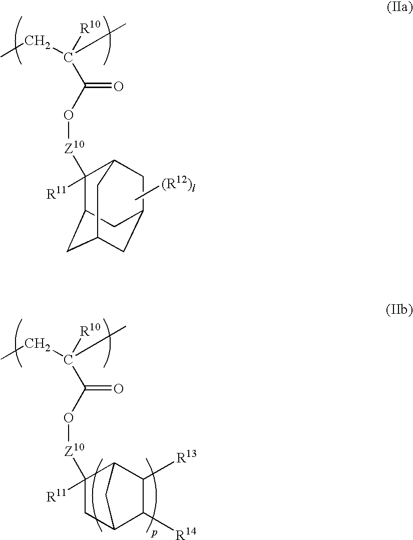

wherein R¹⁰ represents a hydrogen atom or a methyl group, Z¹⁰ represents a single bond or —[CH₂]ᵣ—CO—O—, r represents an integer of 1 to 4, R¹¹ represents a C1-C8 linear or branched chain alkyl group or a C3-C8 cycloalkyl group, R¹² represents a methyl group, 1 represents an integer of 0 to 14, R¹³ and R¹⁴ each independently represent a hydrogen atom or a C1-C8 monovalent hydrocarbon group which may have one or more heteroatoms, or R¹³ and R¹⁴ may be bonded to form a C1-C8 divalent hydrocarbon group which may have one or more heteroatoms and which forms a ring together with the adjacent carbon and R¹⁴ are bonded, or R¹³ and R¹⁴ may be bonded to form a carbon-carbon double bond between the carbon atom to which R¹³ is bonded and the carbon atom to which R¹⁴ is bonded, and p represents an integer of 1 to 3.

In the formulae (IIa) and (IIb), R¹¹ is preferably a C1-C6 linear or branched chain alkyl group or a C3-C6 cycloalkyl group and more preferably a C1-C6 linear or branched chain alkyl group.

Examples of the C1-C8 linear or branched chain alkyl group include a methyl group, an ethyl group, a propyl group, an isopropyl group, a butyl group, an isobutyl group, a sec-butyl group, a pentyl group, an isopentyl group, a neopentyl group, a hexyl group, a heptyl group and an octyl group. Examples of the C3-C8 cycloalkyl group include a cyclopentyl group, a cyclohexyl group, a cyclooctyl group, a 2-methylcyclopentyl group, a 3-methylcyclohexyl group, a 4-methylcyclohexyl group, a 2,3-dimethylcyclohexyl group and a 4,4-dimethylcyclohexyl group.

In the formulae (IIa) and (IIb), Z¹⁰ is preferably a single bond or —CH₂—COO—, and more preferably represents a single bond.

In the formula (IIa), l is preferably 0 or 1. In the formula (IIb), p is preferably 1 or 2.

Examples of the C1-C8 monovalent hydrocarbon group include a methyl group, an ethyl group, a propyl group, an isopropyl group, a butyl group, an isobutyl group, a sec-butyl group, a pentyl group, a hexyl group, a heptyl group and an octyl group. Examples of the C1-C8 divalent hydrocarbon group formed by bonding R¹³ and R¹⁴ include an ethylene group and a trimethylene group.

Examples of the monomer giving the structural unit represented by the formula (IIa) include the followings:

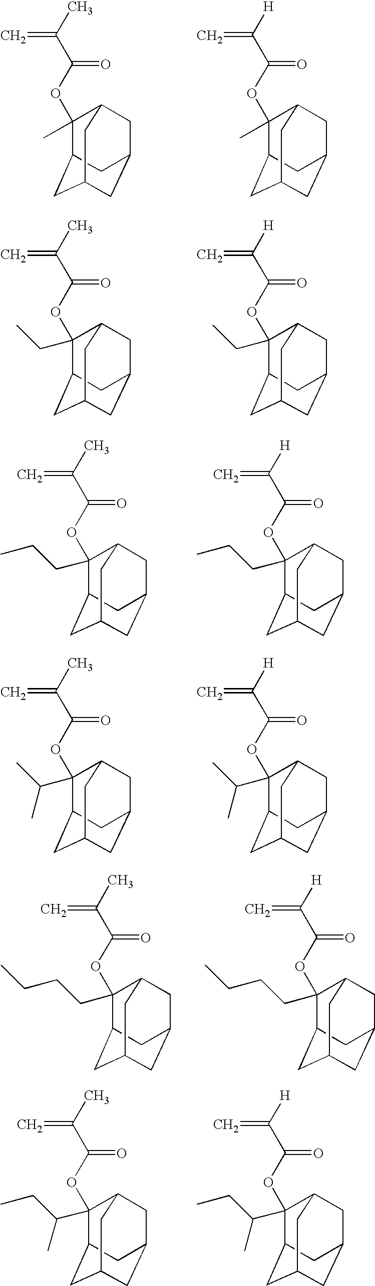

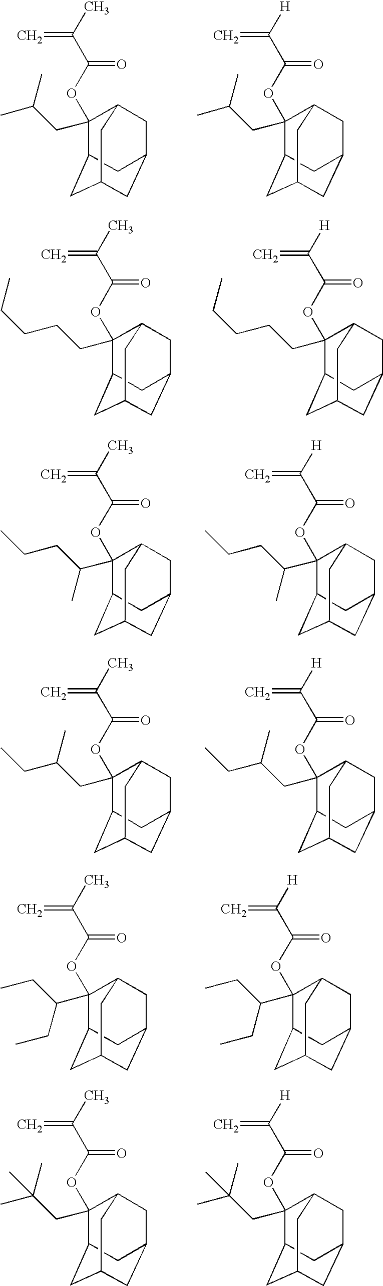

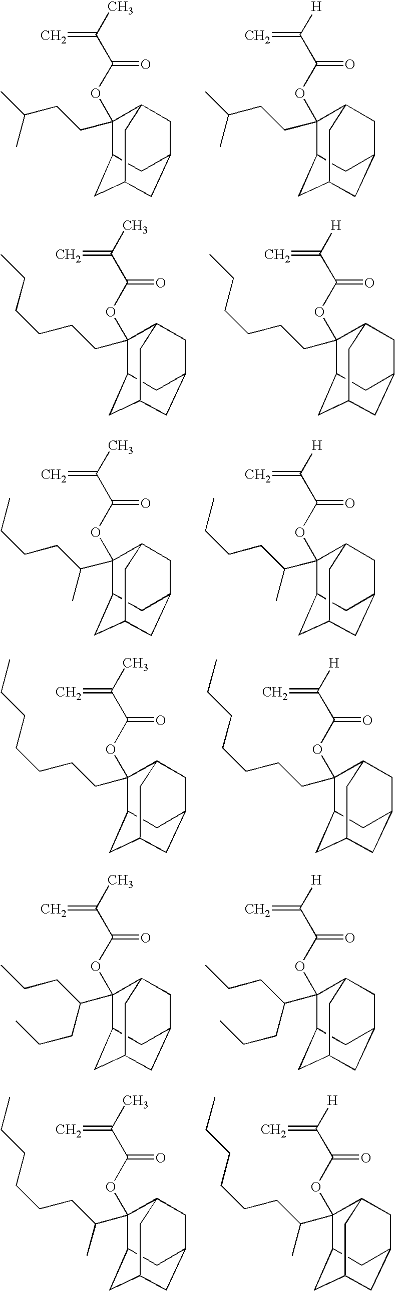

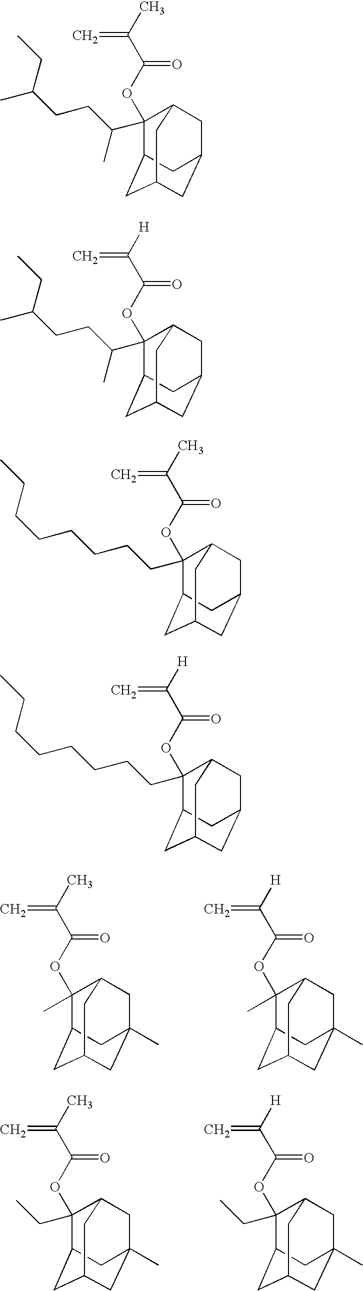

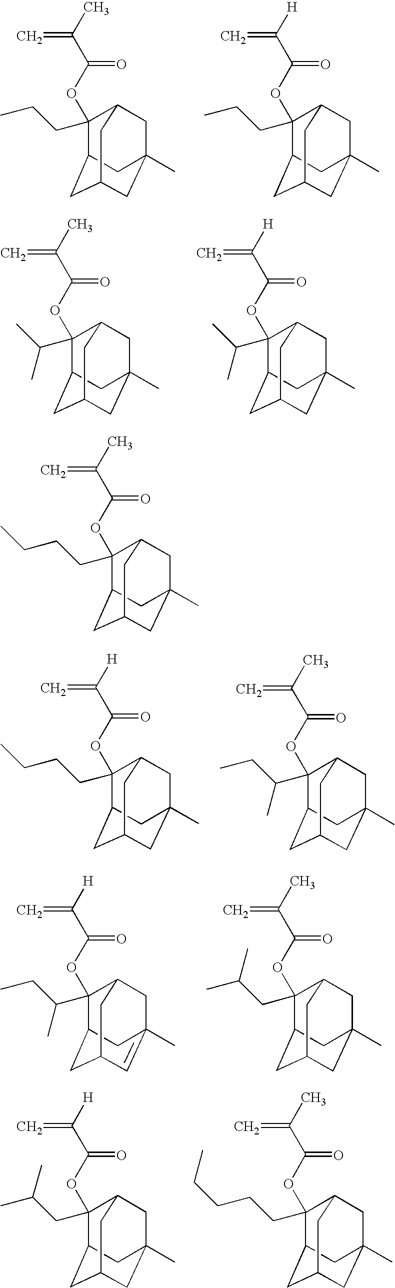

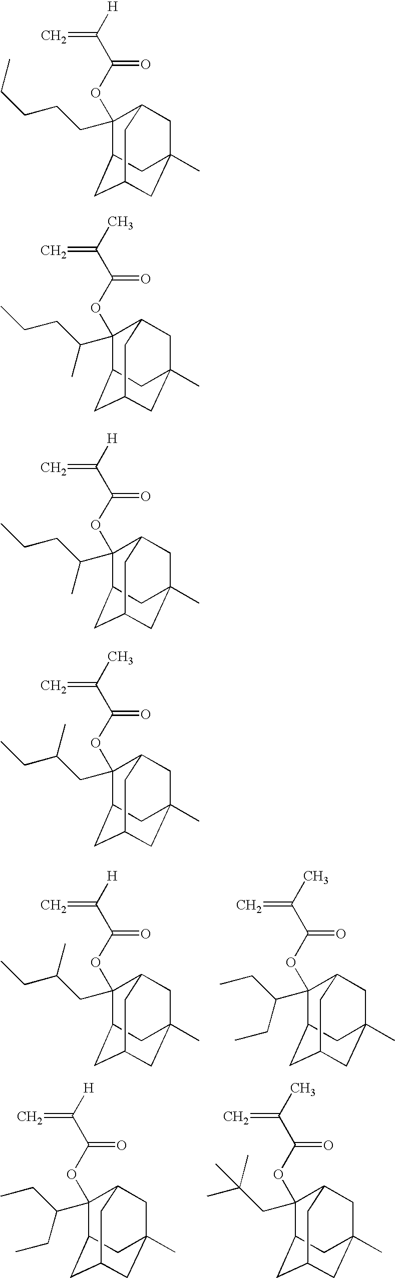

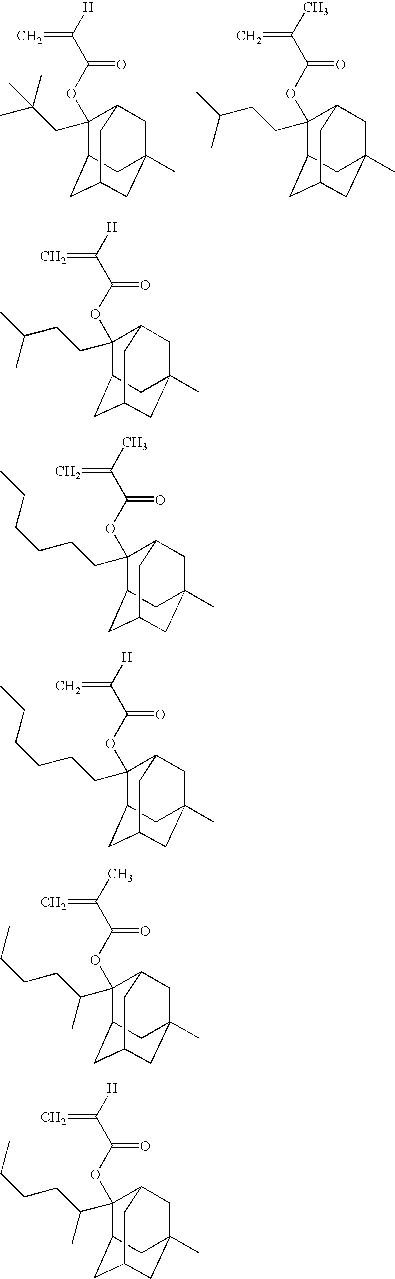

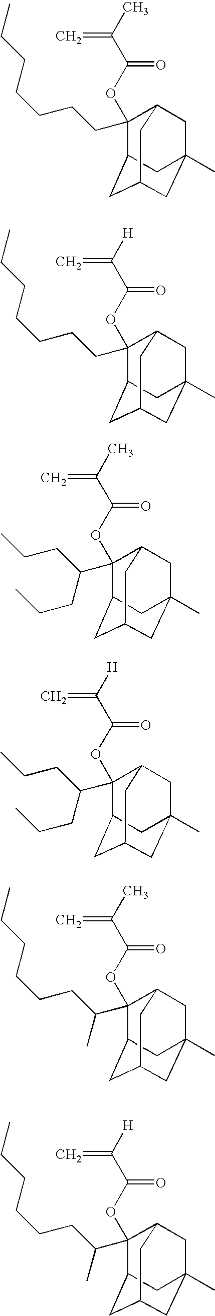

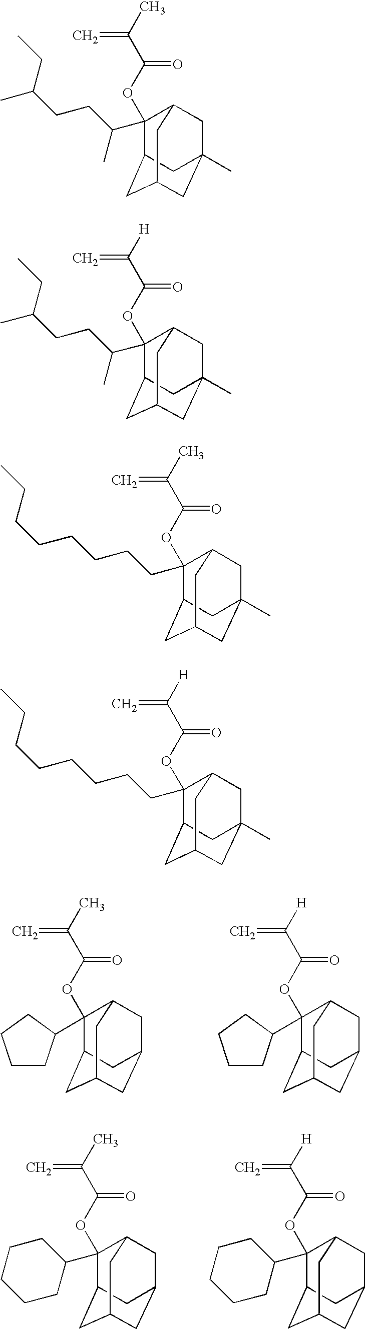

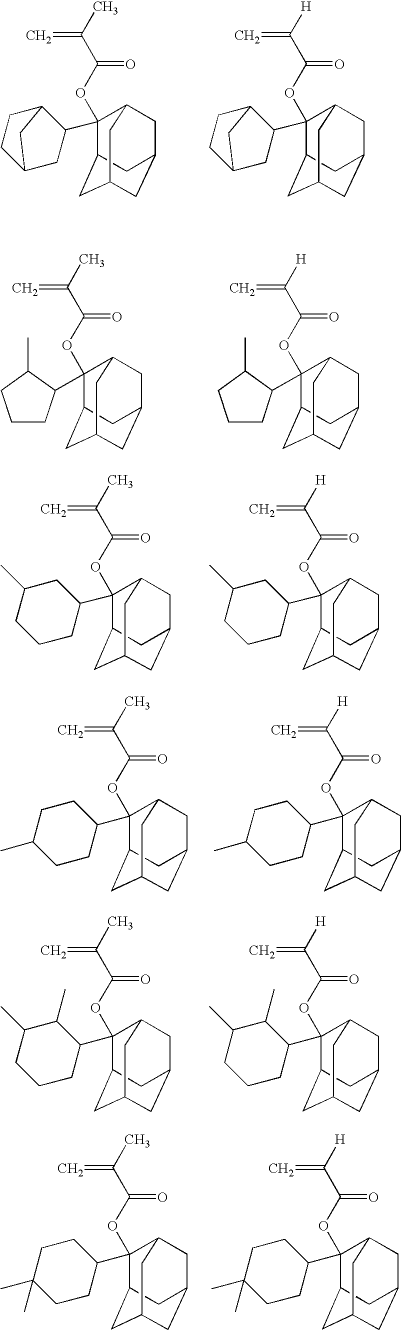

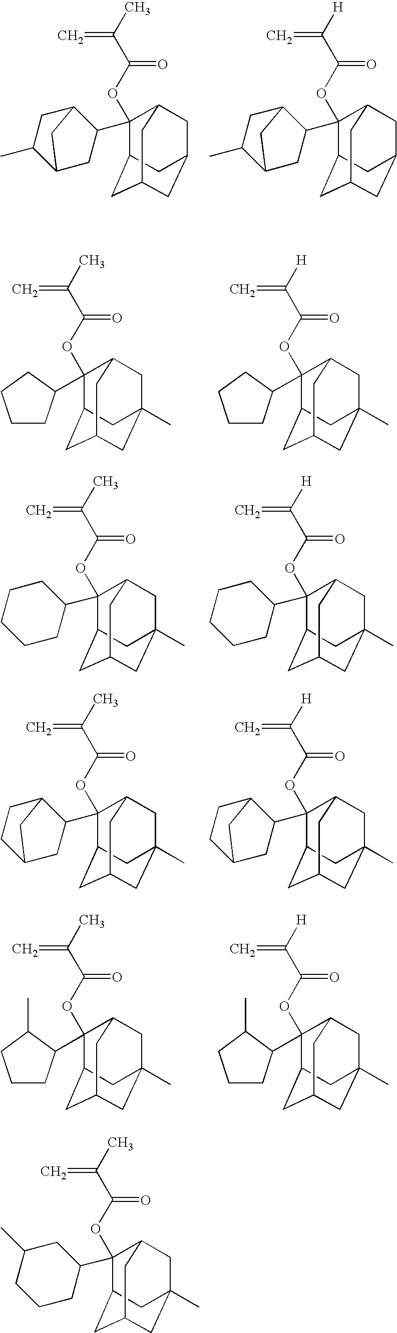

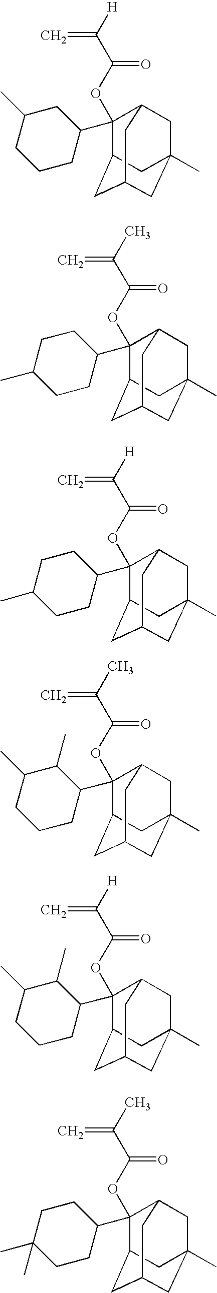

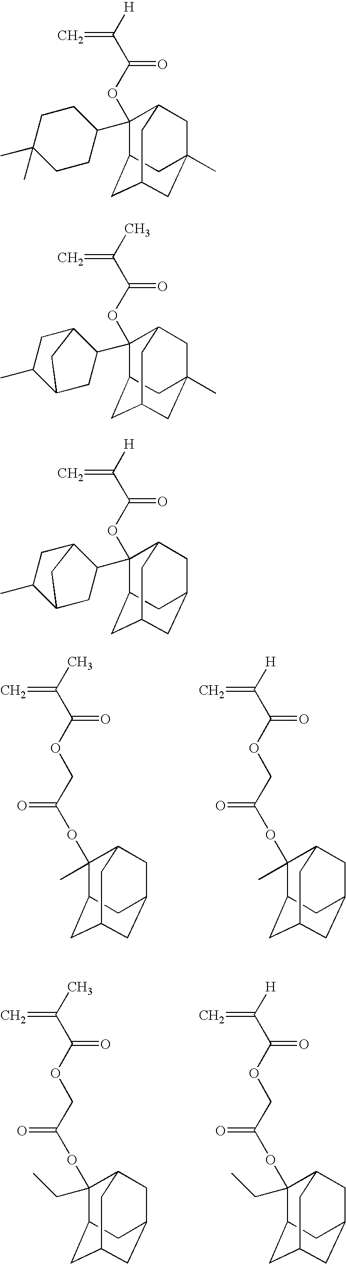

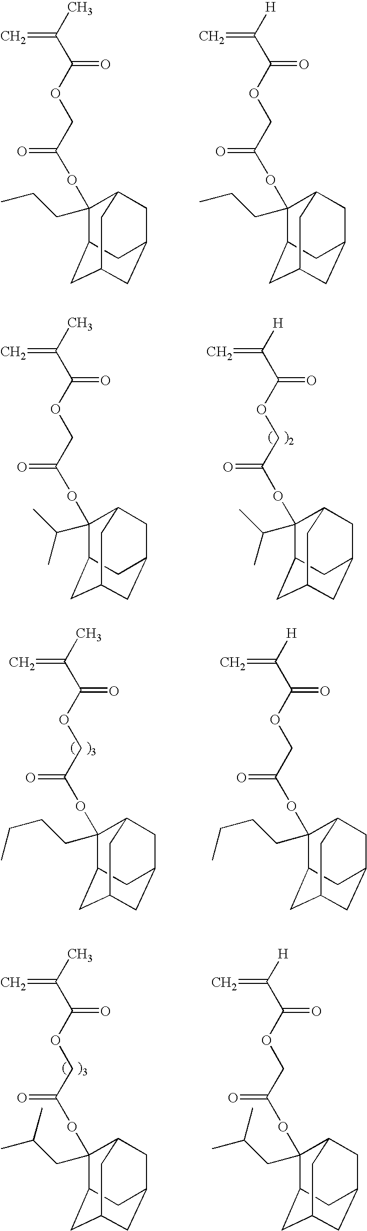

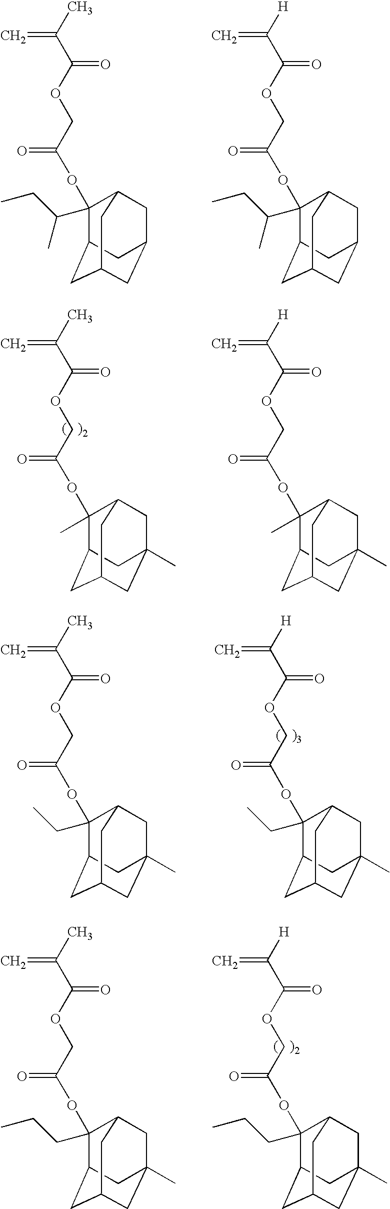

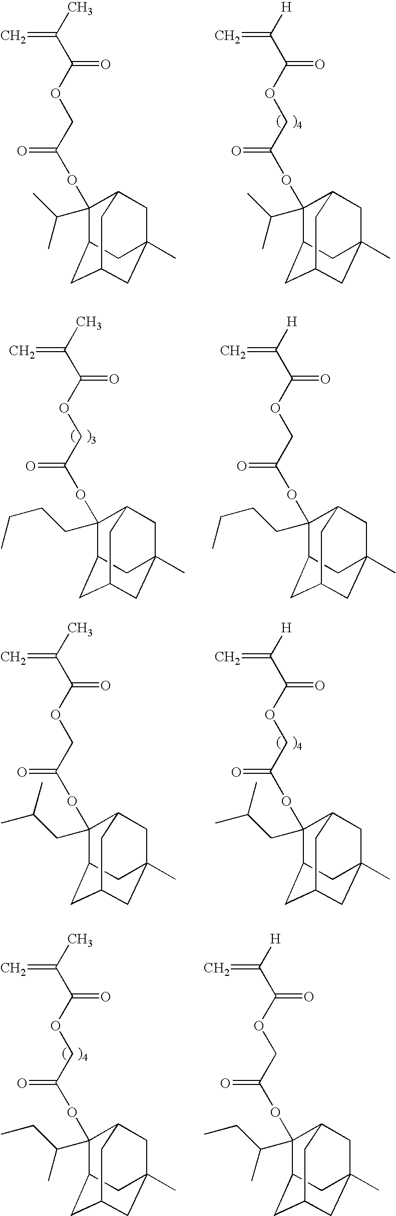

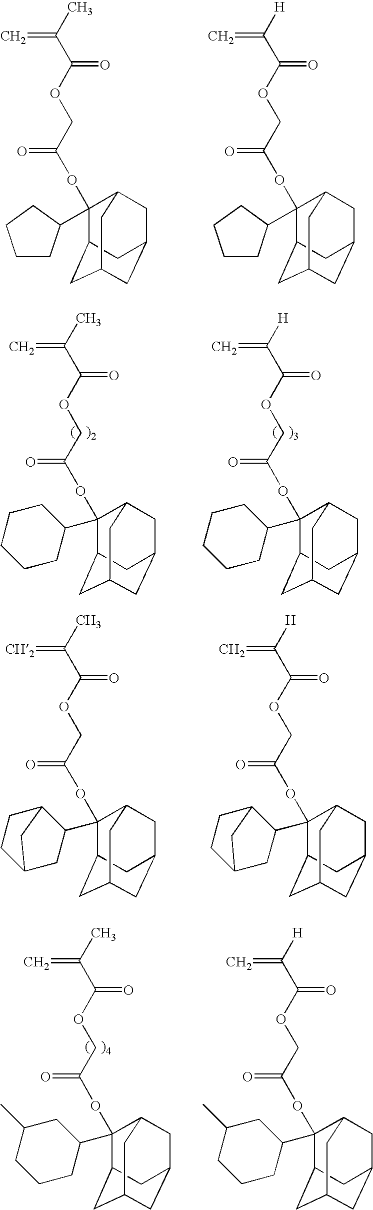

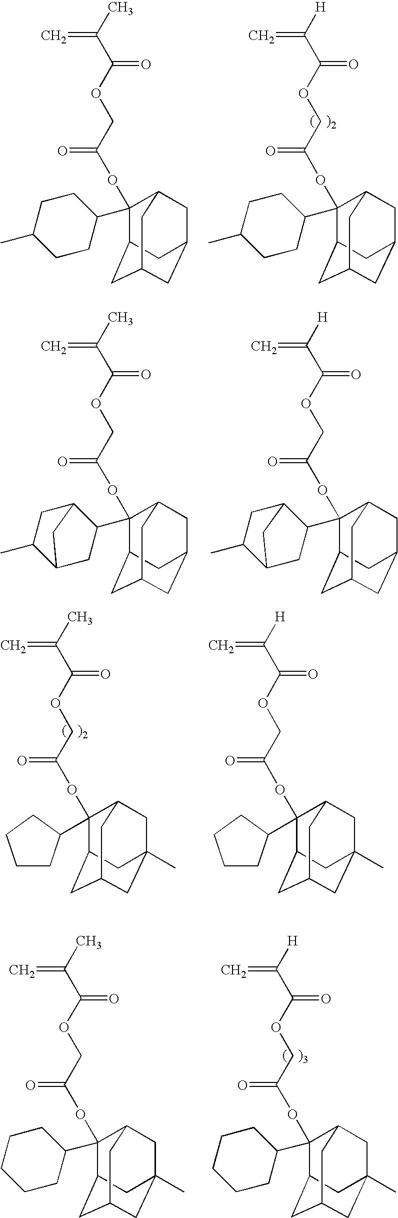

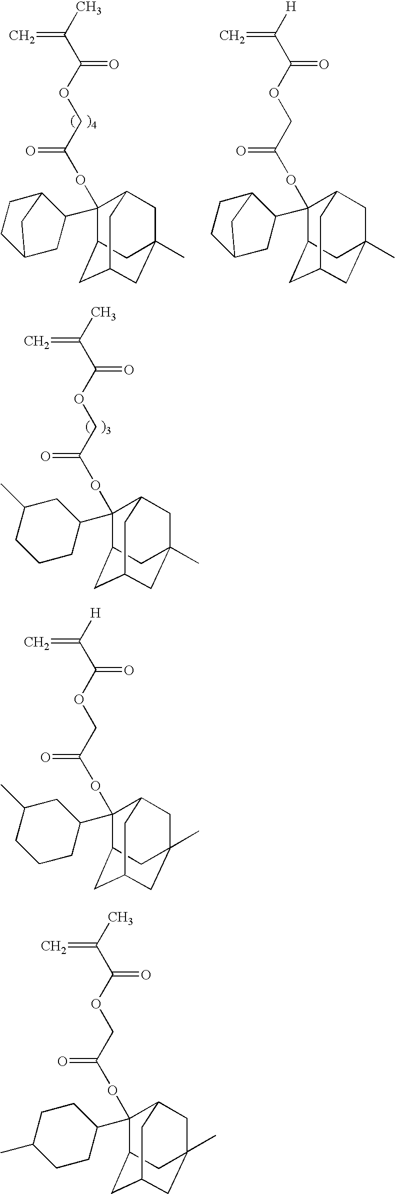

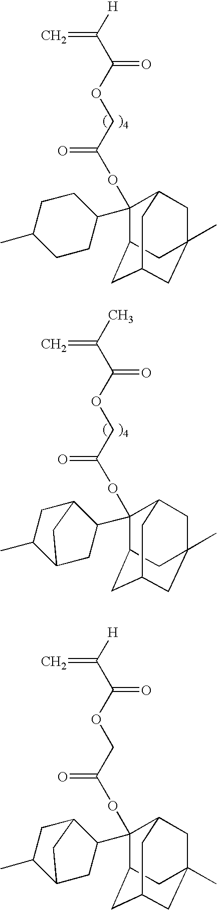

Examples of the monomer giving the structural unit represented by the formula (IIb) include the followings:

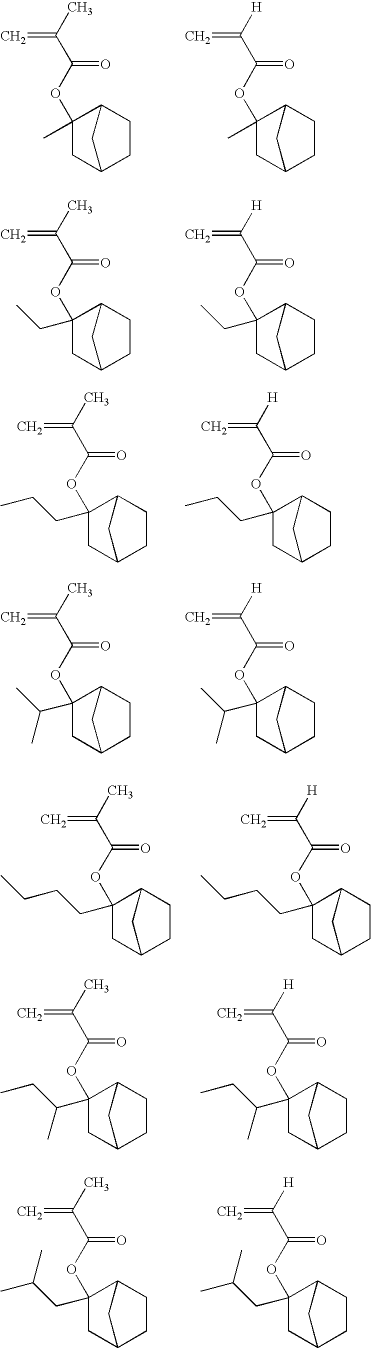

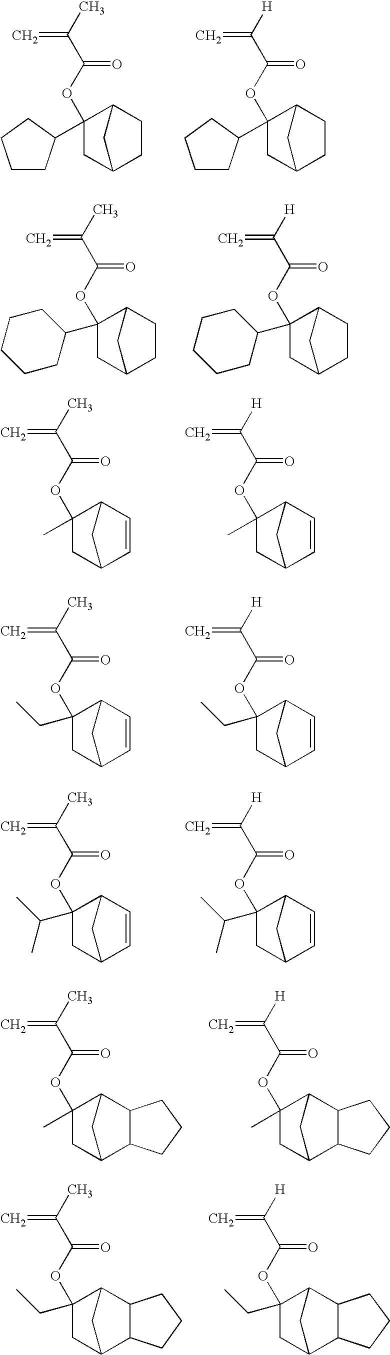

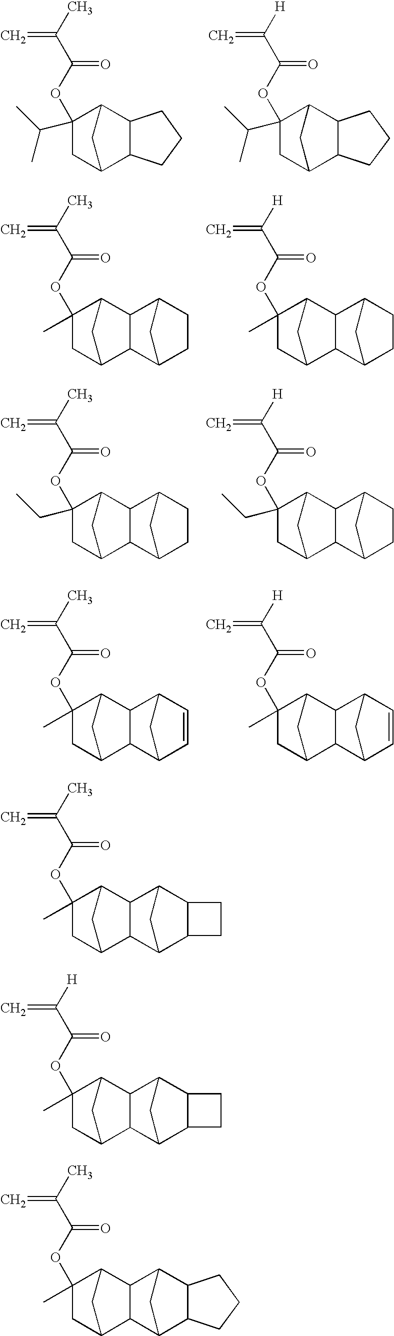

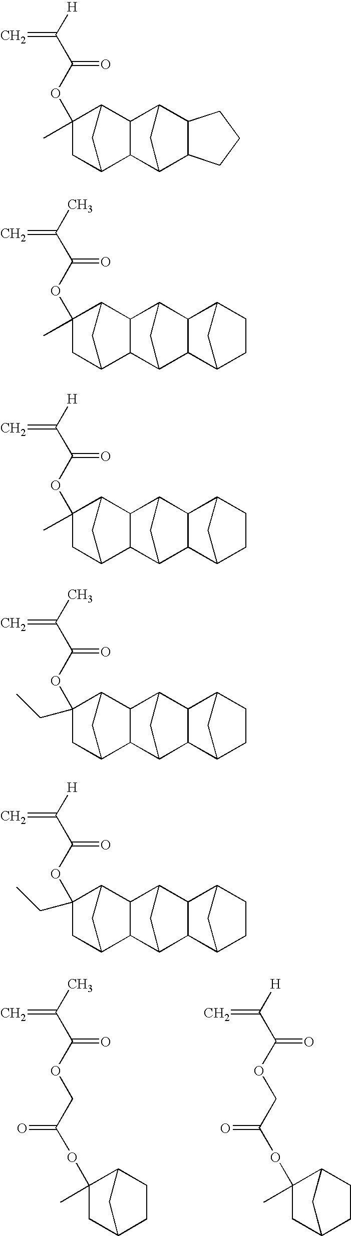

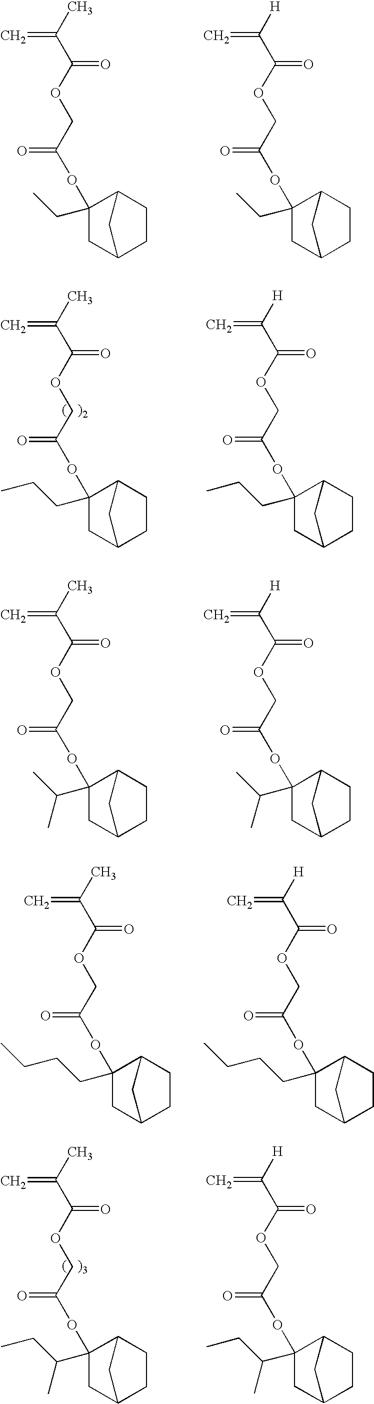

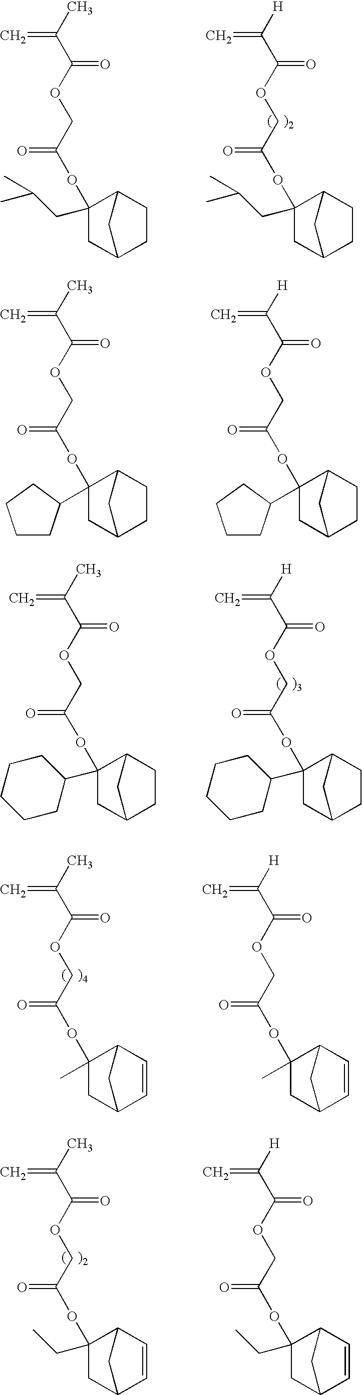

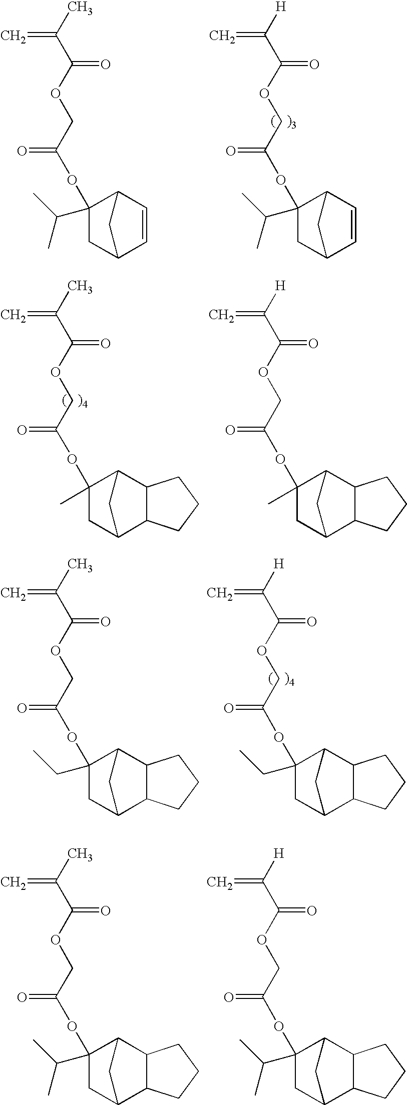

Among them, 2-methyl-2-adamantyl acrylate, 2-methyl-2-adamantyl methacrylate, 2-ethyl-2-adamantyl acrylate, 2-ethyl-2-adamantyl methacrylate, 2-isopropyl-2-adamantyl acrylate, 2-isopropyl-2-adamantyl methacrylate, (2-methyl-2-adamantyloxycarbonyl)methyl acrylate and (2-methyl-2-adamantyloxycarbonyl)methyl methacrylate are preferable from the viewpoint of resolution and heat resistance.

Examples of the other structural unit having an acid-labile group in its side chain include structural units represented by the formulae (IIc) and (IId):

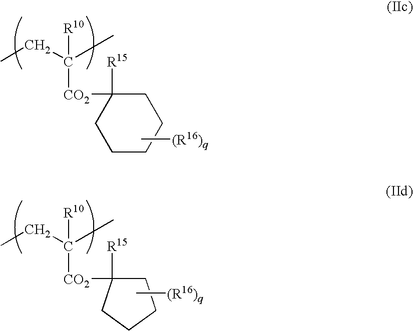

wherein R¹⁰ is the same as defined above, R¹⁵ is independently in each occurrence a C1-C8 alkyl group or a C1-C8 alkoxy group, R¹⁶ represents a C1-C8 alkyl group, q represents an integer of 0 to 3.

Examples of the C1-C8 alkyl group in R¹⁵ include a methyl group, an ethyl group, a propyl group, an isopropyl group, a butyl group, an isobutyl group, a sec-butyl group, a pentyl group, a hexyl group, a heptyl group and an octyl group. Examples of the C1-C8 alkoxy group in R¹⁵ include a methoxy group, an ethoxy group, a propoxy group, an isopropoxy group, a butoxy group, an isobutoxy group, a sec-butoxy group, a pentyloxy group, a hexyloxy group, a heptyloxy group and an octyloxy group.

Examples of the monomer giving the structural units represented by the formulae (IIc) and (IId) include the followings:

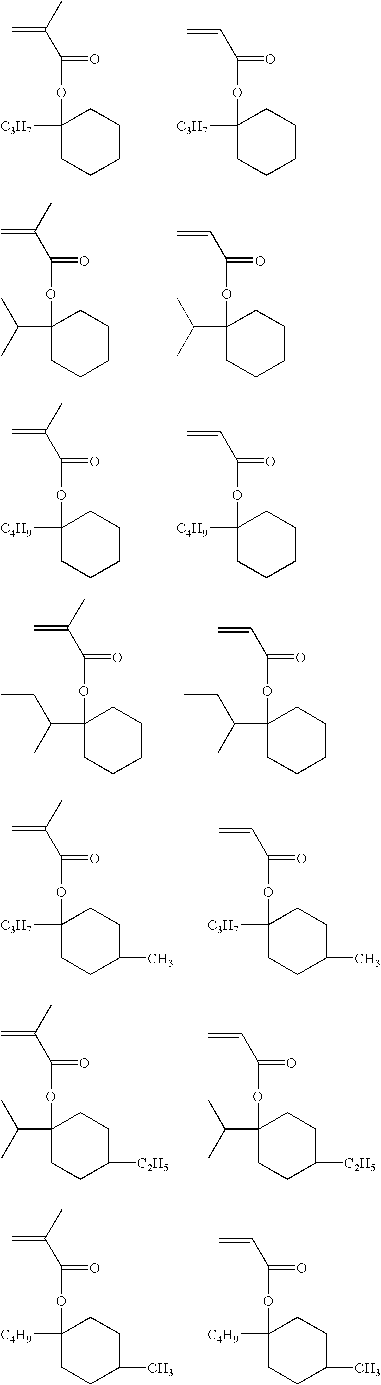

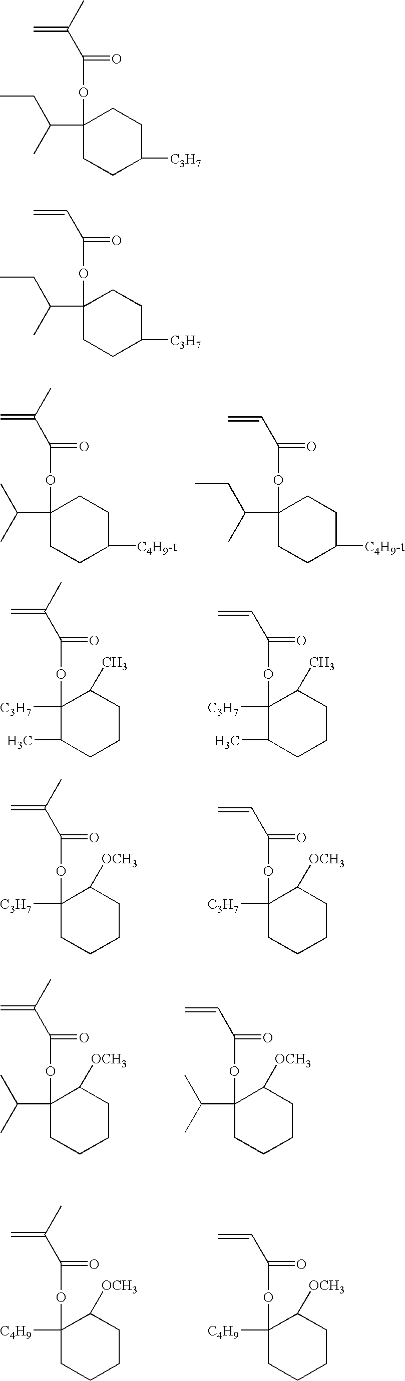

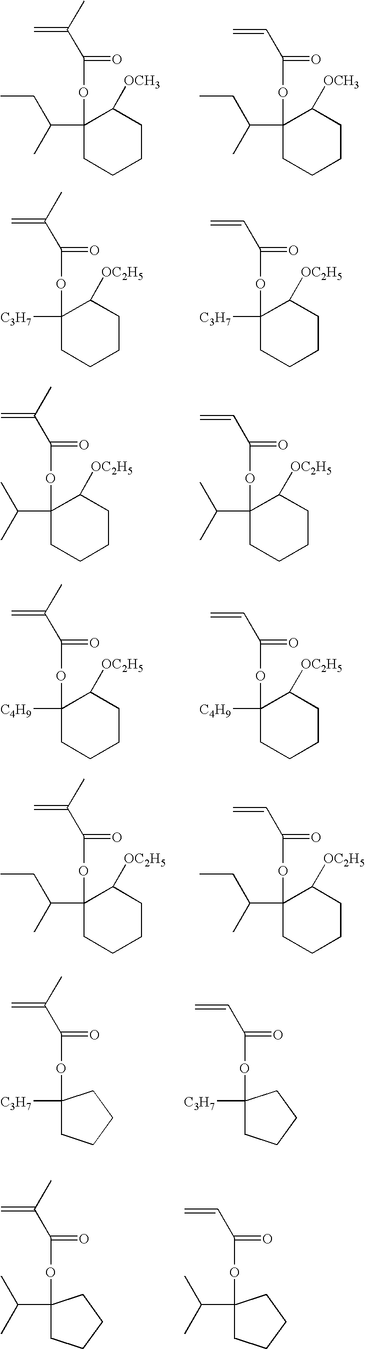

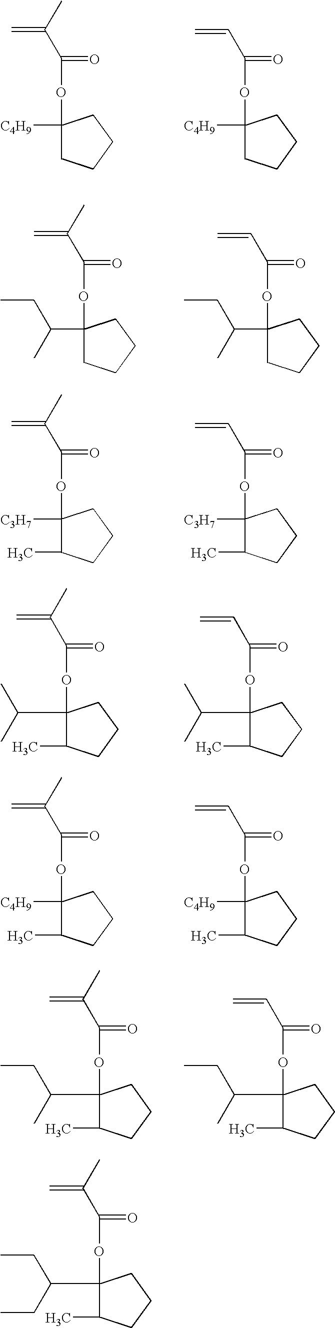

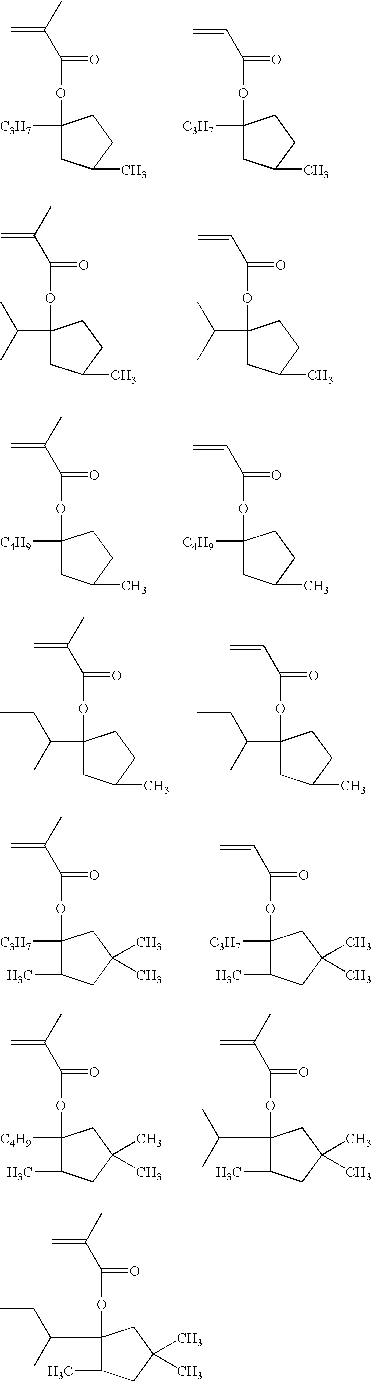

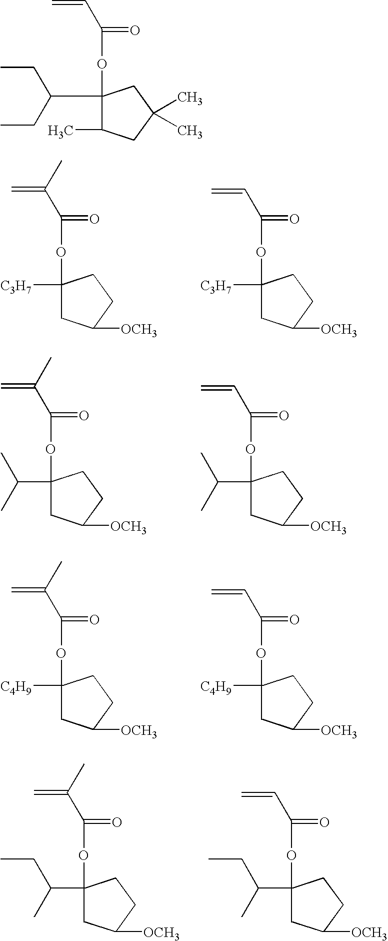

The monomers giving the structural unit represented by the formula (IIa), (IIb), (IIc) and (IId) can be produced, for example, by reacting acrylic halide or methacrylic halide with the corresponding alcohol compound or its alkali salt.

The content of the structural unit having an acid-labile group in its side chain in the resin (A) is usually 10 to 80 mol % and preferably 15 to 40 mol % based on the total molar of all structural units of the resin (A).

The resin (A) may contain one or more kinds of a structural unit having a lactone structure in its side chain in addition to the structural unit having an acid-labile group. Examples of the lactone structure include a β-butyrolactone structure, a γ-butyrolactone structure, a condensed lactone structure composed of a cycloalkane ring and a lactone ring, and a condensed lactone structure composed of a norbornane ring and a lactone ring.

The resin (A) may contain two or more kinds of a structural unit having a lactone structure in its side chain in addition to the structural unit having an acid-labile group.

Examples of the structural unit having a lactone structure in its side chain include the structural unit represented by the formula (I):

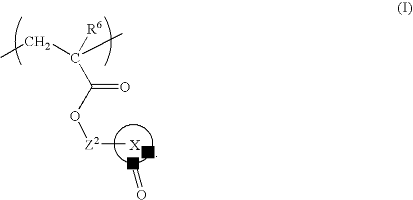

In the formula (I), R⁶ represents a hydrogen atom or a methyl group, Z² represents a single bond or —(CH₂)ₖ—CO—O—, and k represents an integer of 1 to 4. Z² is preferably a single bond or —CH₂—CO—O—, and more preferably a single bond. Ring X represents an unsubstituted or substituted C3-C30 cyclic hydrocarbon group having —COO—. Ring X has a lactone structure, and it may be a monocyclic lactone structure or a polycyclic lactone structure.

The C3-C30 cyclic hydrocarbon group having —COO— may have one or more substituents, and examples of the substituents include a carboxyl group, a cyano group and a C1-C4 hydrocarbon group such as a methyl group.

Preferable examples of the structural unit represented by the formula (I) include structural units represented by the formulae (Ia), (Ib) and (Ic):

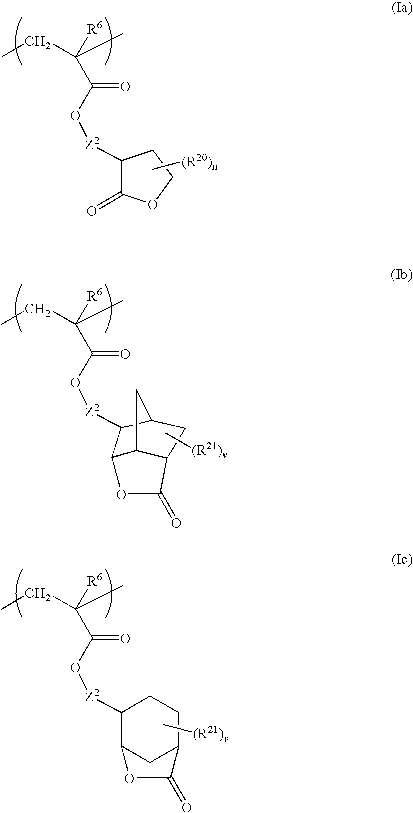

wherein R⁶ and Z² are the same as defined above, R²⁰ represents a methyl group, R²¹ is independently in each occurrence a carboxyl group, a cyano group or a C1-C4 hydrocarbon group. Among them, structural units represented by the formulae (Ia), (Ib) and (Ic) wherein Z² is a single bond or —CH₂—CO—O— are more preferable, and structural units represented by the formulae (Ia), (Ib) and (Ic) wherein Z² is a single bond are especially preferable.

Examples of the monomer giving the structural unit represented by the formulae (Ia), (Ib) and (Ic) include the followings:

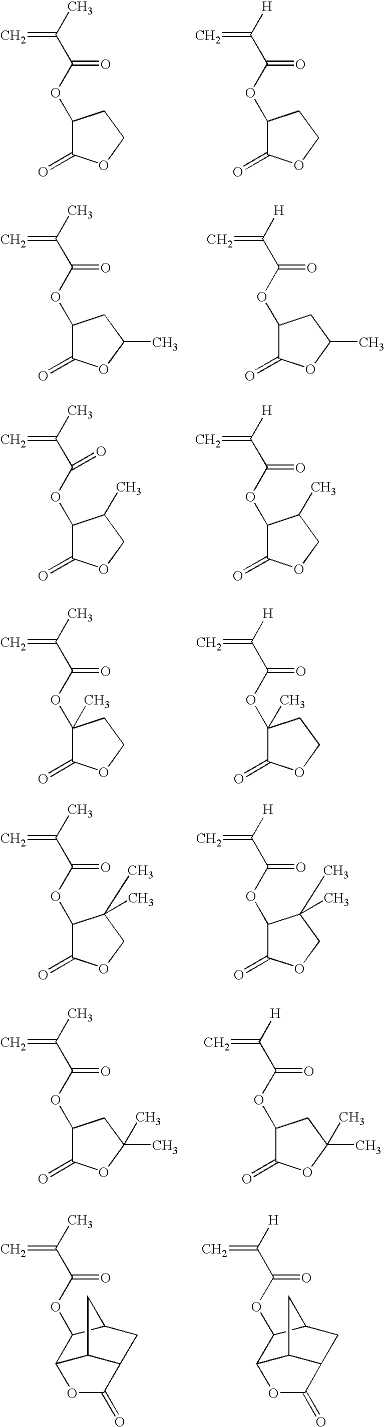

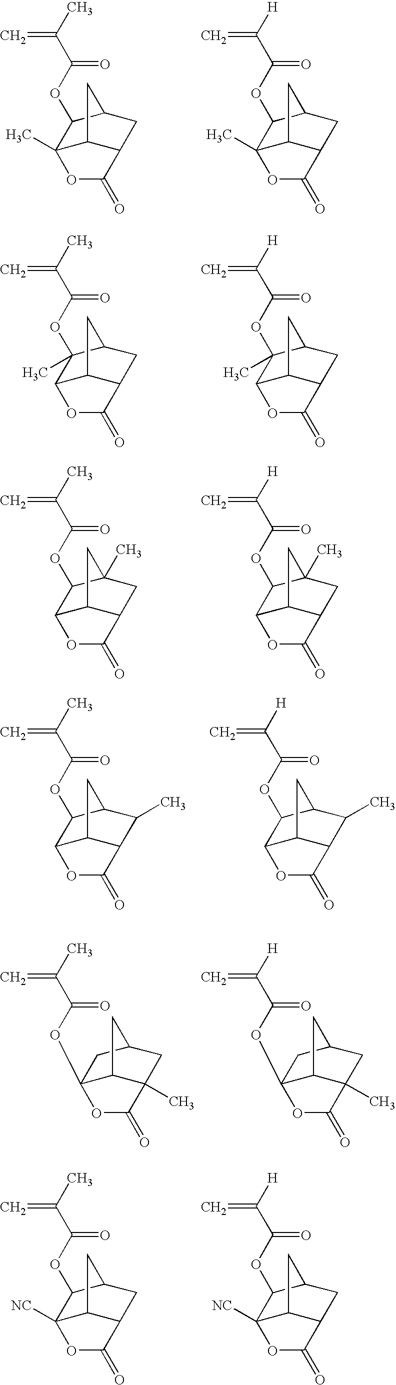

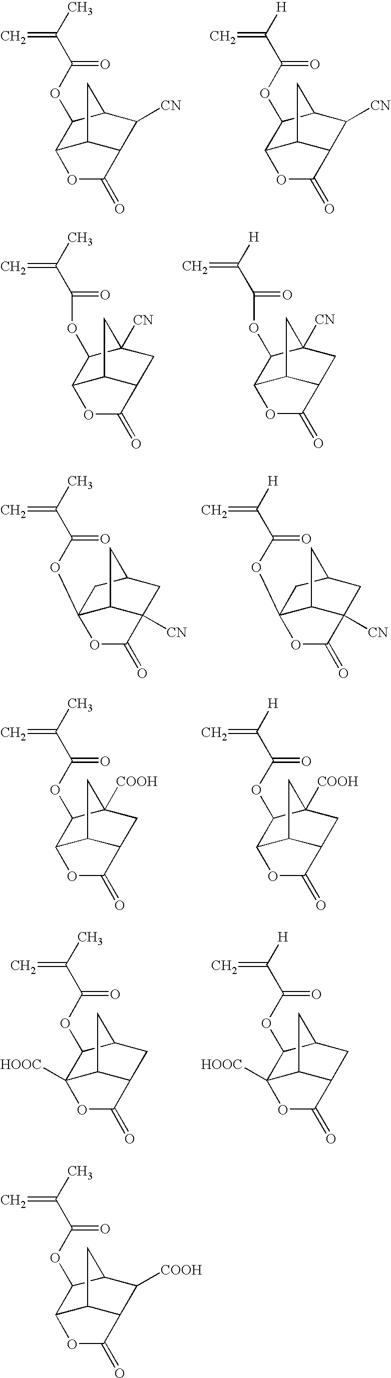

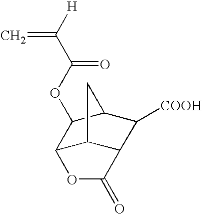

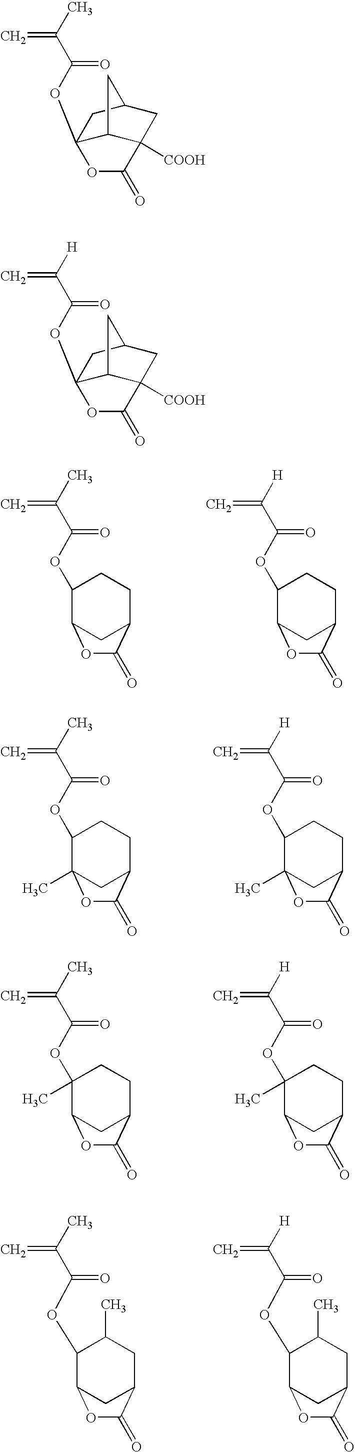

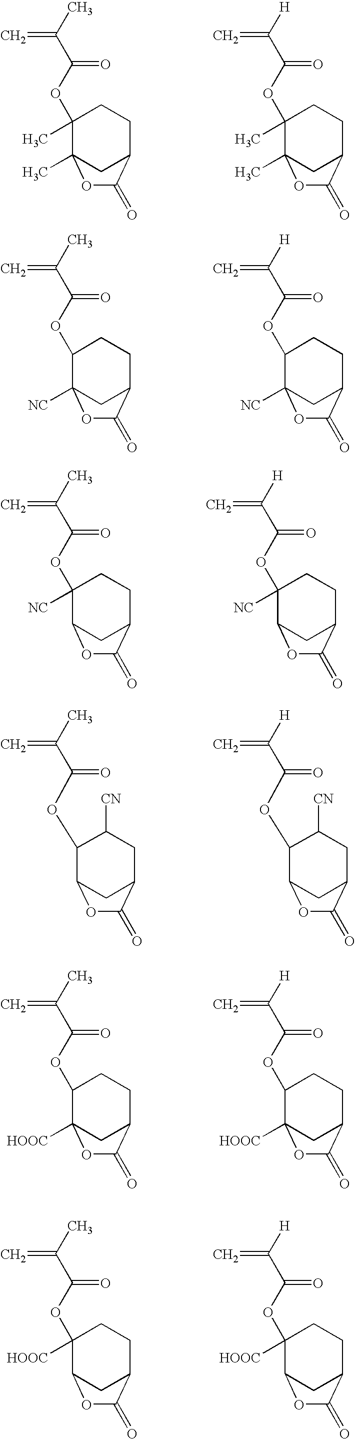

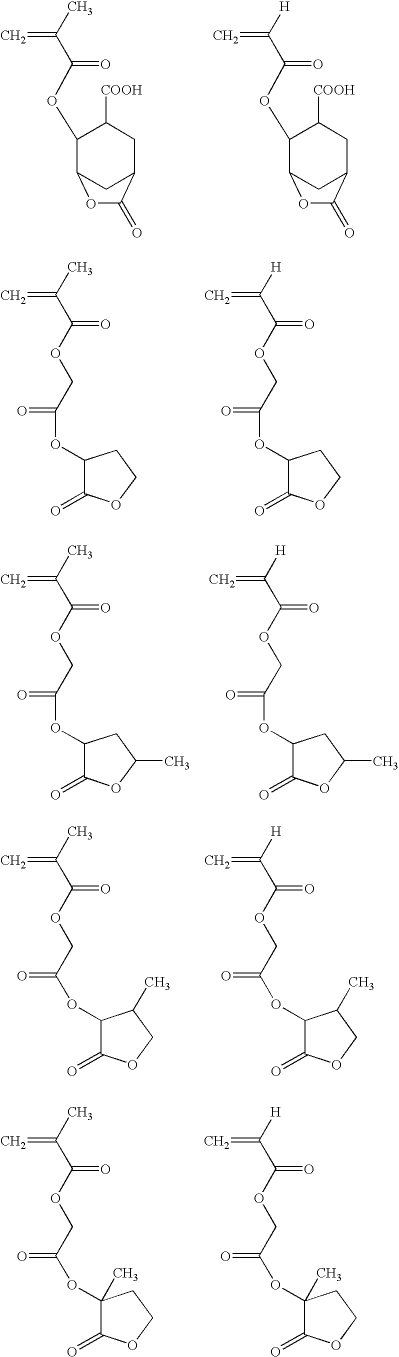

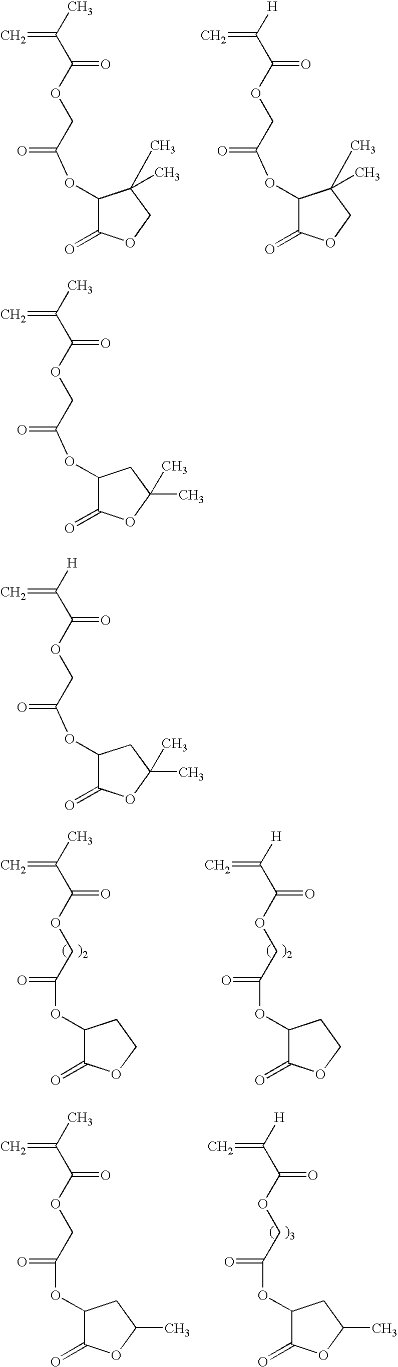

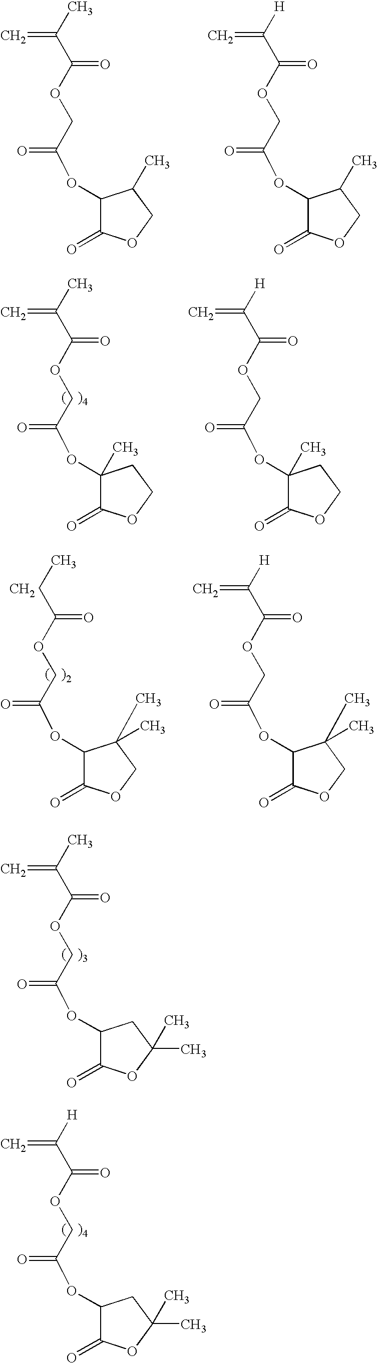

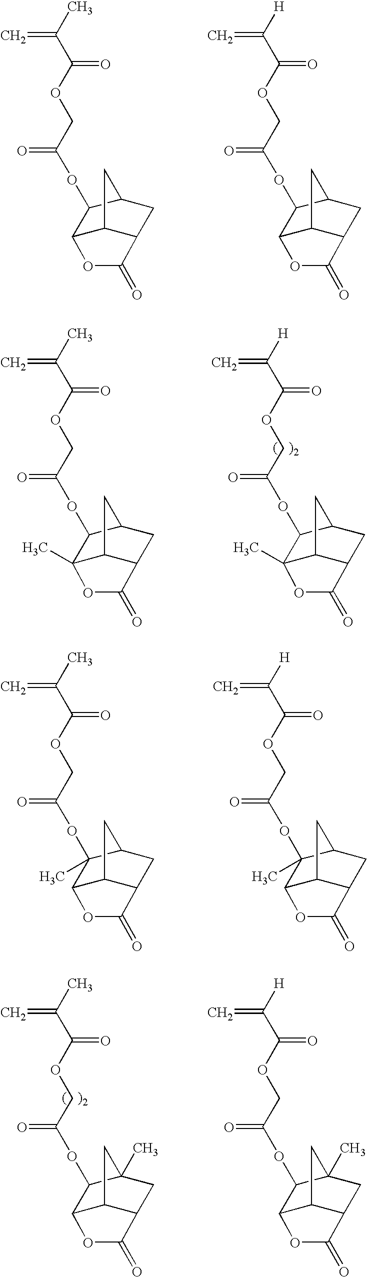

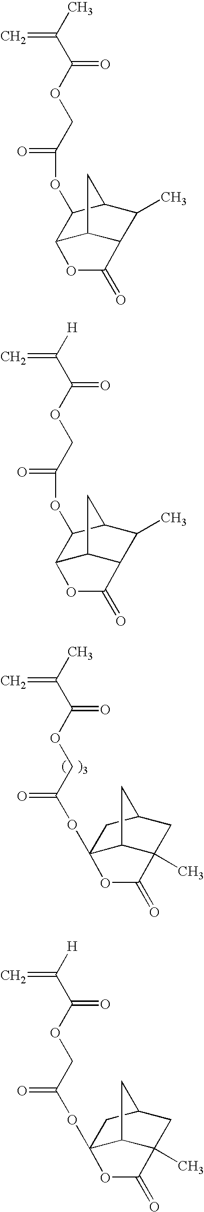

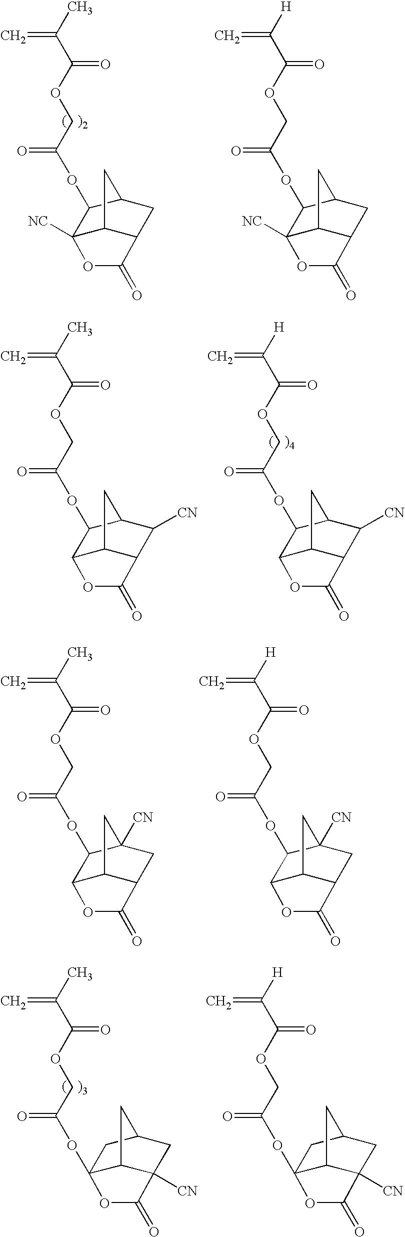

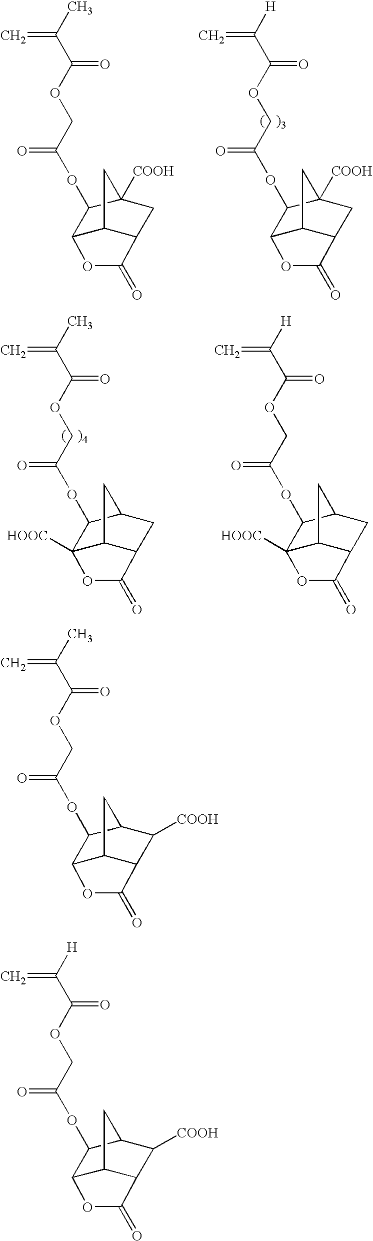

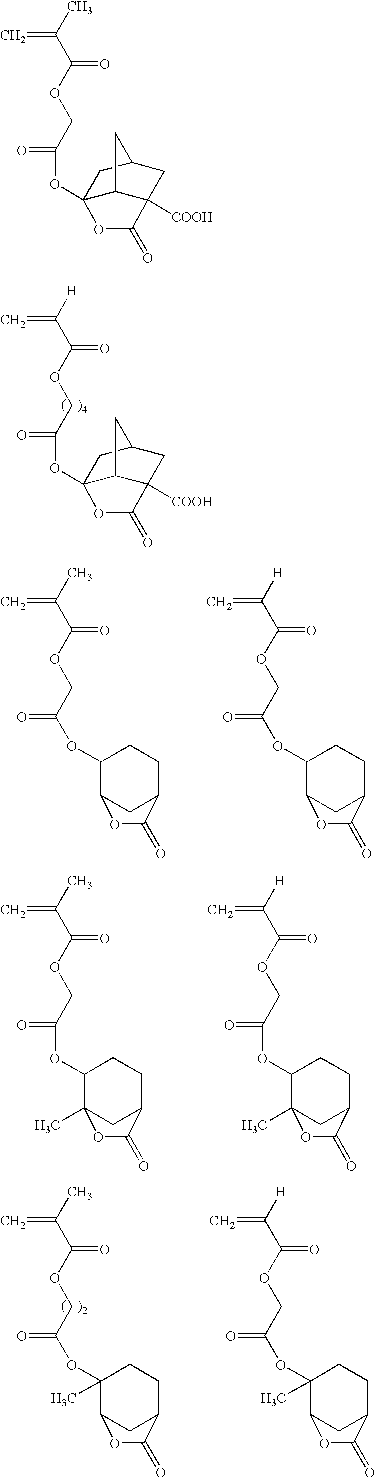

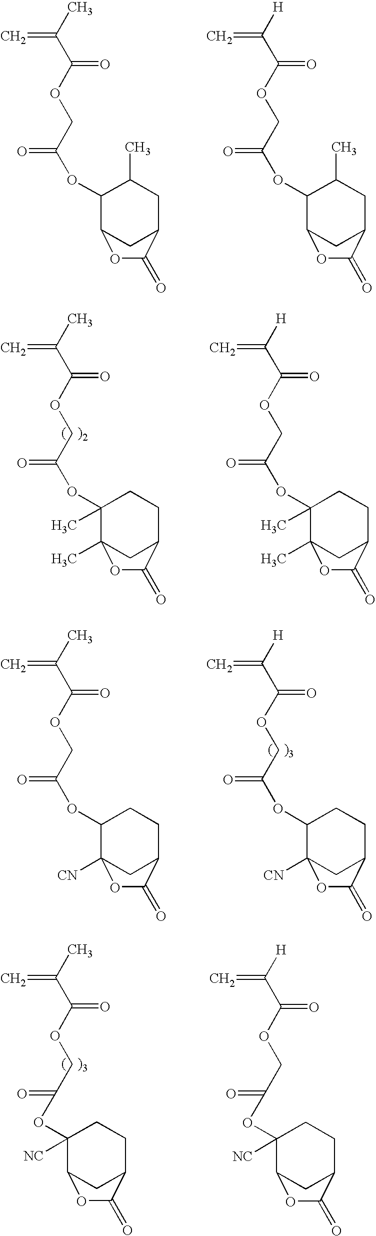

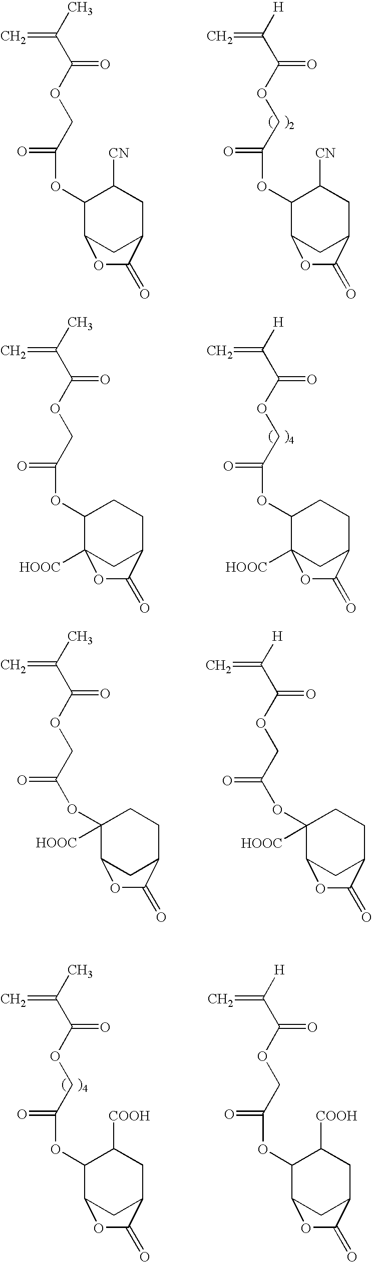

The structural units derived from hexahydro-2-oxo-3,5-methano-2H-cyclopenta[b]furan-6-ylacrylate, hexahydro-2-oxo-3,5-methano-2H-cyclopenta[b]furan-6-yl methacrylate, tetrahydro-2-oxo-3-furyl acrylate, tetrahydro-2-oxo-3-furyl methacrylate are preferable in viewpoint of the adhesiveness of resist composition to a substrate. The structural units derived from 2-(5-oxo-4-oxatricyclo[4.2.1.0^{3.7}]nonan-2-yloxy)-2-oxoethyl acrylate and 2-(5-oxo-4-oxatricyclo[4.2.1.0^{3.7}]nonan-2-yloxy)-2-oxoethyl methacrylate are preferable because the pattern having good profile can be obtained when the resin containing the above-mentioned structural unit is used in the present resist composition.

The monomers giving the structural units represented by the formula (I) can usually be produced by a reaction of the corresponding hydroxyl-containing lactone compound with an acrylic halide or methacrylic halide.

The monomers giving the structural units represented by the formula (I) can also be produced by a reaction of the corresponding halogen-containing lactone compound with an acrylic acid or methacrylic acid.

The content of the structural unit having a lactone structure in its side chain in the resin (A) is usually 10 to 80 mol % and preferably 20 to 60 mol % based on the total molar of all structural units of the resin (A).

As the resin (A), a resin (A1) comprising a structural unit having an acid-labile group in its side chain and a structural unit represented by the formula (I) is preferable.

The resin (A) may contain a structural unit having one or more hydroxyl groups in its side chain other than the structural unit having an acid-labile group in its side chain and the structural unit having a lactone structure in its side chain. The resin (A) preferably contains a structural unit having one or more hydroxyl groups in its side chain. The resin (A) may contain two or more kinds of the structural unit having one or more hydroxyl groups in its side chain.

As the structural unit having one or more hydroxyl groups in its side chain, a structural unit represented by the formula (IV):

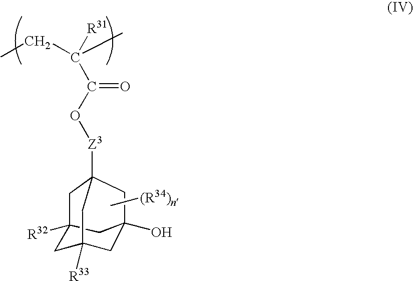

wherein R³¹ represents a hydrogen atom or a methyl group, R³² and R³³ each independently represents a hydrogen atom, a methyl group or a hydroxyl group, R³⁴ represents a methyl group, n′ represents an integer of 0 to 10, Z³ represents a single bond or —(CH₂)_{y}—CO—O— and y represents an integer of 1 to 4, is preferable, and a structural unit represented by the formula (IV) wherein n′ is 0 or 1 is more preferable. The structural unit represented by the formula (IV) wherein R³² and R³³ each independently represents a hydrogen atom or a hydroxyl group is also preferable.

Examples of the monomer giving the structural unit represented by the formula (IV) include the followings.

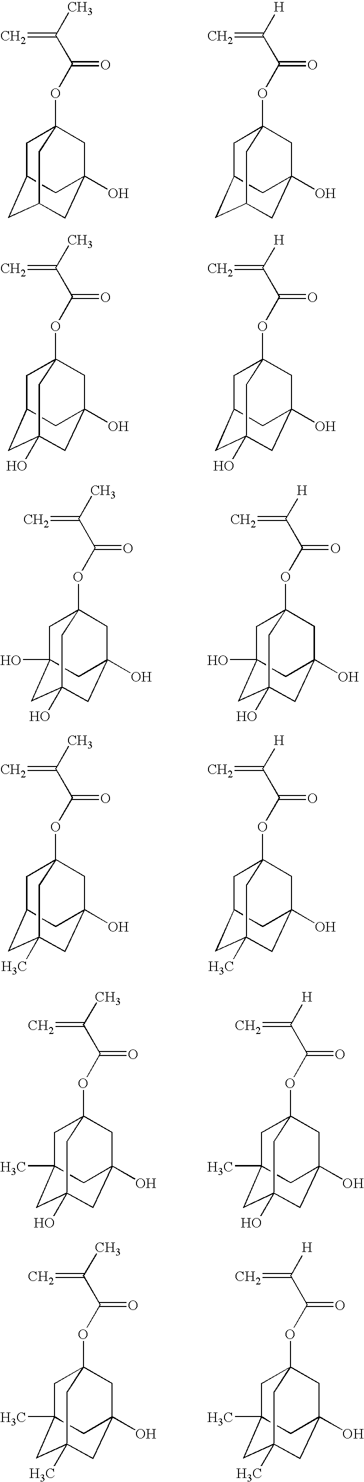

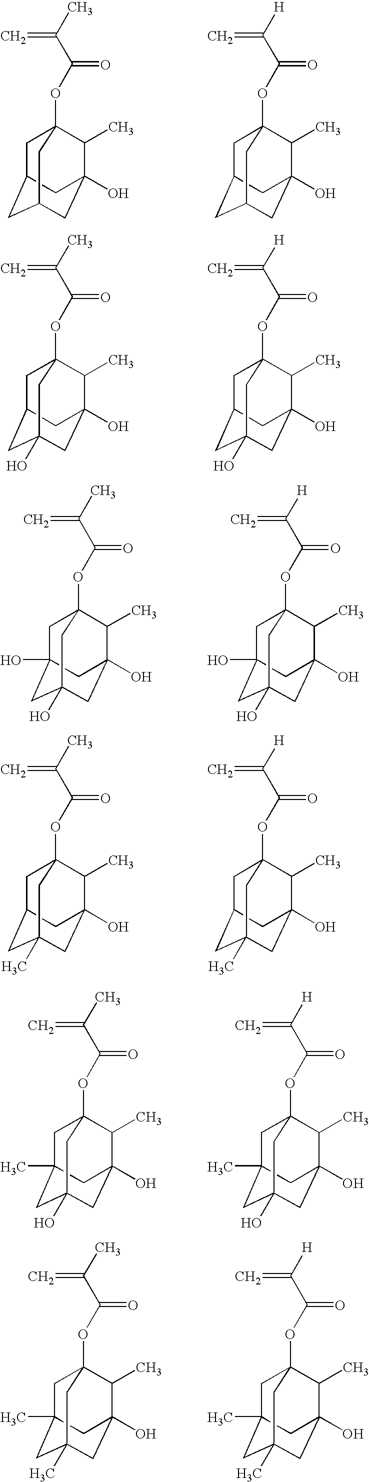

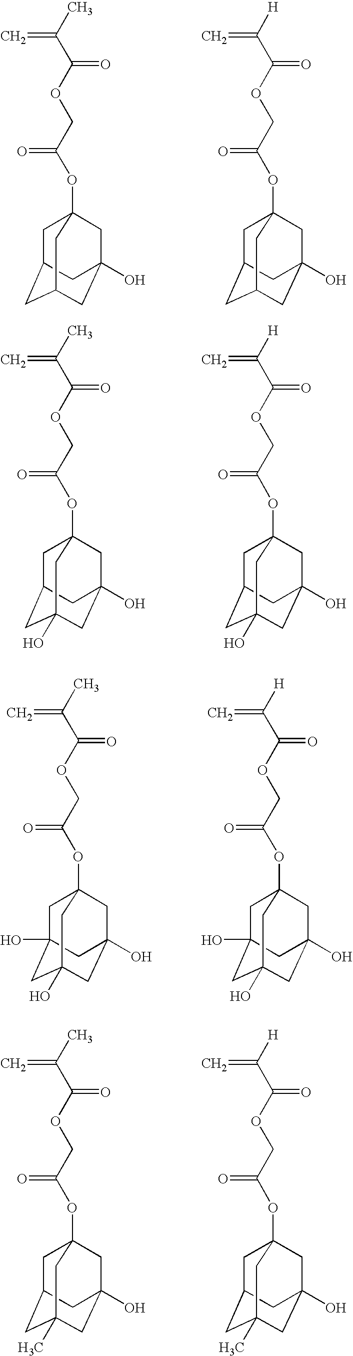

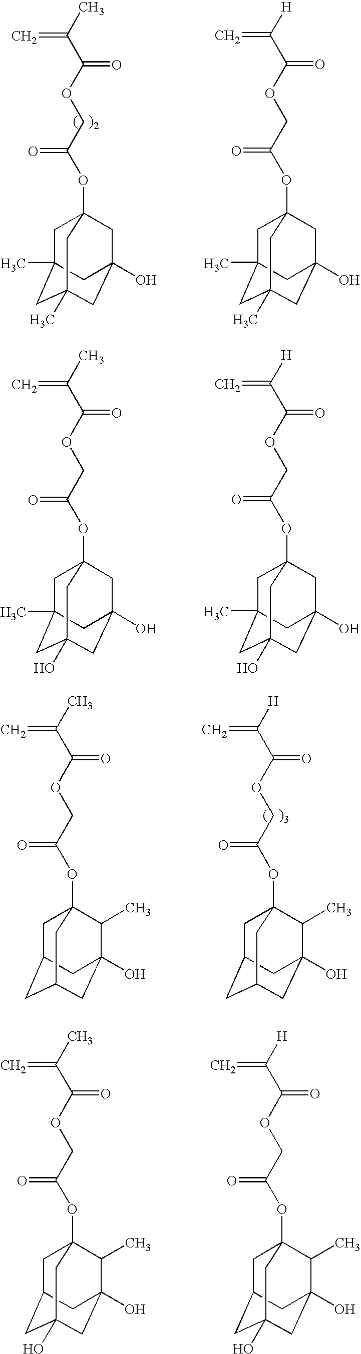

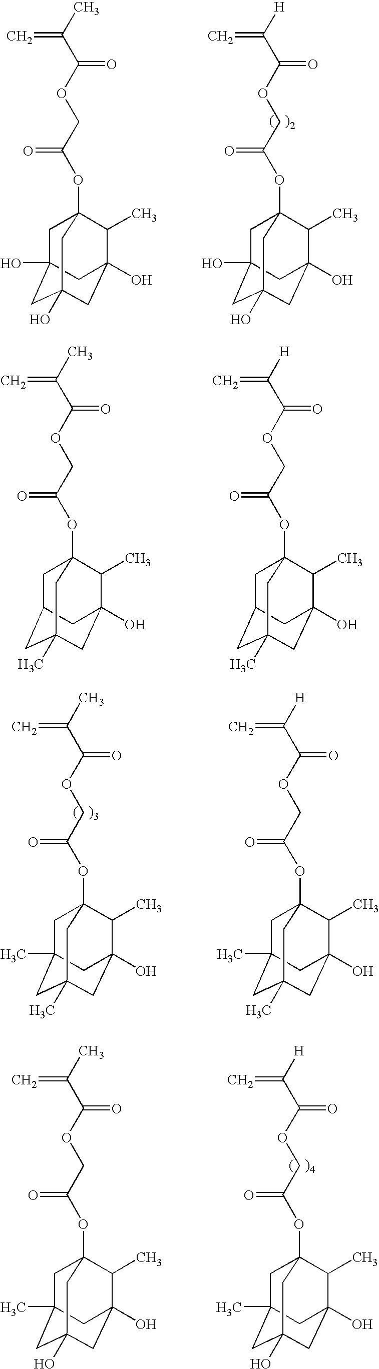

Among them, 3-hydroxy-1-adamantyl acrylate, 3-hydroxy-1-adamantyl methacrylate, 3,5-dihydroxy-1-adamantyl acrylate, 3,5-dihydroxy-1-adamantyl methacrylate, (3,5-dihydroxy-1-adamantyloxycarbonyl)methyl acrylate and (3,5-dihydroxy-1-adamantyloxycarbonyl)methyl methacrylate are preferable from the viewpoint of resolution.

The monomer giving the structural unit represented by the formula (IV) can be produced by a reaction of the corresponding hydroxyl-containing adamantane compound with an acrylic halide or a methacrylic halide.

The content of the structural unit having one or more hydroxyl groups in its side chain in the resin (A) is usually 0 to 40 mol % and preferably 5 to 35 mol % based on the total molar of all structural units of the resin (A).

The resin (A) may contains a structural unit represented by the formula (III):

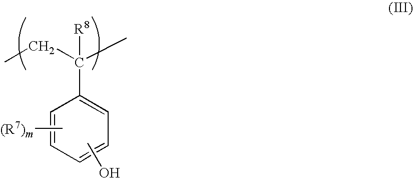

in addition to the structural unit having an acid-labile group in its side chain.

As the resin (A), a resin (A2) comprising a structural unit having an acid-labile group in its side chain and a structural unit represented by the formula (III) is preferable.

The resin (A) may have two or more kinds of the structural unit represented by the formula (III).

In the formula (III), R⁸ represents a hydrogen atom or a methyl group, R⁷ is independently in each occurrence a linear or branched chain C1-C6 alkyl group. Examples of the linear or branched chain C1-C6 alkyl group include a methyl group, an ethyl group, a propyl group, an isopropyl group, a butyl group, a isobutyl group, a pentyl group and a hexyl group, and a methyl group is preferable. In the formula (III), m represents an integer of 0 to 4, and m is preferably 0 or 1, and more preferably 0.

In the formula (III), a hydroxyl group may be bonded at ortho-position, meta-position or para-position.

The structural unit represented by the following formula:

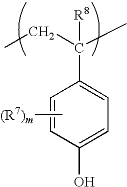

wherein R⁸, R⁷ and m are the same meanings as defined above, is preferable.

Examples of the structural unit represented by the formula (III) include the followings.

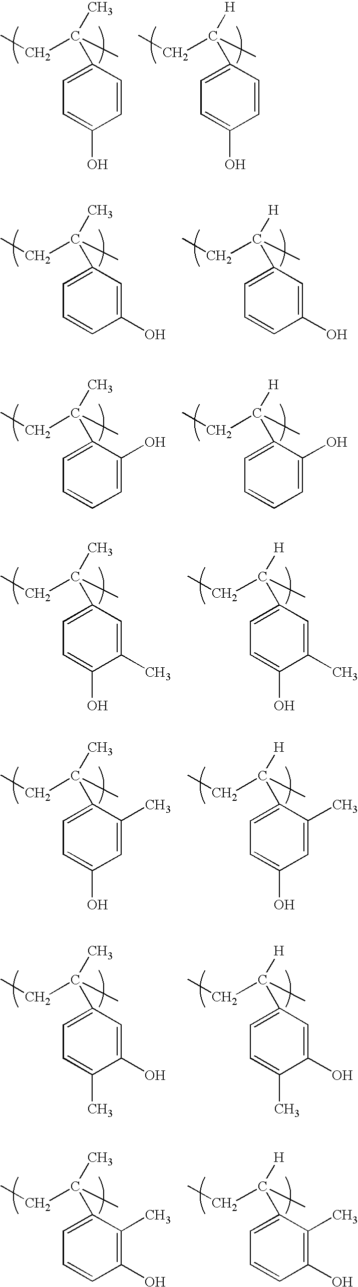

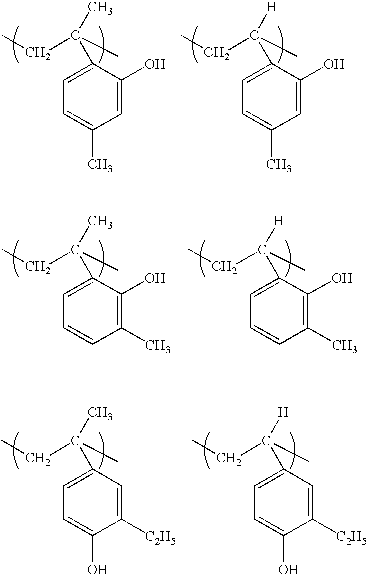

Among them, a structural unit derived from 4-hydroxystyrene and a structural unit derived from 4-hydroxy-α-styrene are preferable.

The structural unit represented by the formula (III) can be derived from a monomer represented by the formula:

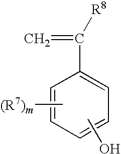

wherein R⁶, R⁷ and n are the same as defined above.

The molar ratio of the structural unit having an acid-labile group in its side chain to the structural unit represented by the formula (III) (the structural unit having an acid-labile group in its side chain/the structural unit represented by the formula (III)) in the resin (A2) is usually 10/90 to 90/10 and preferably 65/35 to 85/15 from the viewpoint of resolution and pattern profile.

The resin (A) may be a mixture of two or more kinds of the resin being insoluble or poorly soluble in an alkali aqueous solution but becoming soluble in an alkali aqueous solution by the action of an acid.

The resin (A) may contain the resin (A1) and the resin (A2).

When the resin (A) contains the resin (A1) and the resin (A2), the weight ratio of the resin (A1) to the resin (A2) (the resin (A1)/the resin (A2)) is usually 1/10 to 10/1, and preferably 1/3 to 3/1.

The resin (A) may contain a structural unit derived from an alicyclic compound having an olefinic double bond. Examples of the structural unit derived from an alicyclic compound having an olefinic double bond include a structural unit represented by the formula (d):

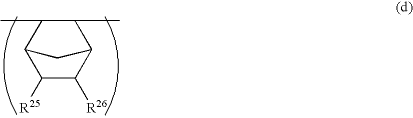

wherein R²⁵ and R²⁶ each independently represents a hydrogen atom, a C1-C3 alkyl group, a C1-C3 hydroxyalkyl group, a carboxyl group, a cyano group, a hydroxyl group or a —COOU group in which U represents an alcohol residue, or R²⁵ and R²⁶ can be bonded together to form a carboxylic anhydride residue represented by —C(═O)OC(═O)—;
a structural unit derived from an aliphatic unsaturated dicarboxylic anhydride such as a structural unit represented by the formula (e):

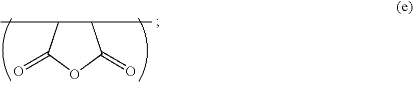

and
a structural unit represented by the formula (f):

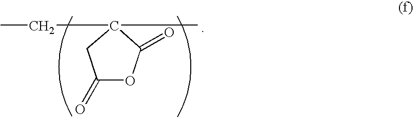

The resin (A) containing a structural unit derived from 2-norbornene shows strong structure because the alicyclic group is directly present on its main chain and shows a property that dry etching resistance is more excellent. The structural unit derived from 2-norbornene can be introduced into the main chain by radical polymerization using, for example, an aliphatic unsaturated dicarboxylic anhydride such as maleic anhydride and itaconic anhydride together in addition to corresponding 2-norbornene. The structural unit derived from 2-norbornene is formed by opening of its double bond, and can be represented by the above-mentioned formula (d). The structural units derived from maleic anhydride and from itaconic anhydride, which are the structural units derived from aliphatic unsaturated dicarboxylic anhydrides, are formed by opening of their double bonds, and can be represented by the above-mentioned formulae (e) and (f), respectively.

In R²⁵ and R²⁶, examples of the C1-C3 alkyl group include a methyl group, an ethyl group, and a propyl group, and examples of the C1-C3 hydroxyalkyl group include a hydroxymethyl group and a 2-hydroxyethyl group.

In R²⁵ and R²⁶, the —COOU group is an ester formed from the carboxyl group, and examples of the alcohol residue corresponding to U include an optionally substituted C1-C8 alkyl group, a 2-oxooxolan-3-yl group and a 2-oxooxolan-4-yl group, and examples of the substituent on the C1-C8 alkyl group include a hydroxyl group and an alicyclic hydrocarbon residue.

Specific examples of the monomer giving the structural unit represented by the above-mentioned formula (d) include 2-norbornene, 2-hydroxy-5-norbornene, 5-norbornene-2-carboxylic acid, methyl 5-norbornene-2-carboxylate, 2-hydroxyethyl 5-norbornene-2-carboxylate, 5-norbornene-2-methanol and 5-norbornene-2,3-dicarboxylic anhydride.

When U in the —COOU group is the acid-labile group, the structural unit represented by the formula (d) is a structural unit having the acid-labile group even if it has the norbornane structure. Examples of monomers giving structural unit having the structural unit represented by the above-mentioned formula (d) and the acid-labile group include tert-butyl 5-norbornene-2-carboxylate, 1-cyclohexyl-1-methylethyl 5-norbornene-2-carboxylate, 1-methylcyclohexyl 5-norbornene-2-carboxylate, 2-methyl-2-adamantyl 5-norbornene-2-carboxylate, 2-ethyl-2-adamantyl 5-norbornene-2-carboxylate, 1-(4-methylcyclohexyl)-1-methylethyl 5-norbornene-2-carboxylate, 1-(4-hydroxylcyclohexyl)-1-methylethyl 5-norbornene-2-carboxylate, 1-methyl-1-(4-oxocyclohexyl)ethyl 5-norbornene-2-carboxylate, and 1-(1-adamantyl)-1-methylethyl 5-norbornene-2-carboxylate.

The resin (A) has usually polystyrene-equivalent weight-average molecular weight of about 1,000 to 500,000, and preferably of 4,000 to 50,000.

The resin (A) can be produced by conducting the polymerization reaction of the corresponding monomers. The resin (A) can be also produced by conducting the oligomerization reaction of the corresponding monomers followed by polymerizing the obtained oligomer.

The polymerization reaction is preferably carried out the presence of a radical initiator.

The radical initiator is not limited and examples thereof include an azo compound such as 2,2′-azobisisobutyronitrile, 2,2′-azobis(2-methylbutyronitrile), 1,1′-azobis(cyclohexane-1-carbonitrile), 2,2′-azobis(2,4-dimethylvaleronitrile), 2,2′-azobis(2,4-dimethyl-4-methoxyvaleronitrile), dimethyl-2,2′-azobis(2-methylpropionate) and 2,2′-azobis(2-hydroxymethylpropionitrile); an organic hydroperoxide such as lauroyl peroxide, tert-butyl hydroperoxide, benzoyl peroxide, tert-butyl peroxybenzoate, cumene hydroperoxide, diisopropyl peroxydicarbonate, di-n-propyl peroxydicarbonate, tert-butyl peroxyneodecanoate, tert-butyl peroxypivalate and 3,5,5-trimethylhexanoyl peroxide; and an inorganic peroxide such as potassium peroxodisulfate, ammonium peroxodisulfate and hydrogen peroxide. Among them, the azo compound is preferable.

These radical initiators may be used alone or in a form of a mixture of two or more kinds thereof. When the mixture of two or more kinds thereof is used, the mixed ratio is not limited.

The amount of the radical initiator is preferably 1 to 20% by mole based on total molar amounts of all monomers or oligomers.

The polymerization temperature is usually 0 to 150° C., and preferably 40 to 100° C.

The polymerization reaction is usually carried out in the presence of a solvent and it is preferred to use a solvent which is sufficient to dissolve the monomer, the radical initiator, the resin (A). Examples thereof include hydrocarbons such as toluene; ethers such as 1,4-dioxane and tetrahydrofuran; ketones such as methyl isobutyl ketone; alcohols such as isopropyl alcohol; cyclic esters such as γ-butyrolactone; glycol ether esters such as propylene glycol monomethyl ether acetate; and acyclic esters such as ethyl lactate. These solvents may be used alone and a mixture thereof may be used.

The amount of the solvent is not limited, and practically, it is preferably 1 to 5 parts by weight per 1 part of all monomers or oligomers.

After completion of the polymerization reaction, the produced polymer can be isolated, for example, by adding a solvent in which the present polymer is insoluble or poorly soluble to the reaction mixture obtained and filtering the precipitated resin. If necessary, the isolated polymer may be purified, for example, by washing with a suitable solvent.

Alternatively, the resin (A2) can be also produced by using a polyvinylphenol. Examples of the polyvinylphenol include a commercially available polyvinylphenol, a polyvinylphenol produced according to the methods described in JP 2000-178325 A or the like.

Next, the polyhydric phenol compound (1) will be illustrated.

In the polyhydric phenol compound (1), at least one selected from the group consisting of R¹, R², R³, R⁴, and R⁵ is a group represented by the formula (2):

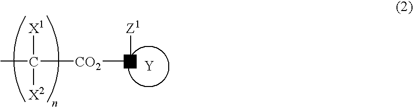

(hereinafter, simply referred to as the group (2)) and the others are hydrogen atoms.

In the group (2), X¹ and X² each independently represent a hydrogen atom or a C1-C4 alkyl group. Examples of the C1-C4 alkyl group include a methyl group, an ethyl group, a propyl group, an isopropyl group, a butyl group, an isobutyl group, a sec-butyl group and a tert-butyl group. It is preferred that X¹ and X² each independently represent the hydrogen atom, a methyl group or an ethyl group. X¹ and X² are more preferably the same and hydrogen atoms, methyl groups or ethyl groups, and X¹ and X² are especially preferably hydrogen atoms.

In the group (2), n represents an integer of 1 to 4, preferably an integer of 1 or 2, and more preferably 1.

The group (2) wherein X¹ and X² are hydrogen atoms and n is 1 is preferable.

In the formula (2), Z¹ represents a C1-C6 alkyl group or a C3-C12 cycloalkyl group, and the C1-C6 alkyl group is preferable. Examples of the C1-C6 alkyl group include a methyl group, an ethyl group, a propyl group, an isopropyl group, a butyl group, an isobutyl group, a sec-butyl group, a tert-butyl group, a pentyl group, a 3-methylbutyl group and a hexyl group, and a methyl group, an ethyl group and an isopropyl group are preferable. Examples of the C3-C12 cycloalkyl group include a cyclopropyl group, a cyclobutyl group, a cyclopentyl group, a cyclohexyl group, a cycloheptyl group and a cyclooctyl group.

In the formula (2), the ring Y represents an alicyclic hydrocarbon group. The alicyclic hydrocarbon group may have monocycle or bicycle or more, and an alicyclic hydrocarbon group having bicycle or more is preferable, and a C3-C12 alicyclic hydrocarbon group is preferable.

Examples of the alicyclic hydrocarbon group include the followings:

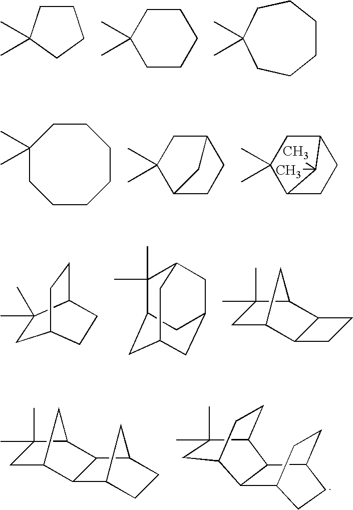

In the above formulae, one straight line with an open end shows a bond extended from the adjacent —CO₂—, and the other straight line with an open end shows a bond extended from the adjacent group Z¹.

Preferable examples thereof include the followings:

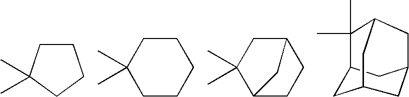

and more preferable examples thereof include the followings:

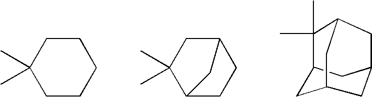

and especially preferable examples thereof include the followings:

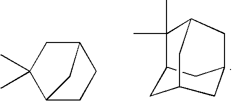

In the above formulae, one straight line with an open end shows a bond extended from the adjacent —CO₂—, and the other straight line with an open end shows a bond extended from the adjacent group Z¹.

Examples of the group represented by the following formula:

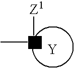

include the followings:

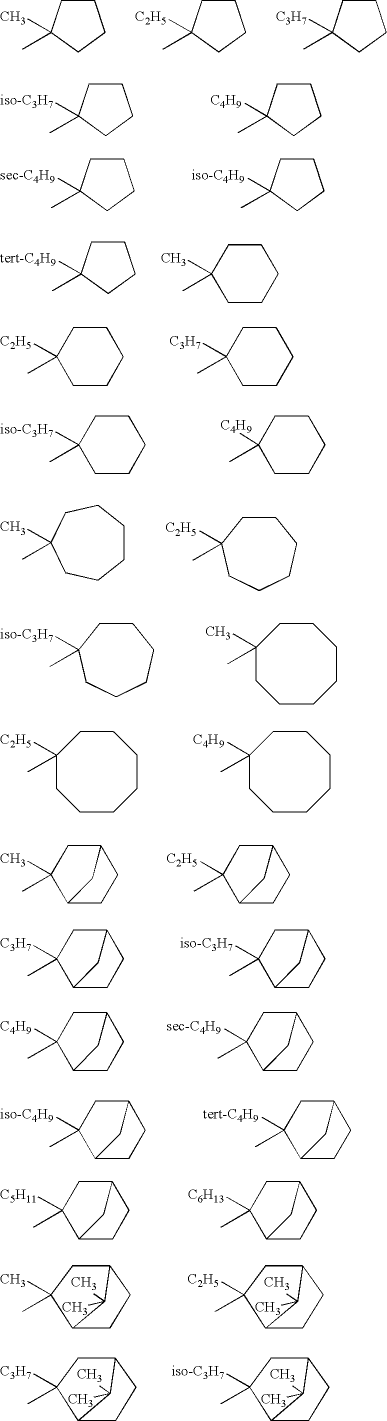

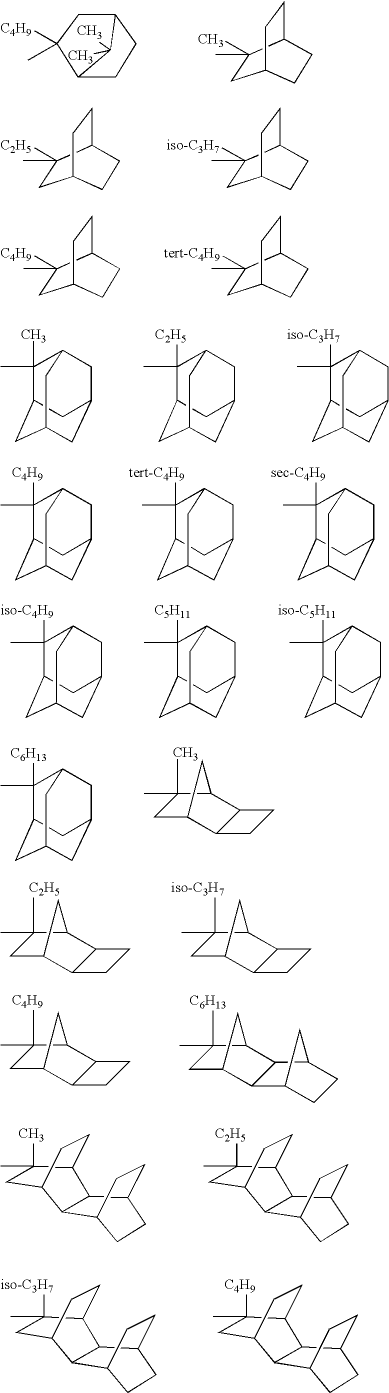

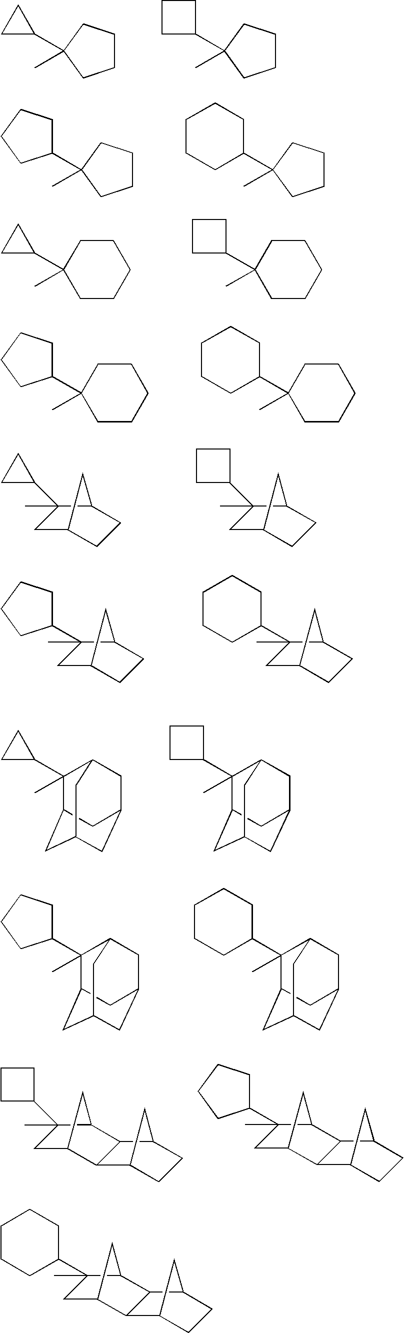

In the above formulae, a straight line with an open end shows a bond extended from the adjacent —CO₂—.

Preferable examples thereof include the followings:

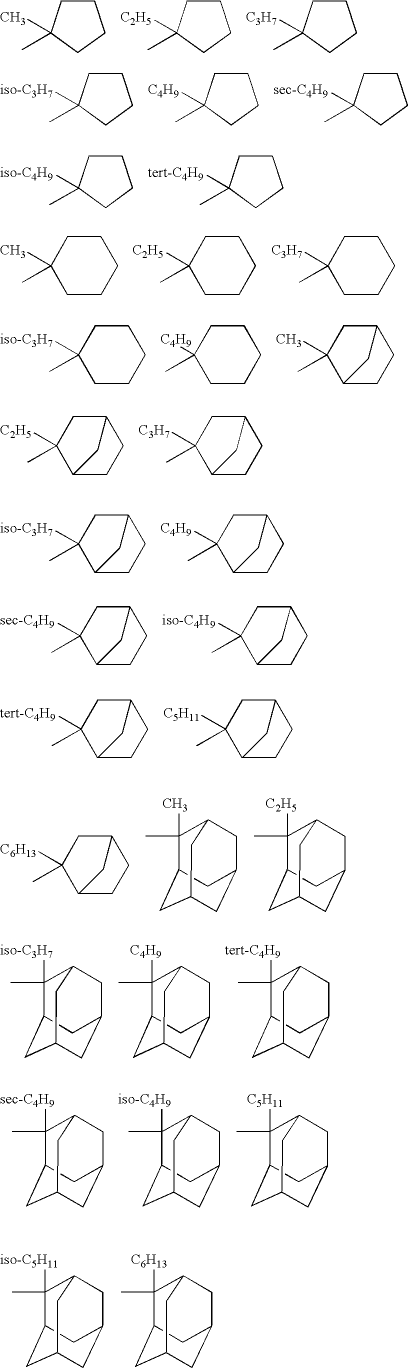

In the above formulae, a straight line with an open end shows a bond extended from the adjacent —CO₂—.

Examples of the polyhydric phenol compound (1) include the polyhydric phenol compound wherein any one of R¹, R², R³, R⁴, and R⁵ is the group (2) and the other four groups are hydrogen atoms; the polyhydric phenol compound wherein any two of R¹, R², R³, R⁴, and R⁵ are the groups (2) and the other three groups are hydrogen atoms;

the polyhydric phenol compound wherein any three of R¹, R², R³, R⁴, and R⁵ are the groups (2) and the other two groups are hydrogen atoms;
the polyhydric phenol compound wherein any four of R¹, R², R³, R⁴, and R⁵ are groups (2) and the other group is a hydrogen atom; and the polyhydric phenol compound wherein all of R¹, R², R³, R⁴, and R⁵ are the groups (2).

Preferred are the polyhydric phenol compound (1) wherein any one of R¹, R², R³, R⁴, and R⁵ is the group (2) and the other four groups are hydrogen atoms; the polyhydric phenol compound (1) wherein any two of R¹, R², R³, R⁴, and R⁵ are the groups (2) and the other three groups are hydrogen atoms; and the polyhydric phenol compound (1) wherein any three of R¹, R², R³, R⁴, and R⁵ are the groups (2) and the other two groups are hydrogen atoms.

The molecular weight of the polyhydric phenol compound (1) is usually 730 to 5,000, preferably 750 to 4, 500 and more preferably 800 to 4,000.

The polyhydric phenol compound (1) can be produced by a reaction of a compound represented by the formula (3):

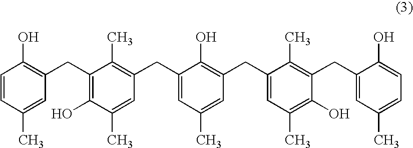

(hereinafter, simply referred to as the compound (3)) and a compound represented by the formula (4):

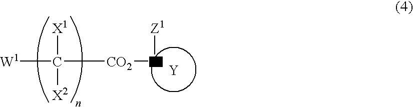

wherein X¹, X², n, Z¹ and Y are the same as defined above, and W¹ represents a chlorine atom, a bromine atom, an iodine atom, a methanesulfonyloxy group or a p-toluenesulfonyloxy group (hereinafter, simply referred to as the compound (4)).

The compound (3) can be produced according to the method described in U.S. Pat. No. 5,866,724A.

As the compound (4), commercially available one may be used and one produced by a known method may be used.

The reaction of the compound (3) and the compound (4) is usually conducted in an inert solvent such as toluene, tetrahydrofuran, N,N-dimethylformamide and dimethylsulfoxide. The reaction temperature is usually −30 to 200° C., preferably 0 to 150° C.

The used amount of the compound (4) is usually 1 to 6 moles, and preferably 1 to 4 moles relative to 1 mole of the compound (3).

The reaction is preferably conducted in the presence of a base. Examples of the base include an organic base such as triethylamine, pyridine, sodium methoxide, sodium ethoxide and potassium tert-butoxide; and an inorganic base such as sodium hydride, potassium carbonate and sodium hydroxide. These bases may be used alone and a mixture thereof may be used. The used amount of the base is usually 1 to 6 moles, and preferably 1 to 4 moles relative to 1 mole of the compound (3).

The reaction may be conducted in the presence of a phase transfer catalyst such as tetrabutylammonium bromide. The reaction may also be conducted in the presence of an iodide compound such as potassium iodide.

After completion of the reaction, the polyhydric phenol compound (1) can be isolated, for example, by conducting extraction treatment of the reaction mixture and then concentrating the organic layer obtained. The polyhydric phenol compound (1) isolated may be further purified by a conventional purification means such as column chromatography, recrystallization and distillation.

The polyhydric phenol compound (1) itself is insoluble or poorly soluble in an aqueous alkali solution and becomes soluble in an aqueous alkali solution by the action of an acid.

The present resist composition preferably contains at least two kinds of the polyhydric phenol compound (1). The present resist composition preferably contains the polyhydric phenol compound (1) wherein any two of R¹, R², R³, R⁴, and R⁵ are the groups (2) and the other three groups are hydrogen atoms.

The resist composition containing the polyhydric phenol compound (1) wherein any one of R¹, R², R³, R⁴, and R⁵ is the group (2) and the other four groups are hydrogen atoms and the polyhydric phenol compound (1) wherein any two of R¹, R², R³, R⁴, and R⁵ are the groups (2) and the other three groups are hydrogen atoms;

the resist composition containing the polyhydric phenol compound (1) wherein any one of R¹, R², R³, R⁴, and R⁵ is the group (2) and the other four groups are hydrogen atoms, the polyhydric phenol compound (1) wherein any two of R¹, R², R³, R⁴, and R⁵ are the groups (2) and the other three groups are hydrogen atoms and the polyhydric phenol compound (1) wherein any three of R¹, R², R³, R⁴, and R⁵ are the groups (2) and the other two groups are hydrogen atoms; and

the resist composition containing the polyhydric phenol compound (1) wherein any two of R¹, R², R³, R⁴, and R⁵ are the groups (2) and the other three groups are hydrogen atoms and the polyhydric phenol compound (1) wherein any three of R¹, R², R³, R⁴, and R⁵ are the groups (2) and the other two groups are hydrogen atoms, are preferable.

The present resist composition comprises the resin (A), the polyhydric phenol compound (1) and an acid generator.

The weight ratio of the resin (A) to the polyhydric phenol compound (1) (the resin (A)/the polyhydric phenol compound (1)) is usually 1/99 to 99/1, preferably 1/9 to 50/1, and more preferably 1/1 to 9/1.

The present resist composition may contain two or more kinds of an acid generator.

The acid generator is a substance which is decomposed to generate an acid by applying a radiation such as a light, an electron beam or the like on the substance itself or on a resist composition containing the substance. The acid generated from the acid generator acts on the resin (A) and the polyhydric phenol compound (1) resulting in dissolving the resin (A) and the polyhydric phenol compound (1) in an alkali aqueous solution.

Examples of the acid generator include an onium salt compound, an organo-halogen compound, a sulfone compound and a sulfonate compound. The onium salt compound is preferable. The acid generators described in JP 2003-5374 A such as an acid generator represented by the following formula:

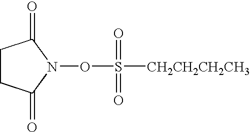

can be used.

A compound represented by the formula:

A⁺B⁻

wherein A⁺ represents an organic counter cation and B⁻ represents a counter anion, are also used as an acid generator. Examples of the counter anion include BF₄⁻, AsF₆⁻, PF₆⁻, SbF₆⁻, SiF₆²⁻, ClO₄⁻, a perfluoroalkanesulfonic acid anion such as CF₃SO₃⁻, pentafluorobenzenesulfonic acid anion, a condensed polynuclear aromatic sulfonic acid anion such as naphthalene-1-sulfonic acid anion, anthraquinonesulfonic acid anion, and a dye containing a sulfonic acid group. Additionally, anions described in JP 2003-5374 A1 such as an anion represented by the following formula:

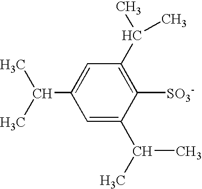

are also listed as the counter anion.

Examples of the preferable acid generator include a salt represented by the formula (V):

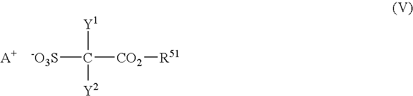

wherein A⁺ represents an organic counter ion, Y¹ and Y² each independently represent a fluorine atom or a C1-C6 perfluoroalkyl group, R⁵¹ represents a C1-C30 hydrocarbon group which may have one or more substituents selected from the group consisting of a C1-C6 alkoxy group, a C1-C4 perfluoroalkyl group, a C1-C6 hydroxyalkyl group, a hydroxyl group and a cyano group, and in which one or more —CH₂— may be replace by —CO— or —O— (hereinafter, simply referred to as Salt (V)).

Examples of the C1-C6 perfluoroalkyl group represented by Y¹ and Y² include a trifluoromethyl group, a pentafluoroethyl group, a heptafluoropropyl group, a nonafluorobutyl group, an undecafluoropentyl group and a tridecafluorohexyl group, and a trifluoromethyl group is preferable. Y¹ and Y² each independently is preferably a fluorine atom or a trifluoromethyl group, and Y¹ and Y² are more preferably fluorine atoms.

Examples of the C1-C30 hydrocarbon group include a linear or branched chain C1-C30 hydrocarbon group such as a methyl group, an ethyl group, a propyl group, an isopropyl group, a butyl group, an isobutyl group, a sec-butyl group, a tert-butyl group, a pentyl group and a hexyl group, and a C3-C30 monocyclic or polycyclic hydrocarbon group such as a hydrocarbon group having a cyclobutane ring, a hydrocarbon group having a cyclopentane ring, a hydrocarbon group having a cyclohexane ring, a hydrocarbon group having a cyclooctane ring, a hydrocarbon group having an adamantane ring, a hydrocarbon group having a benzene ring and a hydrocarbon group having a norbornane ring. The C3-C30 monocyclic or polycyclic hydrocarbon group may have an alicyclic structure or structures and may have an aromatic group or groups. The C3-C30 monocyclic or polycyclic hydrocarbon group may have a carbon-carbon double bond or bonds.

The C1-C30 hydrocarbon group may have one or more substituents selected from the group consisting of a C1-C6 alkoxy group, a C1-C4 perfluoroalkyl group, a C1-C6 hydroxyalkyl group, a hydroxyl group and a cyano group. Examples of the C1-C6 alkoxy group include a methoxy group, an ethoxy group, a propoxy group, an isopropoxy group, a butoxy group, an isobutoxy group, a sec-butoxy group, a tert-butoxy group, a pentyloxy group and a hexyloxy group. Examples of the C1-C4 perfluoroalkyl group include a trifluoromethyl group, a pentafluoroethyl group, a heptafluoropropyl group and a nonafluorobutyl group. Examples of the C1-C6 hydroxyalkyl group include a hydroxymethyl group, a 2-hydroxyethyl group, a 3-hydroxypropyl group, a 4-hydroxybutyl group and a 6-hydroxyhexyl group.

Specific examples of the anion part of Salt (V) include the followings.

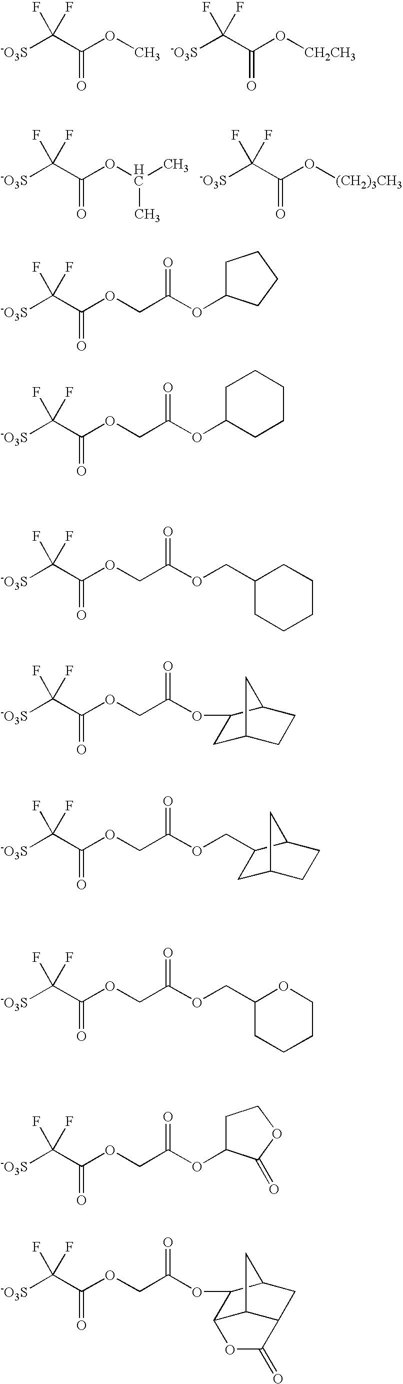

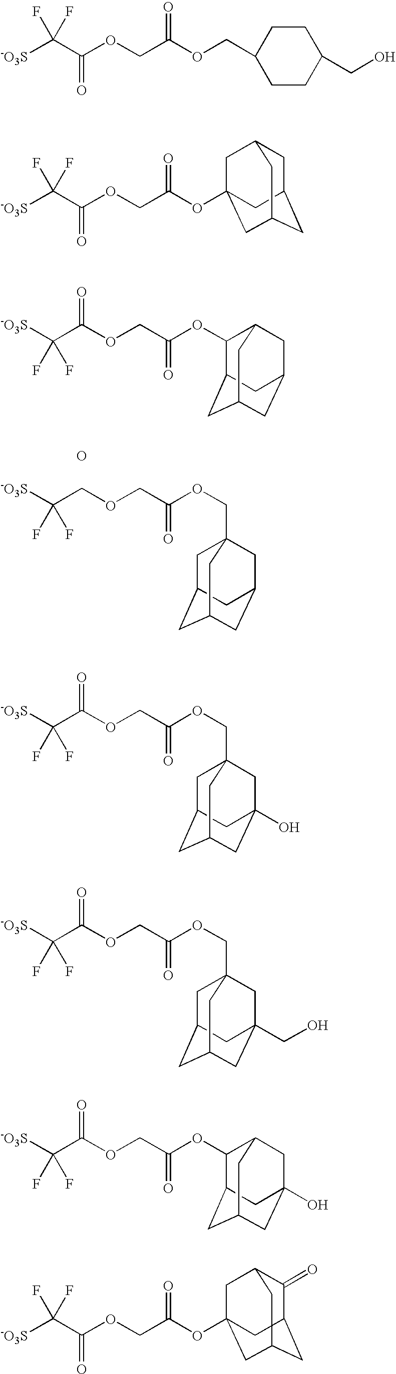

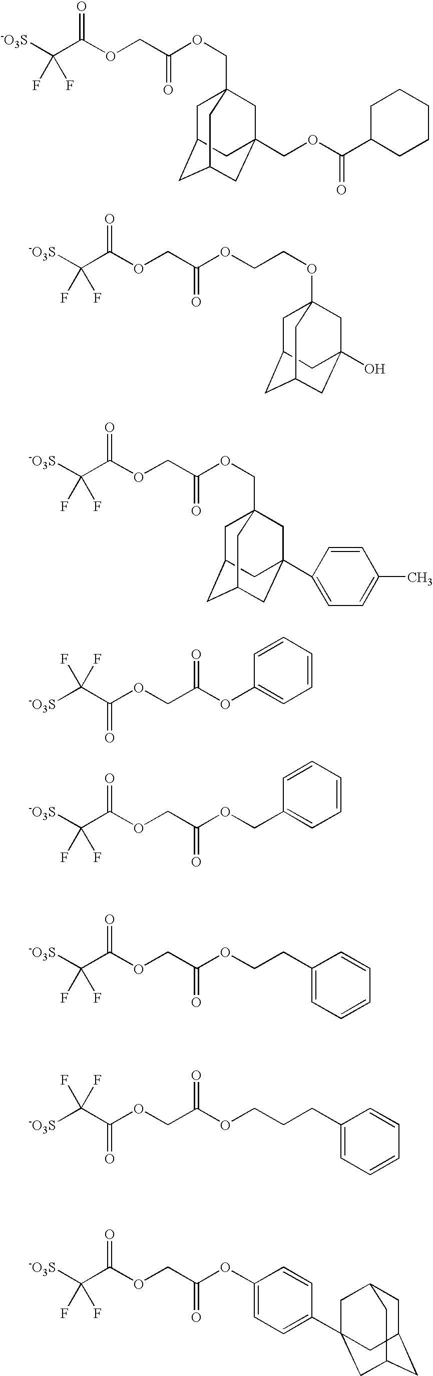

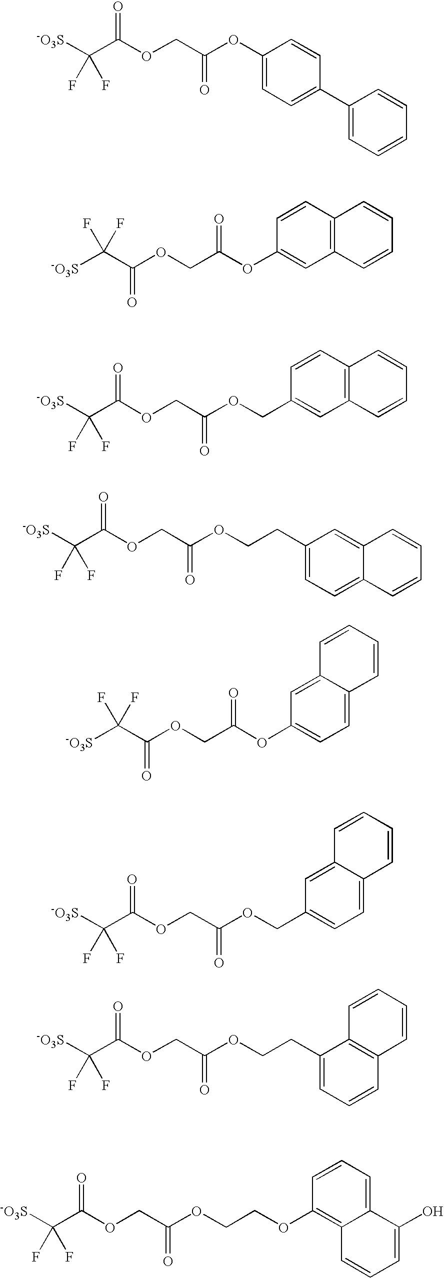

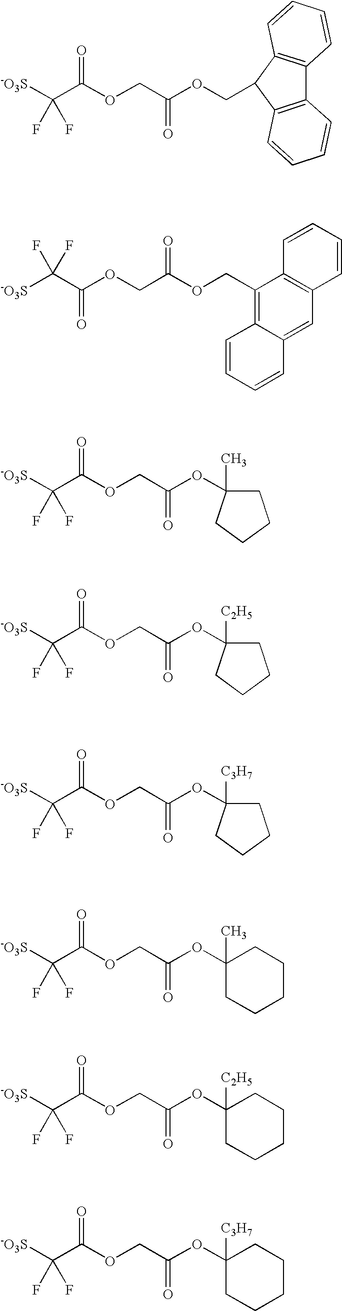

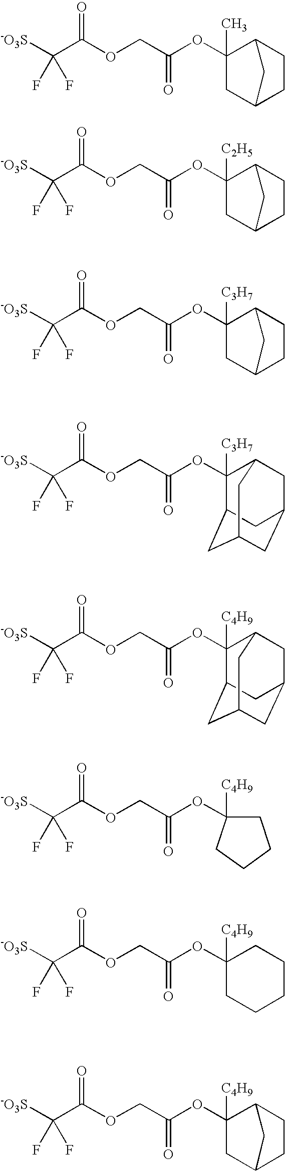

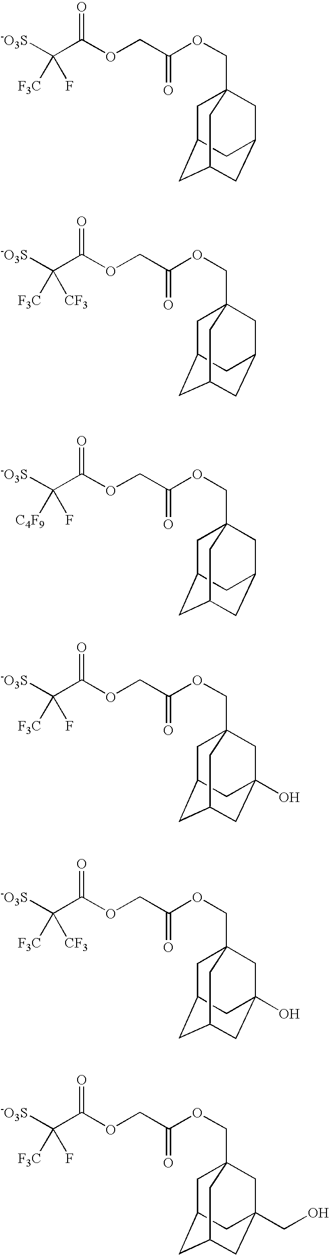

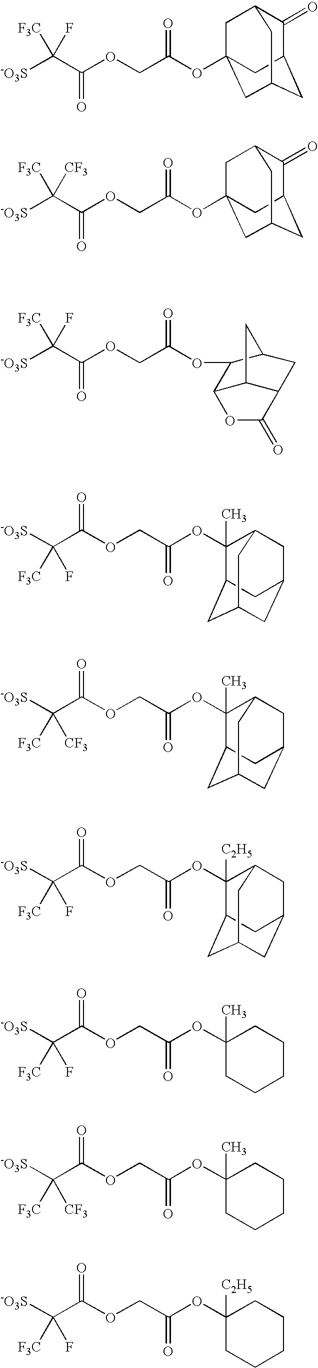

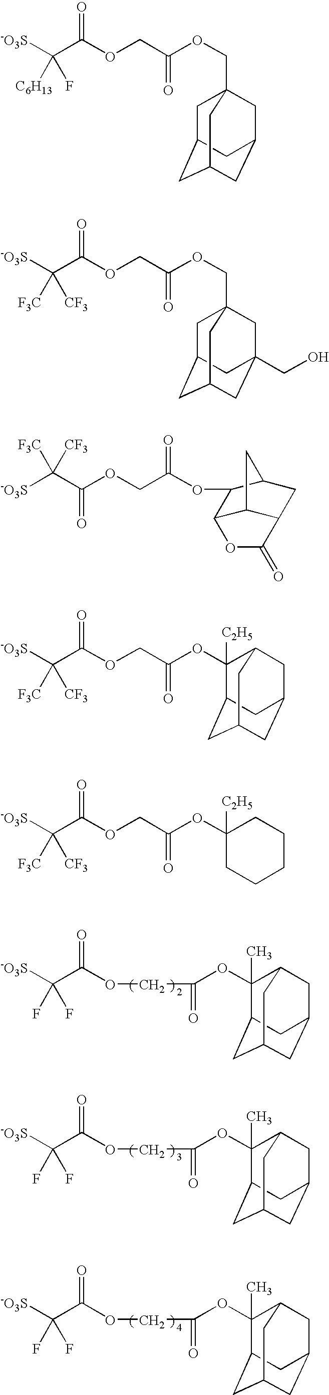

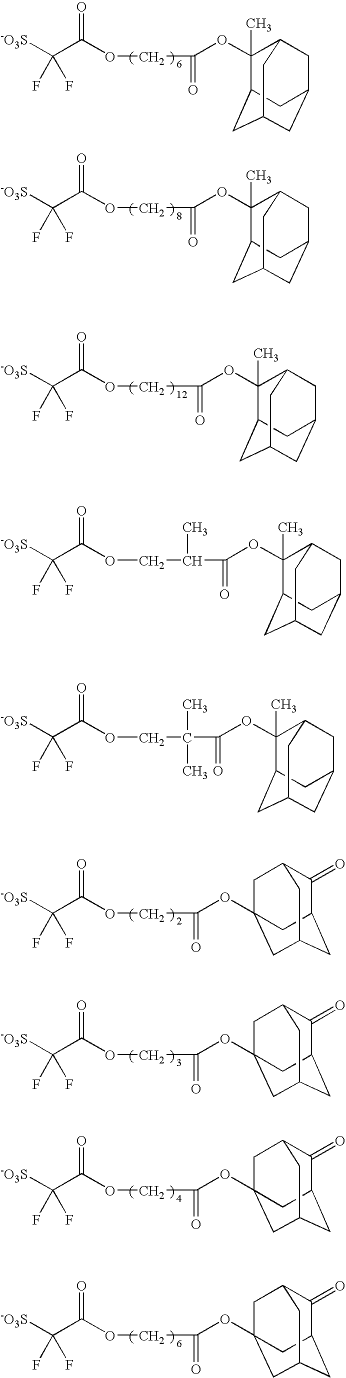

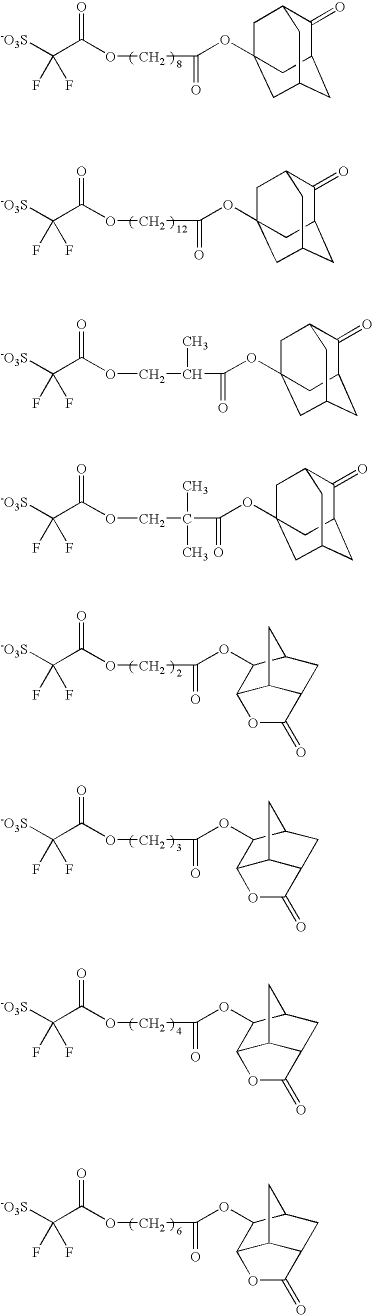

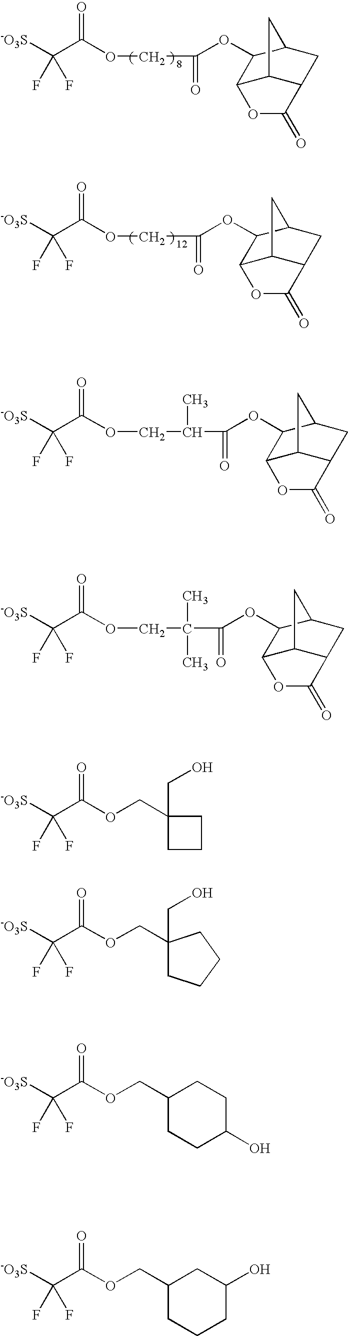

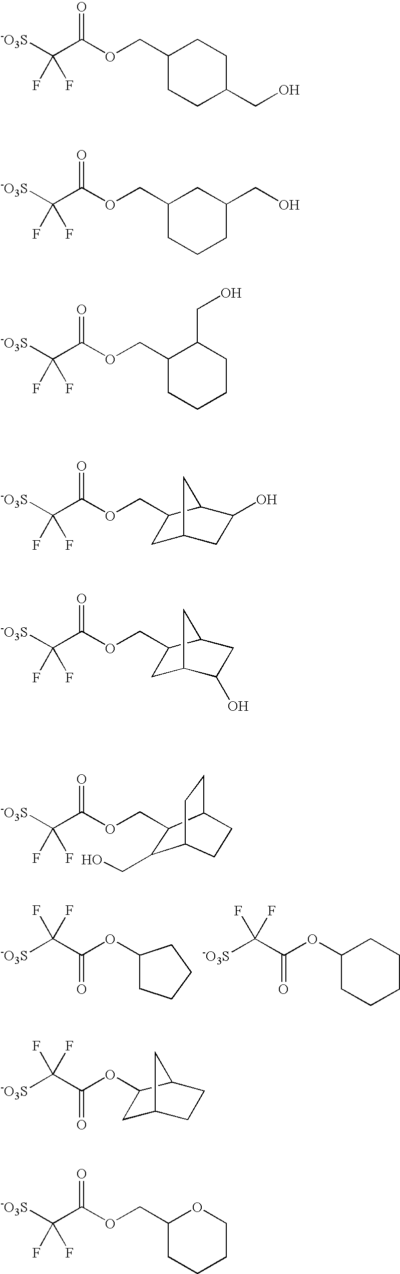

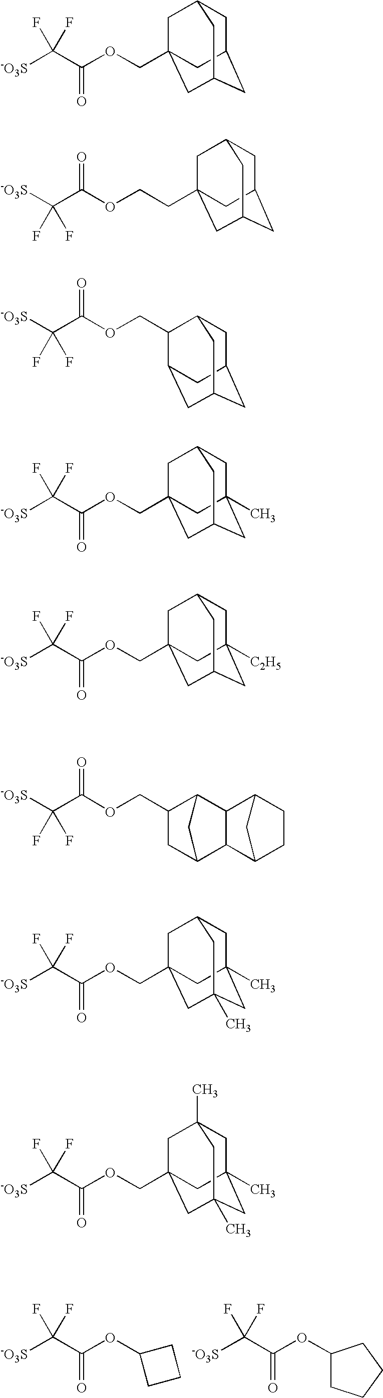

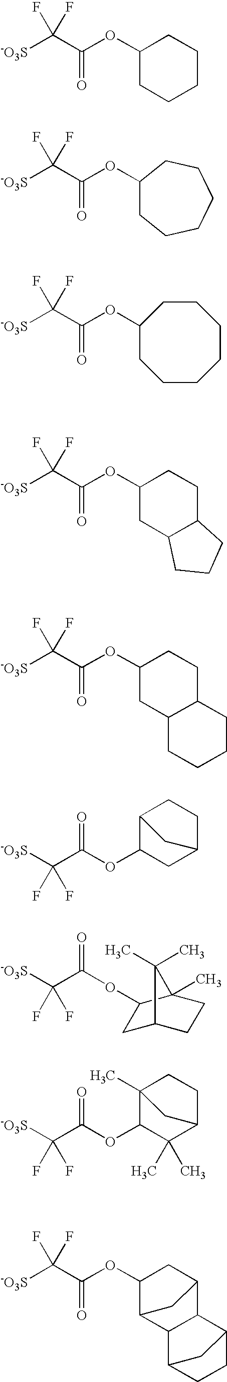

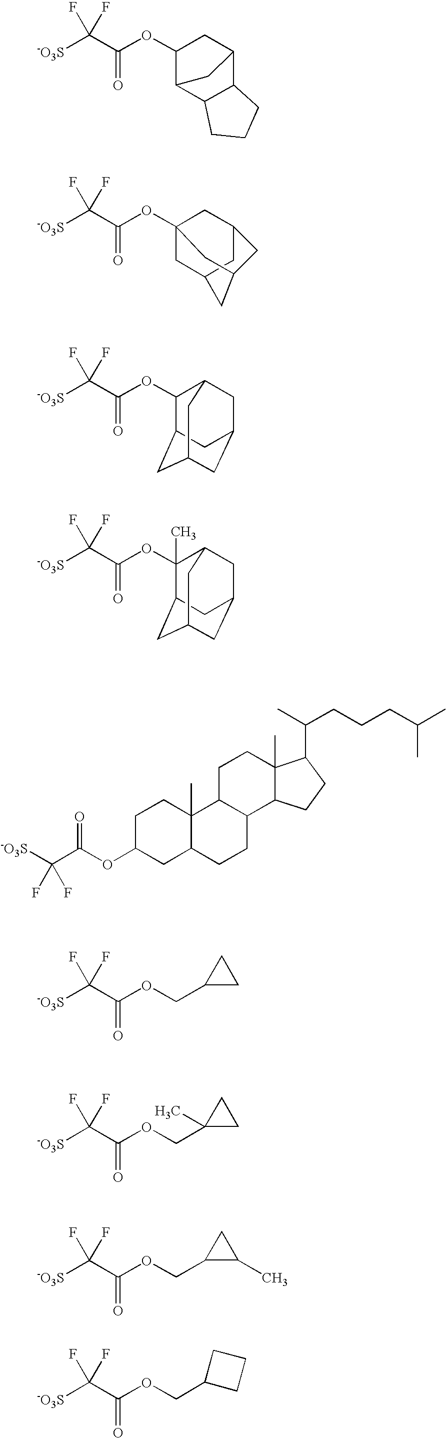

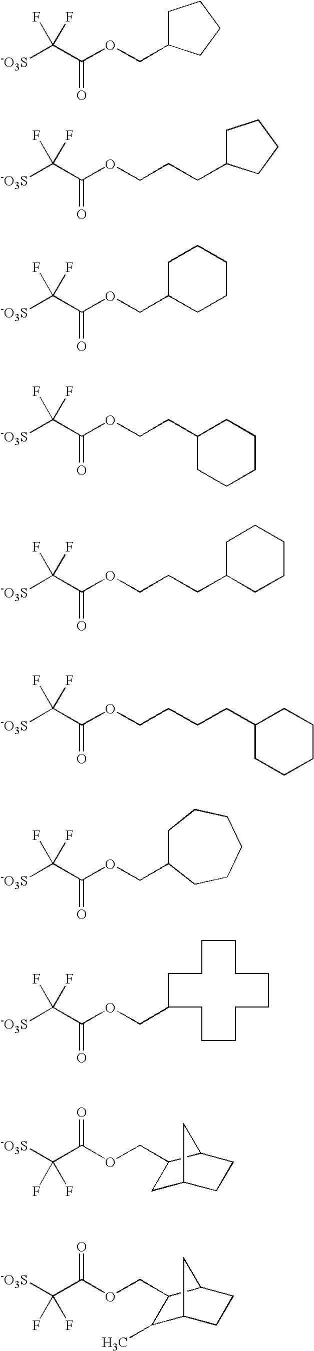

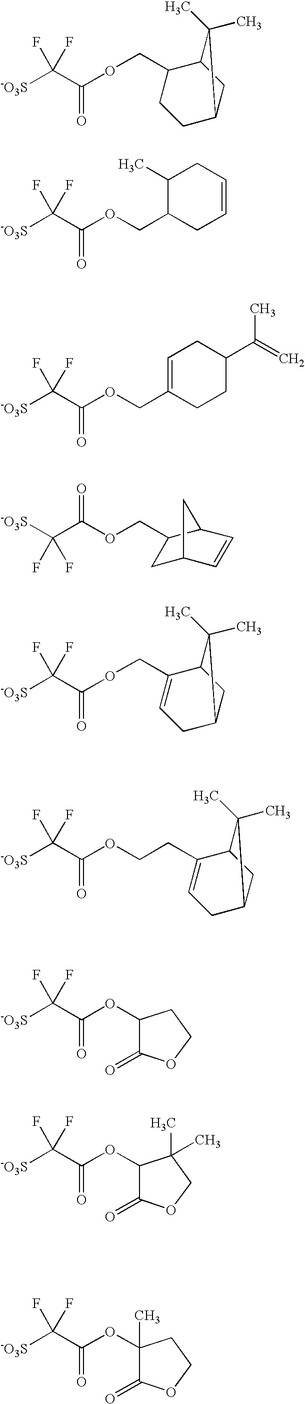

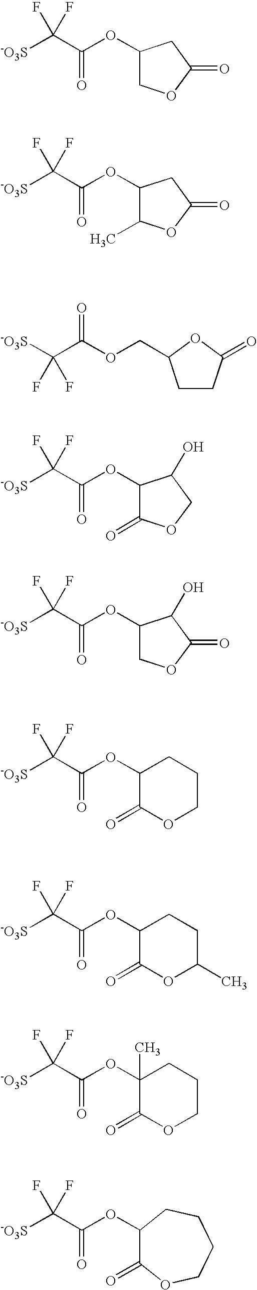

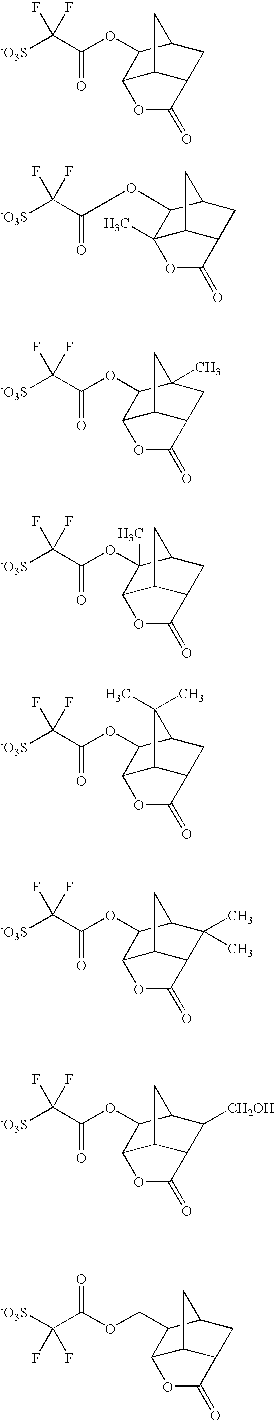

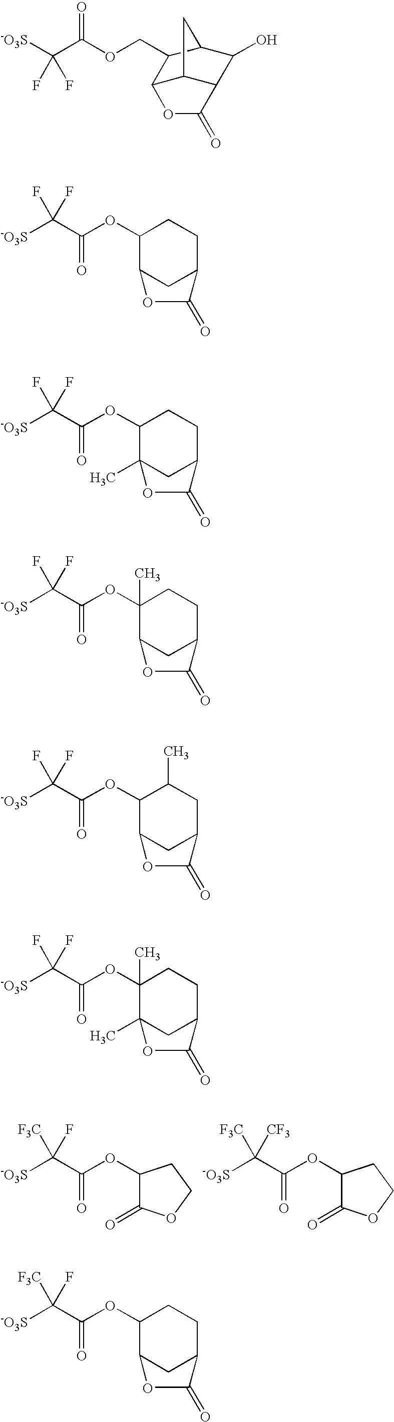

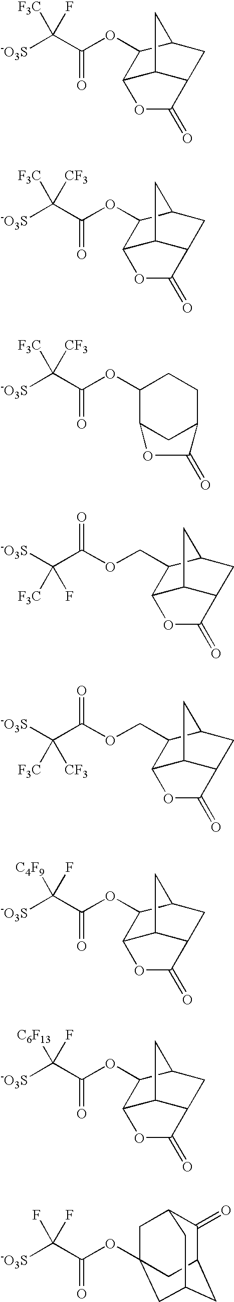

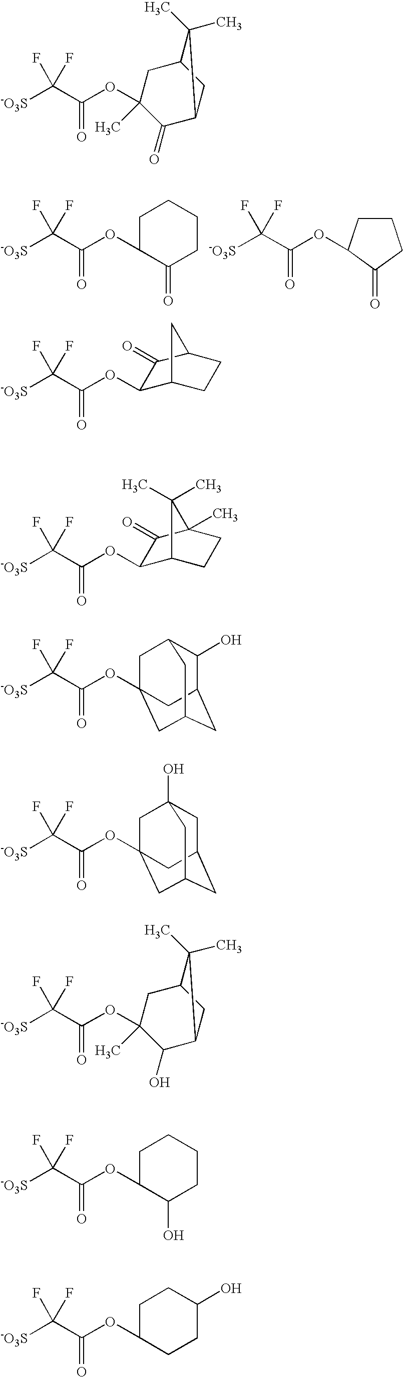

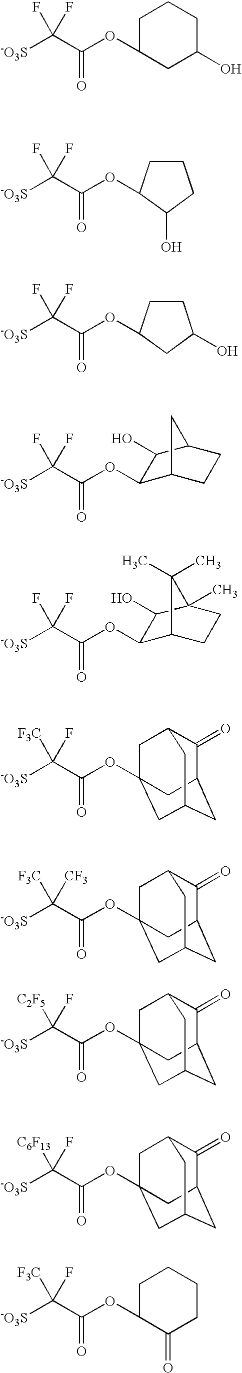

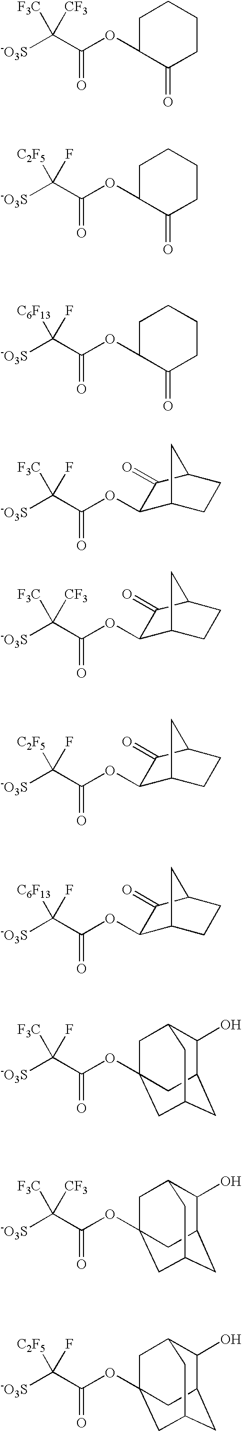

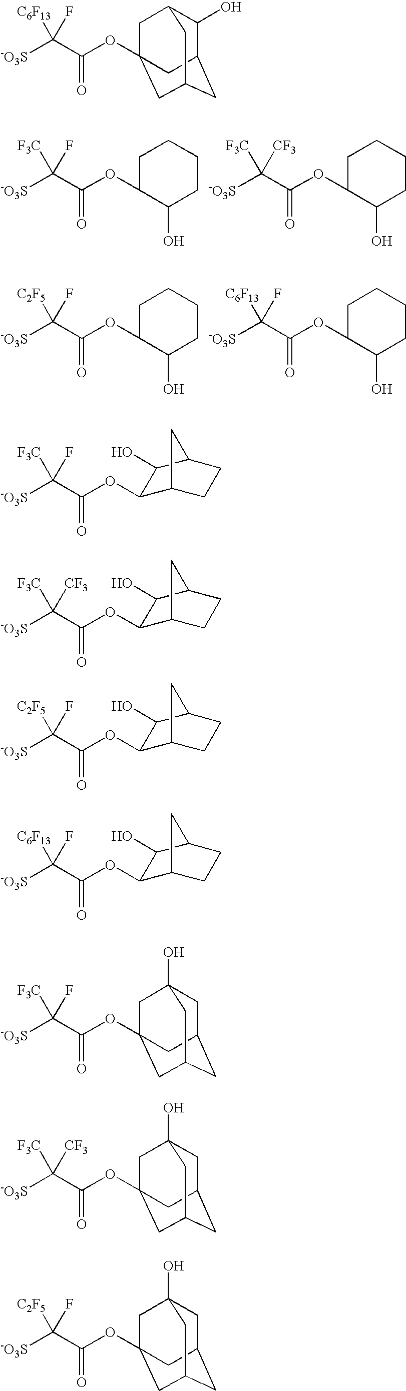

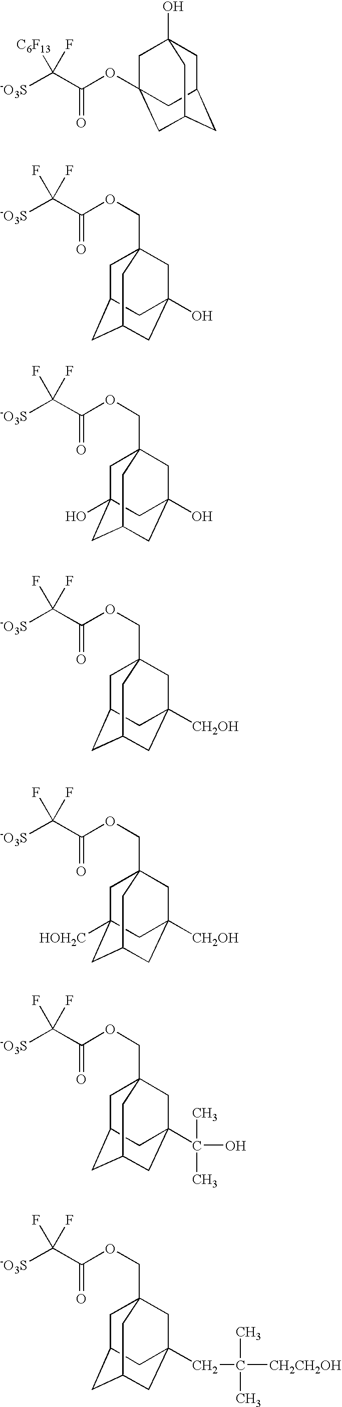

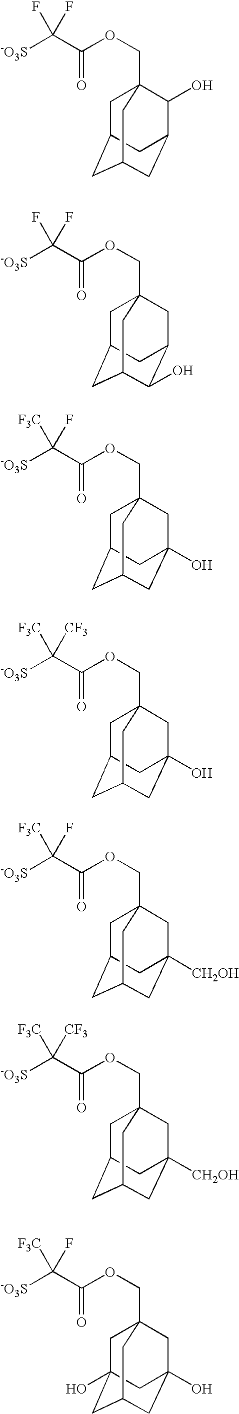

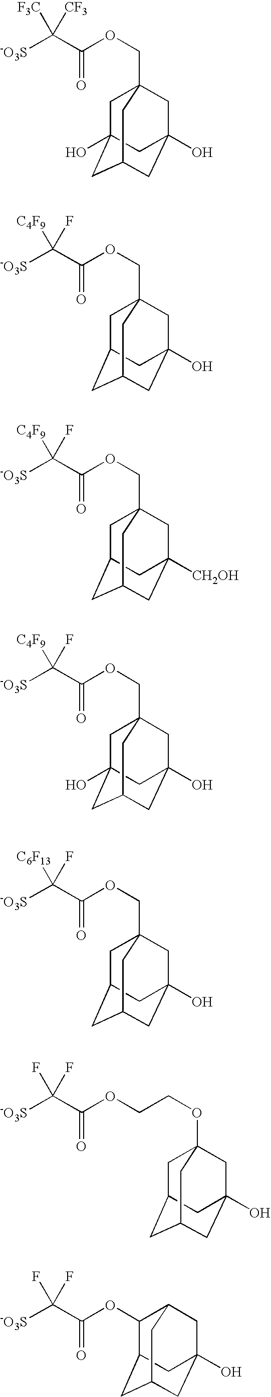

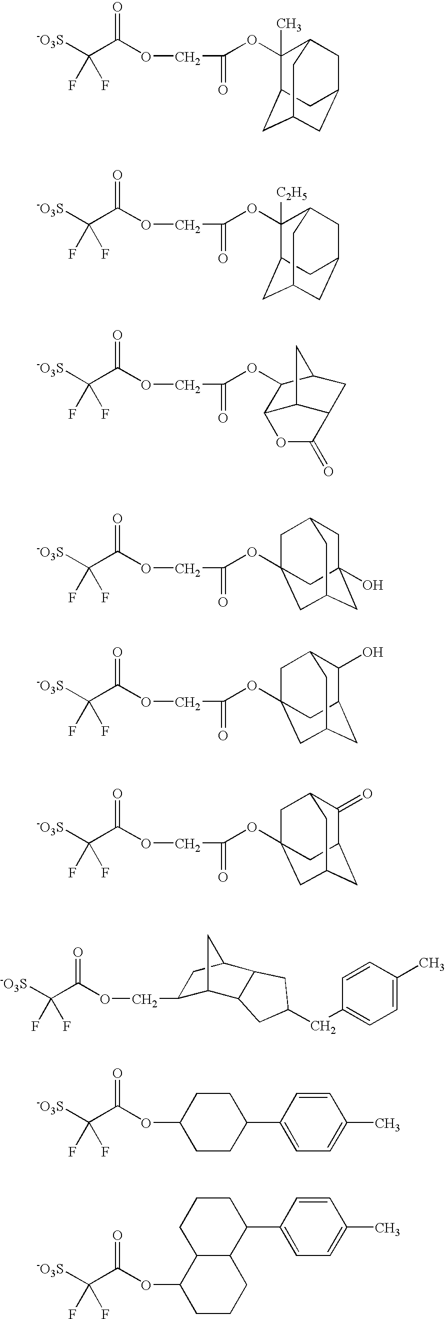

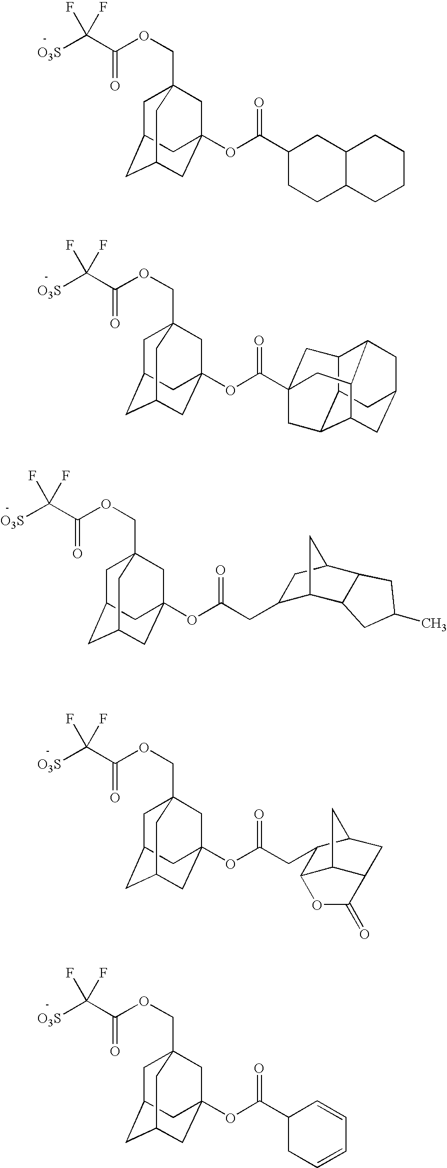

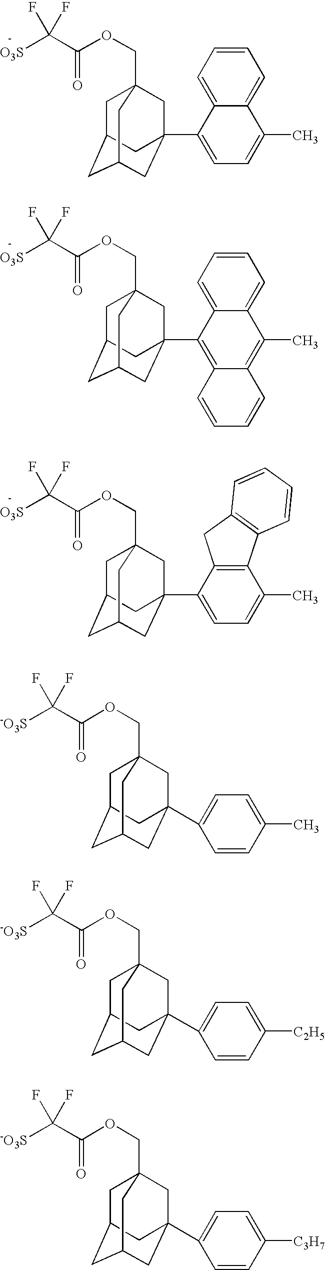

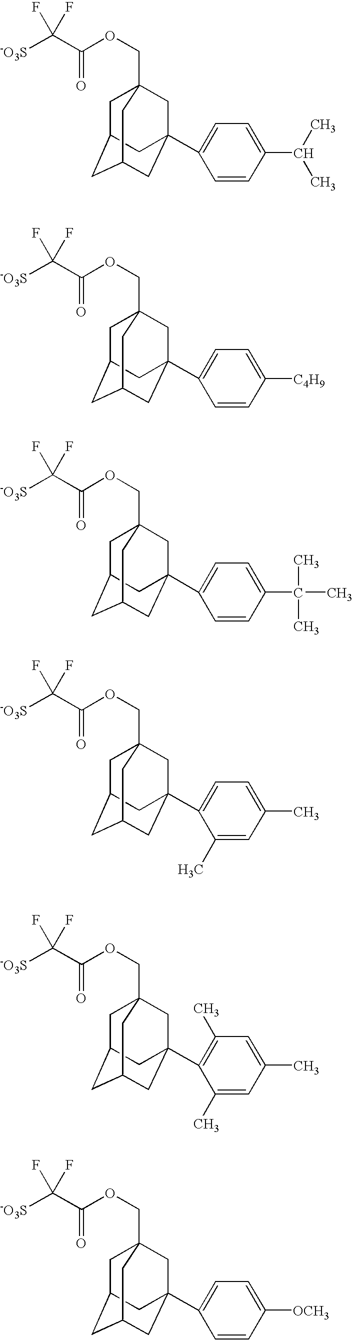

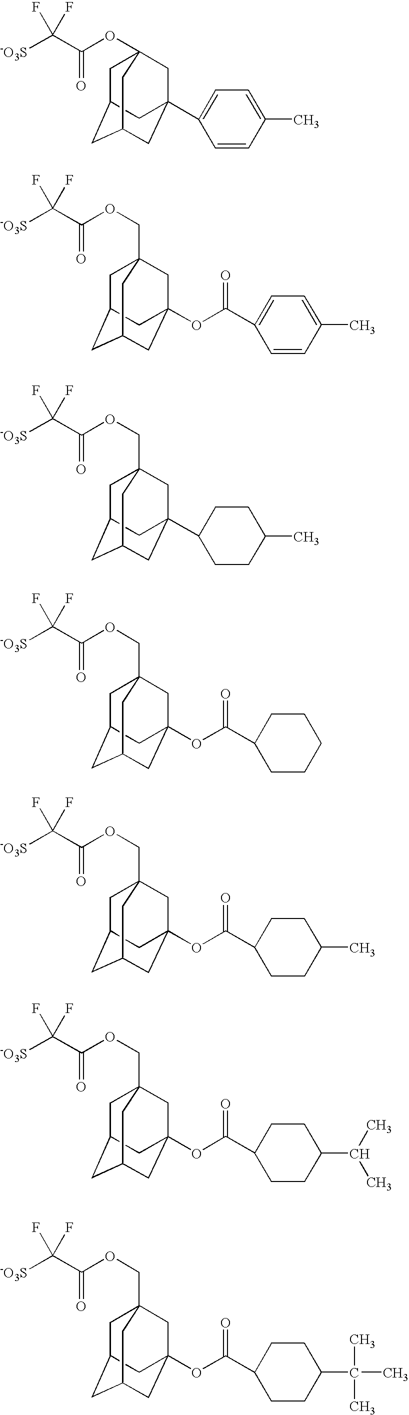

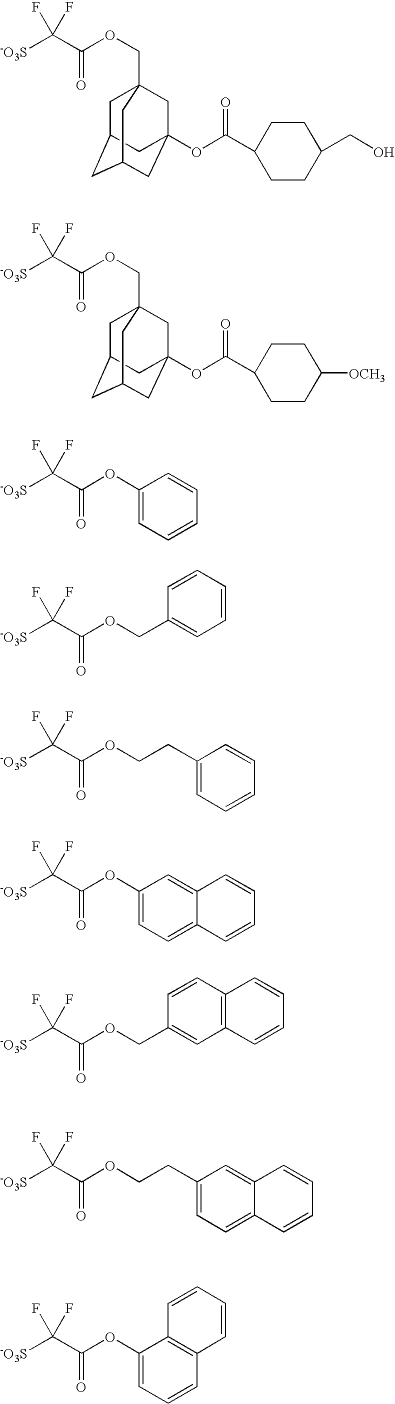

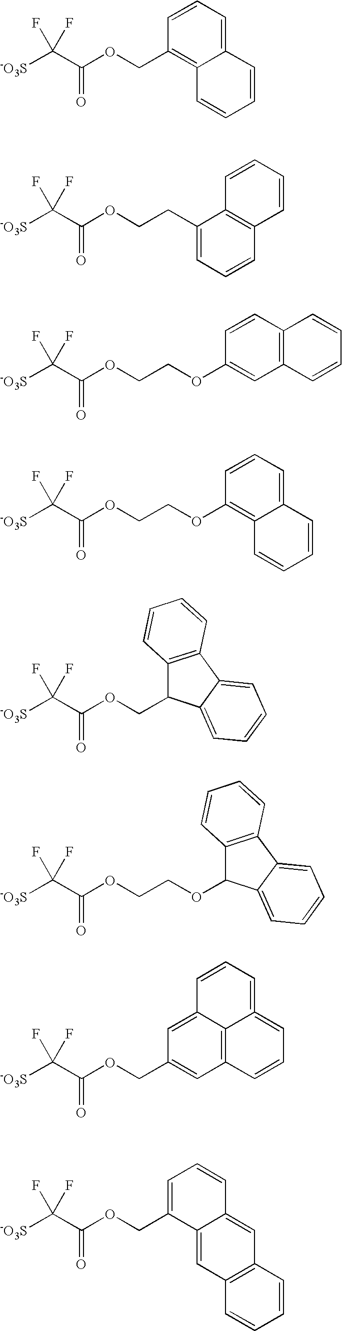

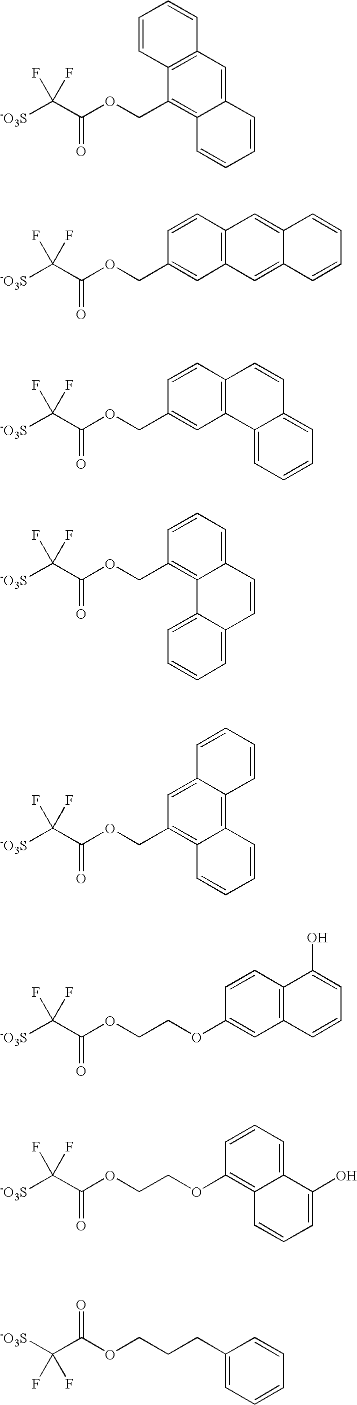

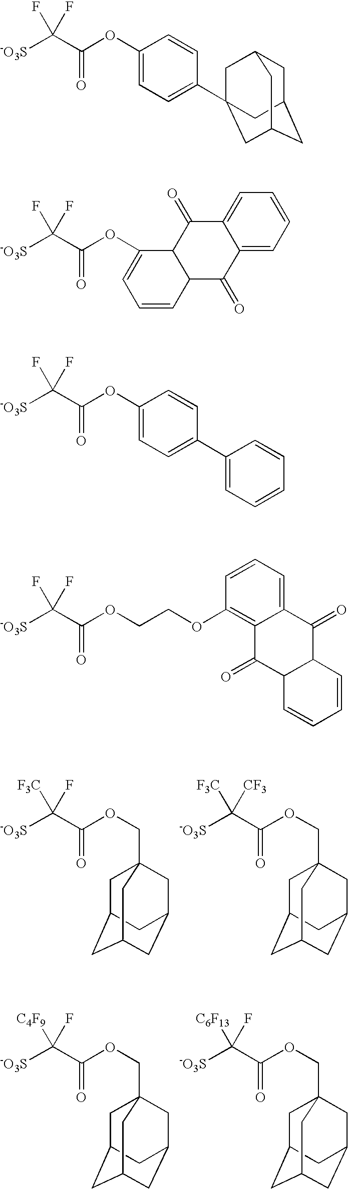

Among Salt (V), a salt represented by the formula (VI):

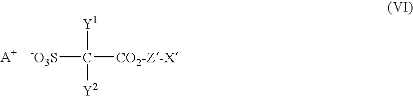

wherein Y¹, Y² and A⁺ are the same meanings as defined above, Z′ represents a single bond or a C1-C4 alkylene group, and X′ represents a C3-C30 monocyclic or polycyclic hydrocarbon group having a hydroxyl group or a carbonyl group, and one or more hydrogen atoms in the monocyclic or polycyclic hydrocarbon group may be replaced by a C1-C6 alkoxy group, a C1-C4 perfluoroalkyl group, a C1-C6 hydroxyalkyl group, a hydroxyl group or a cyano group (hereinafter, simply referred to as Salt (VI)) is preferable.

Examples of the C1-C6 alkoxy group, the C1-C4 perfluoroalkyl group and the C1-C6 hydroxyalkyl group in X′ include the same groups as described above, respectively.

Examples of the C1-C4 alkylene group in Z′ include a methylene group, an ethylene group, a trimethylene group and a tetramethylene group. Z′ is preferably a single bond, a methylene group or an ethylene group, and is more preferably a single bond or a methylene group.

Examples of X′ include a C4-C8 cycloalkyl group such as a cyclobutyl group, a cyclopentyl group, a cyclohexyl group and a cyclooctyl group, an adamantyl group, and a norbornyl group, in all of which one or more hydrogen atoms may be replaced by the C1-C6 alkoxy group, the C1-C4 perfluoroalkyl group, the C1-C6 hydroxyalkyl group, a hydroxyl group or a cyano group.

Specific examples of X′ include a 2-oxocyclopentyl group, a 2-oxocyclohexyl group, a 3-oxocyclopentyl group, a 3-oxocyclohexyl group, a 4-oxocyclohexyl group, a 2-hydroxycyclopentyl group, a 2-hydroxycyclohexyl group, a 3-hydroxycyclopentyl group, a 3-hydroxycyclohexyl group, a 4-hydroxycyclohexyl group, a 4-oxo-2-adamantyl group, a 3-hydroxy-1-adamantyl group, a 4-hydroxy-1-adamantyl group, a 5-oxonorbornan-2-yl group, a 1,7,7-trimethyl-2-oxonorbornan-2-yl group, a 3,6,6-trimethyl-2-oxo-bicyclo[3.1.1]heptan-3-yl group, a 2-hydroxy-norbornan-3-yl group, a 1,7,7-trimethyl-2-hydroxynorbornan-3-yl group, a 3,6,6-trimethyl-2-hydroxybicyclo[3.1.1]heptan-3-yl group, and the following groups (in the following formulae, straight line with an open end shows a bond which is extended from an adjacent group).

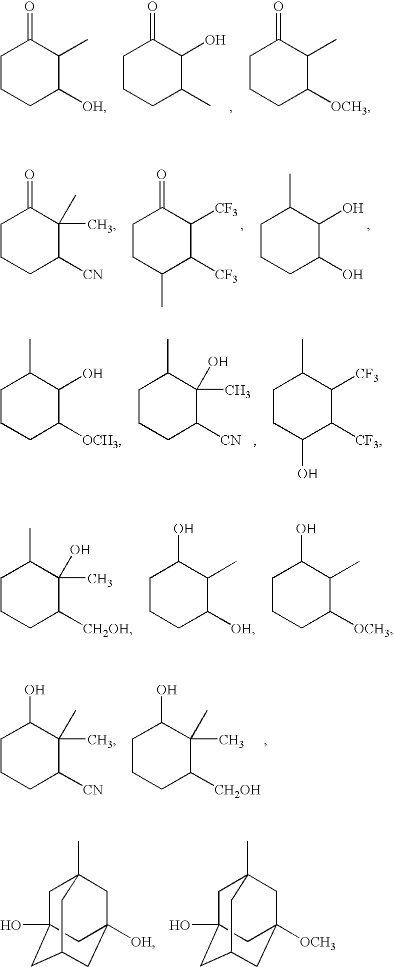

Specific examples of the anion part of Salt (VI) include the followings.

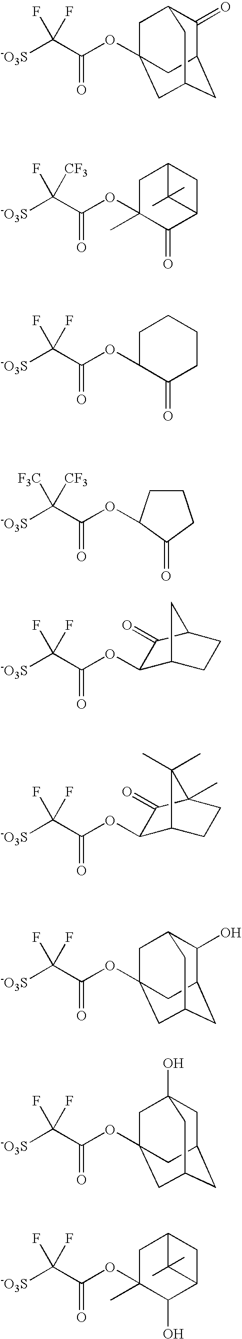

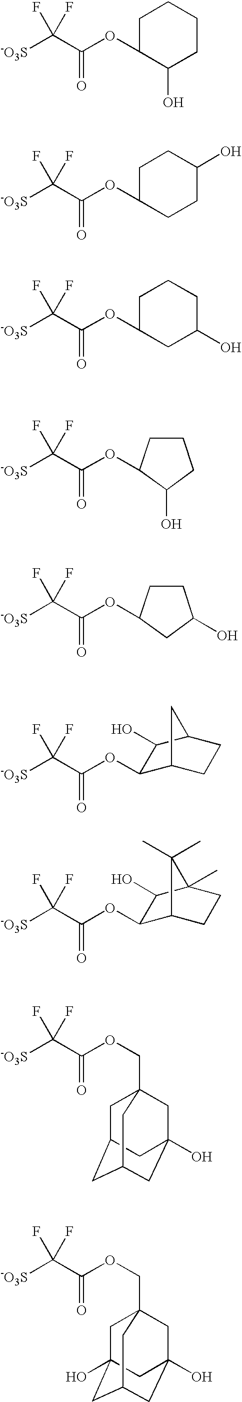

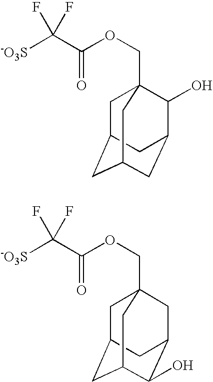

Other examples of the acid generator include a salt represented by the formula (VIII):

A⁺⁻O₃S—R⁵² (VIII)

wherein R⁵² represents a linear or branched chain C1-C6 perfluoroalkyl group and A⁺ is the same as defined above (hereinafter, simply referred to as Salt (VIII)).

In Salt (VIII), examples of the linear or branched chain C1-C6 perfluoroalkyl group include a trifluoromethyl group, a pentafluoroethyl group, a heptafluoropropyl group, a nonafluorobutyl group and a tridecafluorohexyl group.

Specific examples of the anion part of Salt (VIII) include the followings.

CF₃—SO₃⁻

CF₃CF₂CF₂—SO₃⁻

CF₃CF₂CF₂CF₂SO₃⁻

CF₃CF₂CF₂CF₂CF₂CF₂—SO₃⁻

In Salt (V), Salt (VI) and Salt (VIII), A⁺ represents an organic counter ion. Examples of the organic counter ion include a cation represented by the formula (IXz):

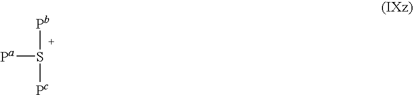

wherein P^{a}, P^{b} and P^{c} each independently represent a C1-C30 linear or branched chain alkyl group which may have one or more substituents selected from the group consisting of a hydroxyl group, a C3-C12 cyclic hydrocarbon group and a C1-C12 alkoxy group, or a C3-C30 cyclic hydrocarbon group which may have one or more substituents selected from the group consisting of a hydroxyl group and a C1-C12 alkoxy group (hereinafter, simply referred to as the cation (IXz)), a cation represented by the formula (IXb):

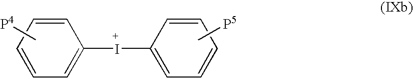

wherein P⁴ and P⁵ each independently represent a hydrogen atom, a hydroxyl group, a C1-C12 alkyl group or a C1-C12 alkoxy group (hereinafter, simply referred to as the cation (IXb)), a cation represented by the formula (IXc):

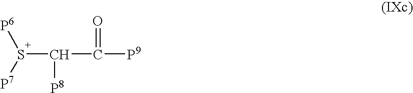

wherein P⁶ and P⁷ each independently represent a C1-C12 alkyl group or a C3-C12 cycloalkyl group, or P⁶ and P⁷ are bonded to form a C3-C12 divalent acyclic hydrocarbon group which forms a ring together with the adjacent S⁺, and one or more —CH₂— in the divalent acyclic hydrocarbon group may be replaced by —CO—, —O— or —S—, P⁸ represents a hydrogen atom, P⁹ represents a C1-C12 alkyl group, a C3-C12 cycloalkyl group or an aromatic group which may have one or more substituents, or P⁸ and P⁹ are bonded to form a divalent acyclic hydrocarbon group which forms a 2-oxocycloalkyl group together with the adjacent —CHCO—, and one or more —CH₂— in the divalent acyclic hydrocarbon group may be replaced by —CO—, —O— or —S— (hereinafter, simply referred to as the cation (IXc)); and a cation represented by the formula (IXd):

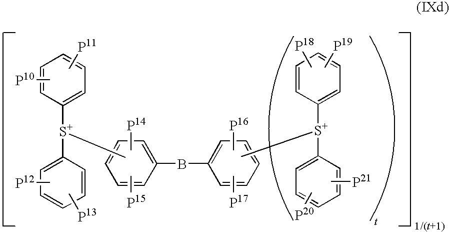

wherein P¹⁰, P¹¹, P¹², P¹³, P¹⁴, P¹⁵, P¹⁶, P¹⁷, P¹⁸, P¹⁹, P²⁰ and P²¹ each independently represent a hydrogen atom, a hydroxyl group, a C1-C12 alkyl group or a C1-C12 alkoxy group, B represents a sulfur atom or an oxygen atom and t represents 0 or 1 (hereinafter, simply referred to as the cation (IXd)).

Examples of the C1-C12 alkoxy group in the cations (IXz), (IXb) and (IXd) include a methoxy group, an ethoxy group, a propoxy group, an isopropoxy group, a butoxy group, an isobutoxy group, a sec-butoxy group, a tert-butoxy group, a pentyloxy group, a hexyloxy group, a octyloxy group and a 2-ethylhexyloxy group.

Examples of the C3-C12 cyclic hydrocarbon group in the cation (IXz) include a cyclopentyl group, a cyclohexyl group, a 1-adamantyl group, a 2-adamantyl group, a phenyl group, a 2-methylphenyl group, a 4-methylphenyl group, a 1-naphthyl group and a 2-naphthyl group.

Examples of the C1-C30 alkyl group which may have one or more substituents selected from the group consisting of a hydroxyl group, a C3-C12 cyclic hydrocarbon group and a C1-C12 alkoxy group in the cation (IXz) include a methyl group, an ethyl group, a propyl group, an isopropyl group, a butyl group, an isobutyl group, a sec-butyl group, a tert-butyl group, a pentyl group, a hexyl group, a octyl group, a 2-ethylhexyl group and a benzyl group.

Examples of the C3-C30 cyclic hydrocarbon group which may have one or more substituents selected from the group consisting of a hydroxyl group and a C1-C12 alkoxy group in the cation (IXz) include a cyclopentyl group, a cyclohexyl group, a 1-adamantyl group, a 2-adamantyl group, a bicyclohexyl group, a phenyl group, a 2-methylphenyl group, a 4-methylphenyl group, a 4-ethylphenyl group, a 4-isopropylphenyl group, a 4-tert-butylphenyl group, a 2,4-dimethylphenyl group, a 2,4,6-trimethylphenyl group, a 4-hexylphenyl group, a 4-octylphenyl group, a 1-naphthyl group, a 2-naphthyl group, a fluorenyl group, a 4-phenylphenyl group, a 4-hydroxyphenyl group, a 4-methoxyphenyl group, a 4-tert-butoxyphenyl group and a 4-hexyloxyphenyl group.

Examples of the C1-C12 alkyl group in the cations (IXb), (IXc) and (IXd) include a methyl group, an ethyl group, a propyl group, an isopropyl group, a butyl group, an isobutyl group, a sec-butyl group, a tert-butyl group, a pentyl group, a hexyl group, a octyl group and a 2-ethylhexyl group.

Examples of the C3-C12 cycloalkyl group in the cation (IXc) include a cyclopropyl group, a cyclobutyl group, a cyclopentyl group, a cyclohexyl group, a cycloheptyl group, a cyclooctyl group and a cyclodecyl group. Examples of the C3-C12 divalent acyclic hydrocarbon group formed by bonding P⁶ and P⁷ include a trimethylene group, a tetramethylene group and a pentamethylene group. Examples of the ring group formed together with the adjacent S⁺ and the divalent acyclic hydrocarbon group include a tetramethylenesulfonio group, a pentamethylenesulfonio group and oxybisethylenesulfonio group.

Examples of the aromatic group in the cation (IXc) include a phenyl group, a tolyl group, a xylyl group, a 4-butylphenyl group, a 4-isobutylphenyl group, a 4-tert-butylphenyl group, a 4-cyclohexylphenyl group, a 4-phenylphenyl group, a 1-naphthyl group and a 2-naphthyl group. The aromatic group may have one or more substituents, and examples of the substituents include a C1-C6 alkoxy group such as a methoxy group, an ethoxy group, a propoxy group, a butoxy group, a tert-butoxy group and a hexyloxy group; a C2-C12 acyloxy group such as an acetyloxy group and a 1-adamantylcarbonyloxy group; and a nitro group.

Examples of the divalent acyclic hydrocarbon group formed by bonding P⁸ and P⁹ include a methylene group, an ethylene group, a trimethylene group, a tetramethylene group and a pentamethylene group and examples of the 2-oxocycloalkyl group formed together with the adjacent —CHCO— and the divalent acyclic hydrocarbon group include a 2-oxocyclopentyl group and a 2-oxocyclohexyl group.

Examples of the cation (IXz) include the followings:

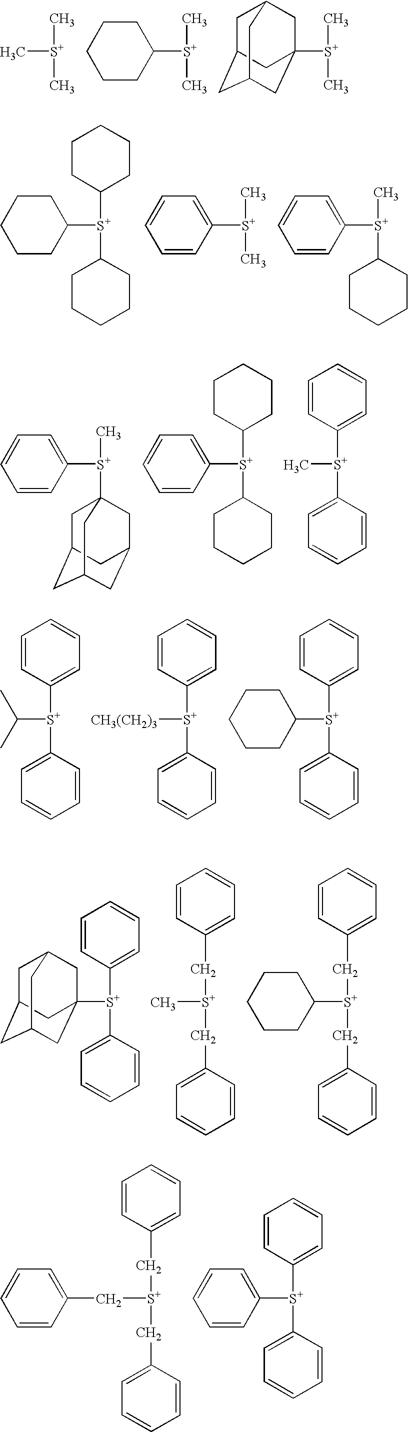

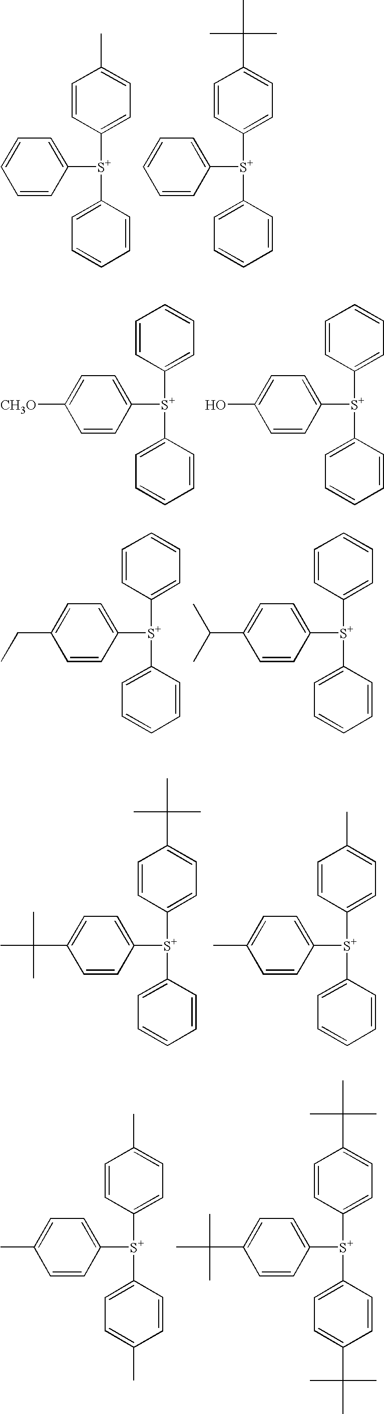

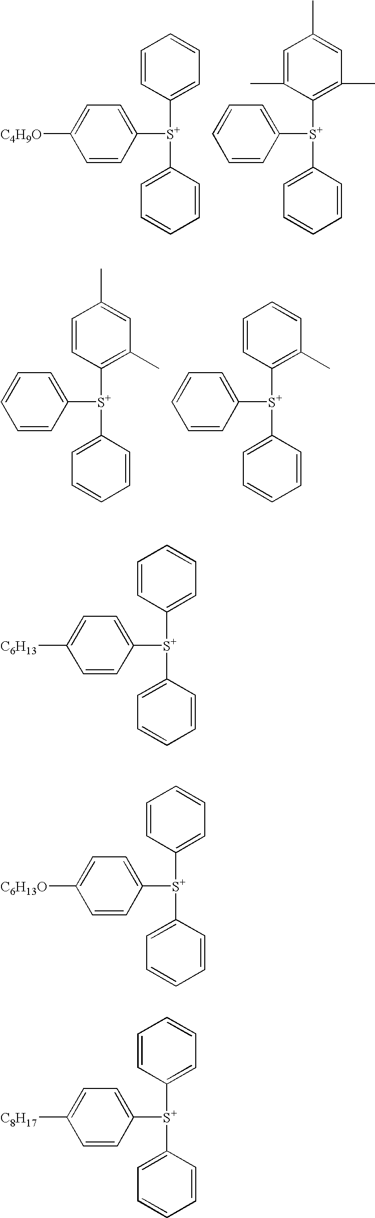

Specific examples of the cation (IXb) include the following:

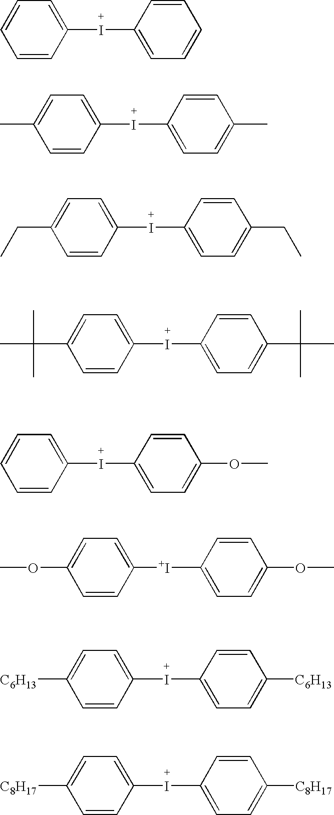

Specific examples of the cation (IXc) include the following:

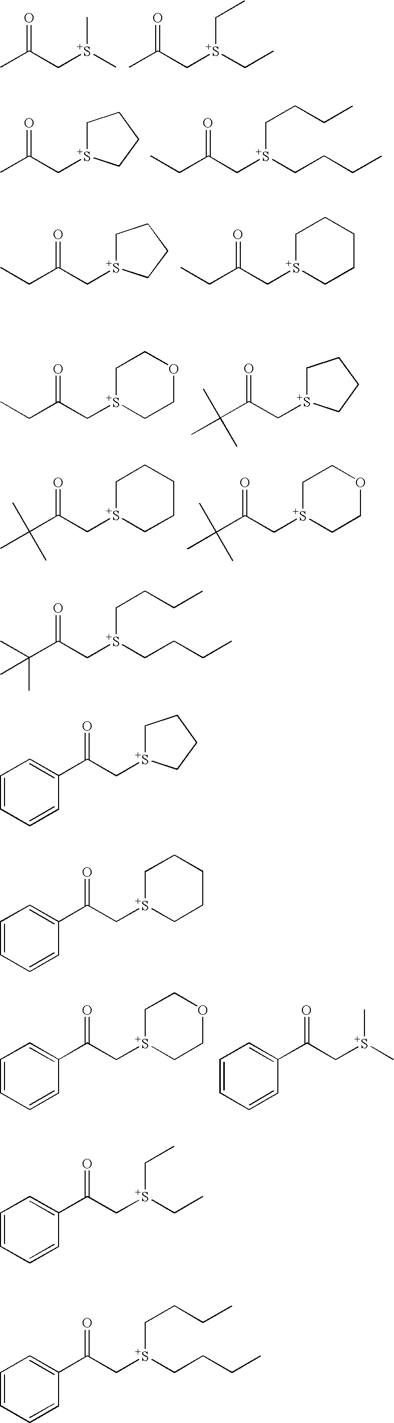

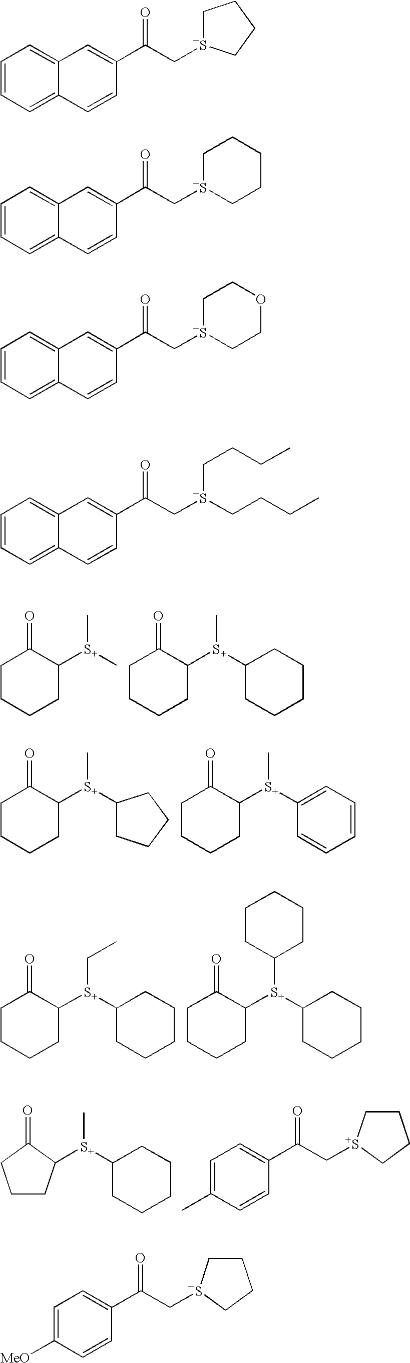

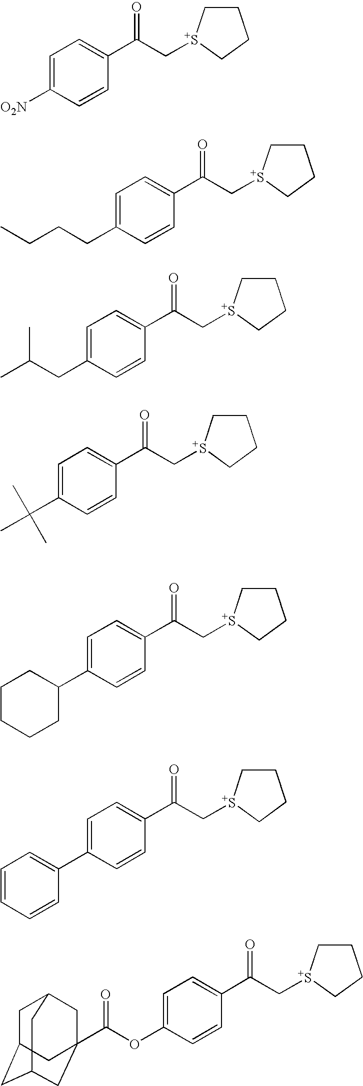

Specific examples of the cation (IXd) include the following:

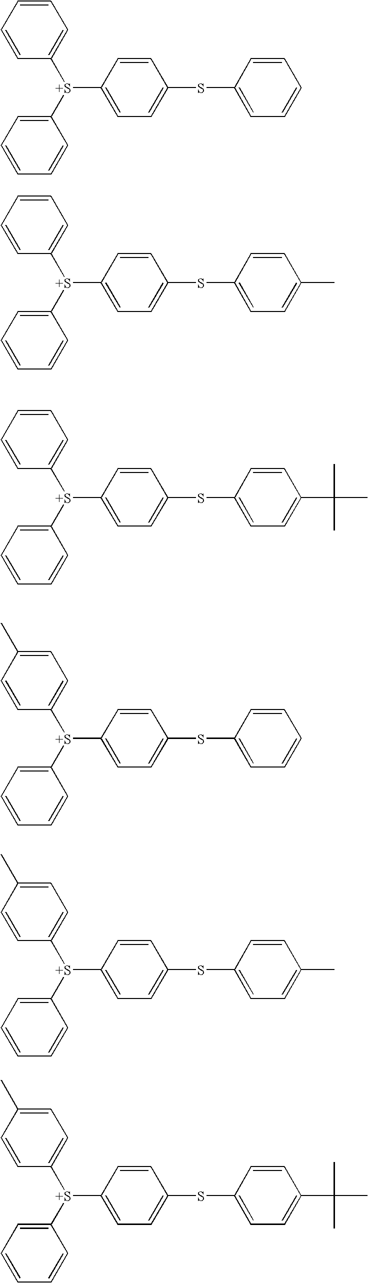

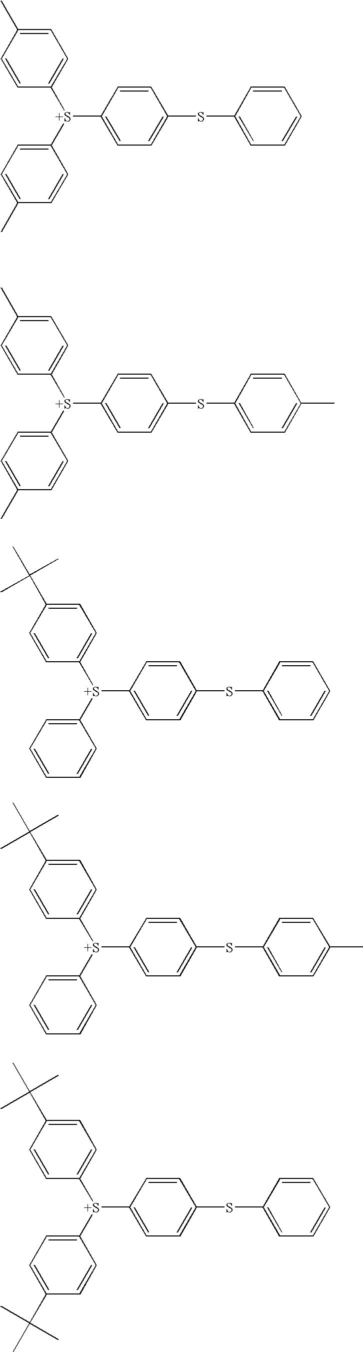

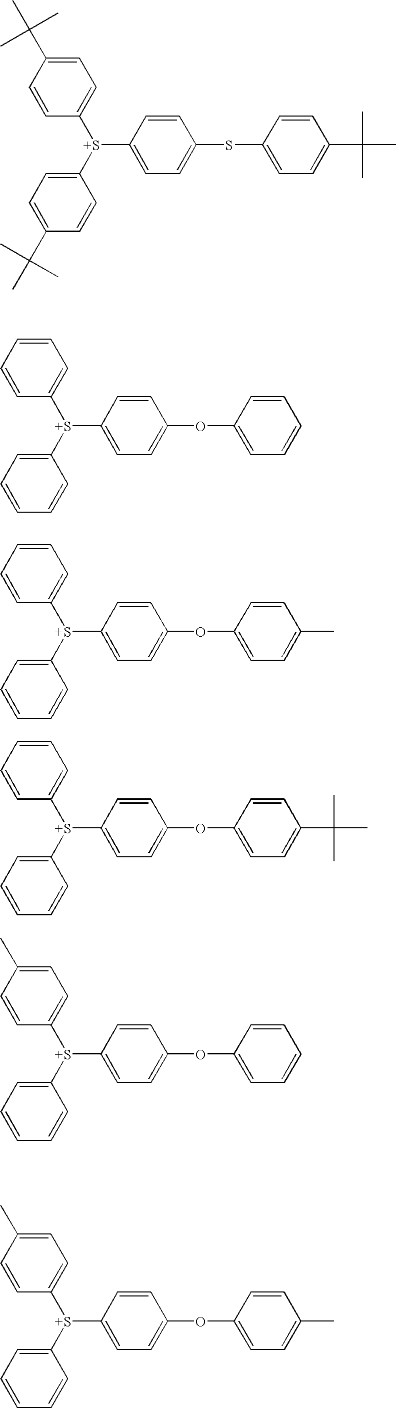

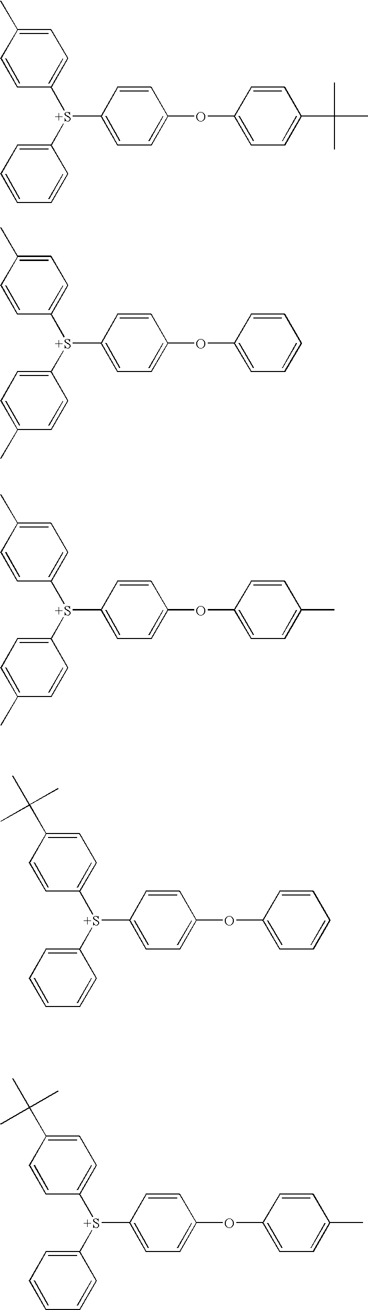

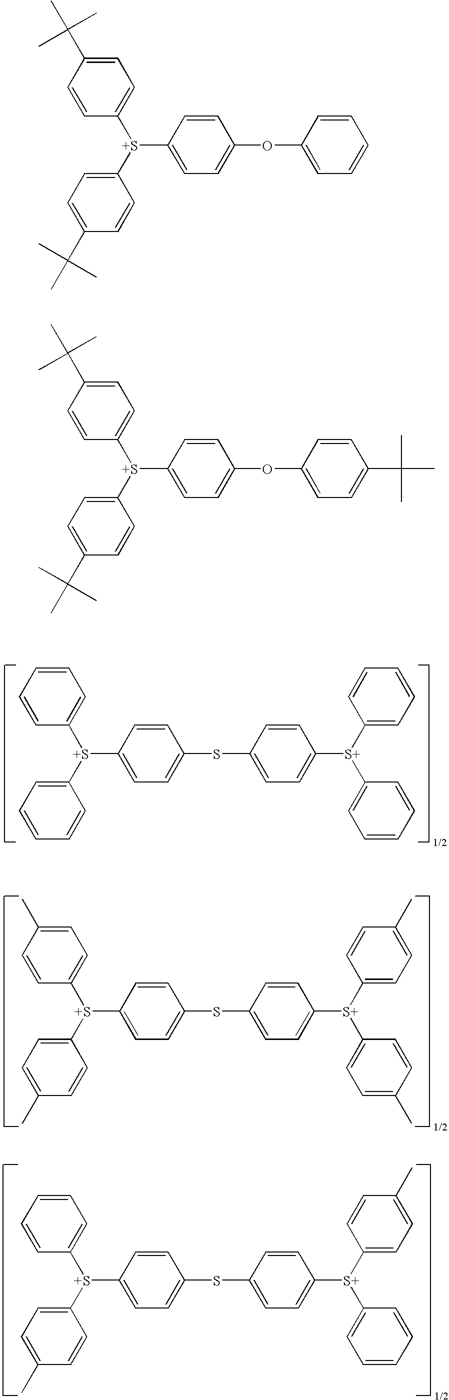

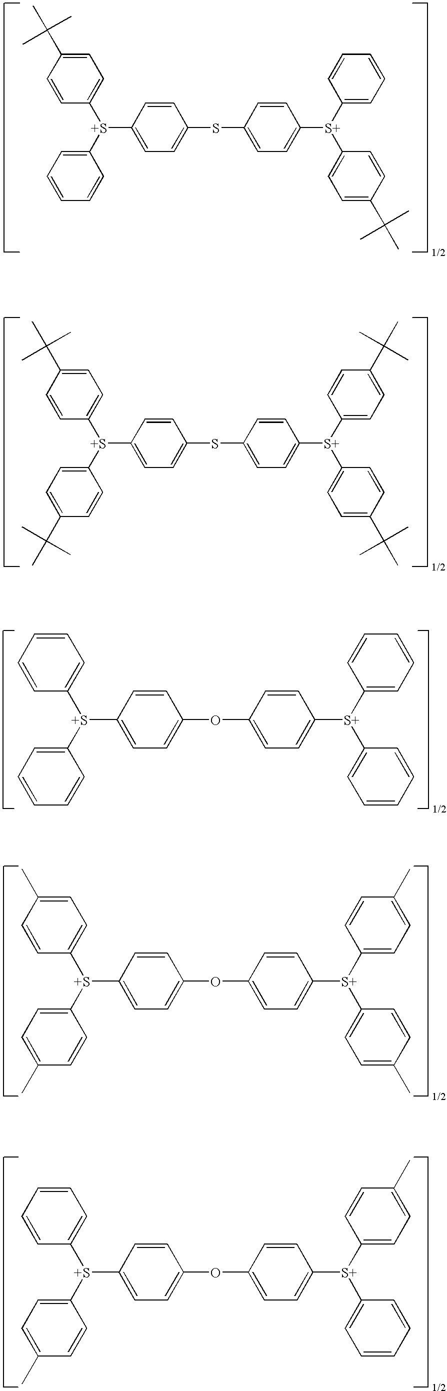

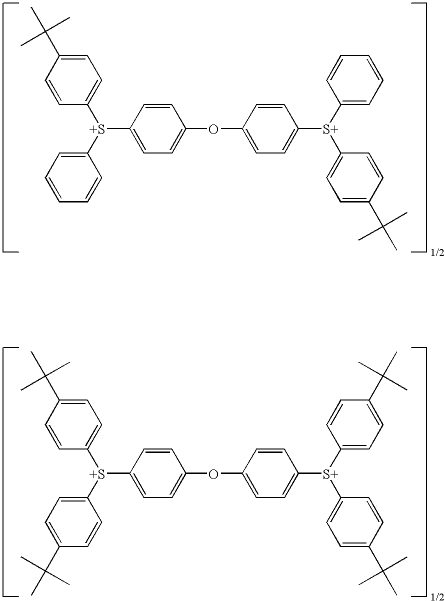

Among the cation (IXz), the cation represented by the formula (IXa):

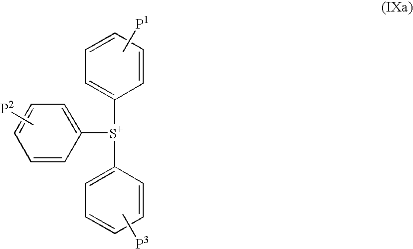

wherein P¹, P² and P³ each independently represent a hydrogen atom, a hydroxyl group, a C1-C12 linear or branched chain alkyl group or a C1-C12 linear or branched chain alkoxy group, is preferable. Examples of the C1-C12 linear or branched chain alkyl group and the C1-C12 linear or branched chain alkoxy group include the same as described above.

As the organic counter ion represented by A⁺, a cation represented by the following formulae (IXe):

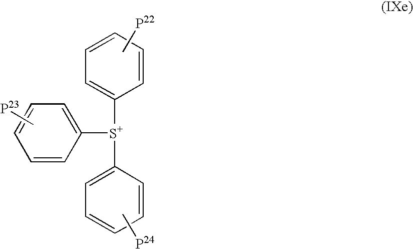

wherein P²², P²³ and P²⁴ each independently represent a hydrogen atom or a C1-C4 alkyl group, is also preferable.

As the Salt (VI), a salt wherein A⁺ is the cation represented by the following formulae (IXe) and the anion part is the following:

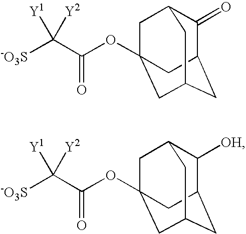

and
a salt wherein A⁺ is the cation represented by the following formulae (IXc) and the anion part is the following:

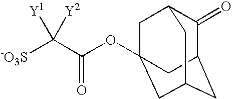

are preferable.

Salt (VI) can be produced according to known methods such as a method described in JP 2007-249192 A1.

In the present resist composition, the weight ratio of the resin (A) and the polyhydric phenol compound (1) to the acid generator (the resin (A) and the polyhydric phenol compound (1)/the acid generator) is preferably 99.9/0.1 to 60/40.

The resist composition of the present invention may further contain the compound (3).

In the present resist composition, performance deterioration caused by inactivation of acid which occurs due to post exposure delay can be diminished by adding an organic base compound, particularly a nitrogen-containing organic base compound as a quencher. The present resist composition may contain two or more kinds of organic base compounds.

Specific examples of the nitrogen-containing organic base compound include an amine compound represented by the following formulae:

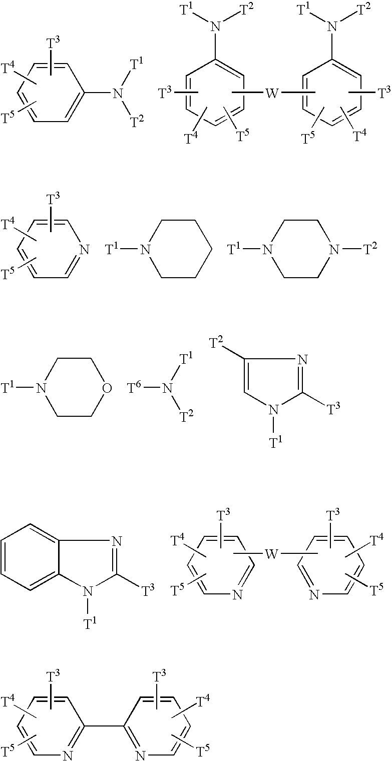

wherein T¹ and T² each independently represent a hydrogen atom, an alkyl group, a cycloalkyl group or an aryl group, and the alkyl, cycloalkyl and aryl groups may have one or more substituents selected from the group consisting of a hydroxyl group, an amino group which have one or two C1-C4 alkyl groups and a C1-C6 alkoxy group,
T³ and T⁴ each independently represent a hydrogen atom, an alkyl group, a cycloalkyl group, an aryl group or an alkoxy group, and the alkyl, cycloalkyl, aryl and alkoxy groups may have one or more substituents selected from the group consisting of a hydroxyl group, an amino group which may have one or more C1-C4 alkyl groups and a C1-C6 alkoxy group, or T³ and T⁴ are bonded each other to form an aromatic ring together with the carbon atoms to which they are bonded,
T⁵ represents a hydrogen atom, an alkyl group, a cycloalkyl group, an aryl group, an alkoxy group or a nitro group, and the alkyl, cycloalkyl, aryl and alkoxy groups may have one or more substituents selected from the group consisting of a hydroxyl group, an amino group which may have one or two C1-C4 alkyl groups and a C1-C6 alkoxy group,
T⁶ represents an alkyl group or a cycloalkyl group, and the alkyl and cycloalkyl groups may have one or more substituents selected from the group consisting of a hydroxyl group, an amino group which may have one or two C1-C4 alkyl groups and a C1-C6 alkoxy group, and
W represents —CO—, —NH—, —S—, —S—S—, an alkylene group of which one or more —CH₂— may be replaced by —O—, or an alkenylene group of which one or more —CH₂— may be replaced by —O—, and a quaternary ammonium hydroxide represented by the following formula:

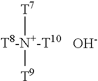

wherein T⁷, T⁸, T⁹ and T¹⁰ each independently represent an alkyl group, a cycloalkyl group or an aryl group, and the alkyl, cycloalkyl and aryl groups may have one or more substituents selected from the group consisting of a hydroxyl group, an amino group which may have one or two C1-C4 alkyl groups and a C1-C6 alkoxy group.

The alkyl group in T¹, T², T³, T⁴, T⁵, T⁶, T⁷, T⁸, T⁹ and T¹⁰ preferably has about 1 to 10 carbon atoms, and more preferably has about 1 to 6 carbon atoms.

Examples of the amino group which may have one or two C1-C4 alkyl groups include an amino group, a methylamino group, an ethylamino group, a butylamino group, a dimethylamino group and a diethylamino group. Examples of the C1-C6 alkoxy group which may be substituted with the C1-C6 alkoxy group or groups include a methoxy group, an ethoxy group, a propoxy group, an isopropoxy group, a butoxy group, a tert-butoxy group, a pentyloxy group, a hexyloxy group and a 2-methoxyethoxy group.

Specific examples of the alkyl group which may have one or more substituents selected from the group consisting of a hydroxyl group, an amino group which may have one or two C1-C4 alkyl groups, and a C1-C6 alkoxy group include a methyl group, an ethyl group, a propyl group, an isopropyl group, a butyl group, a tert-butyl group, a pentyl group, a hexyl group, an octyl group, a nonyl group, a decyl group, a 2-(2-methoxyethoxy)ethyl group, a 2-hydroxyethyl group, a 2-hydroxypropyl group, a 2-aminoethyl group, a 4-aminobutyl group and a 6-aminohexyl group.

The cycloalkyl group in T¹, T², T³, T⁴, T⁵, T⁶, T⁷, T⁸, T⁹ and T¹⁰ preferably has about 5 to 10 carbon atoms. Specific examples of the cycloalkyl group which may have one or more substituents selected from the group consisting of a hydroxyl group, an amino group which may have one or two C1-C4 alkyl groups and a C1-C6 alkoxy group include a cyclopentyl group, a cyclohexyl group, a cycloheptyl group and a cyclooctyl group.

The aryl group in T¹, T², T³, T⁴, T⁵, T⁶, T⁷, T⁸, T⁹ and T¹⁰ preferably has about 6 to 10 carbon atoms. Specific examples of the aryl group which may have one or more substituents selected from the group consisting of a hydroxyl group, an amino group which may have one or two C1-C4 alkyl groups and a C1-C6 alkoxy group include a phenyl group and a naphthyl group.

The alkoxy group in T³, T⁴ and T⁵ preferably has about 1 to 6 carbon atoms and specific examples thereof include a methoxy group, an ethoxy group, a propoxy group, an isopropoxy group, a butoxy group, a tert-butoxy group, a pentyloxy group and a hexyloxy group.

The alkylene and alkenylene groups in W preferably have 2 to 6 carbon atoms. Specific examples of the alkylene group include an ethylene group, a trimethylene group, a tetramethylene group, a methylenedioxy group and an ethylene-1,2-dioxy group, and specific examples of the alkenylene group include an ethene-1,2-diyl group, a 1-propene-1,3-diyl group and a 2-butene-1,4-diyl group.

Specific examples of the amine compound include hexylamine, heptylamine, octylamine, nonylamine, decylamine, aniline, 2-methylaniline, 3-methylaniline, 4-methylaniline, 4-nitroaniline, tetramethylenediamine, hexamethylenediamine, 4,4′-diamino-1,2-diphenylethane, 4,4′-diamino-3,3′-dimethyldiphenylmethane, 4,4′-diamino-3,3′-diethyldiphenylmethane, dibutylamine, dipentylamine, dihexylamine, diheptylamine, dioctylamine, dinonylamine, didecylamine, N-methylaniline, piperidine, diphenylamine, triethylamine, trimethylamine, tripropylamine, tributylamine, tripentylamine, trihexylamine, triheptylamine, trioctylamine, trinonylamine, tridecylamine, methyldibutylamine, methyldipentylamine, methyldihexylamine, methyldicyclohexylamine, methyldiheptylamine, methyldioctylamine, methyldinonylamine, methyldidecylamine, ethyldibutylamine, ethyldipentylamine, ethyldihexylamine, ethyldiheptylamine, ethyldioctylamine, ethyldinonylamine, ethyldidecylamine, dicyclohexylmethylamine, tris[2-(2-methoxyethoxy)ethyl]amine, triisopropanolamine, N,N-dimethylaniline, 2,6-diisopropylaniline, imidazole, benzimidazole, pyridine, 4-methylpyridine, 4-methylimidazole, bipyridine, 2,2′-dipyridylamine, di-2-pyridyl ketone, 1,2-di(2-pyridyl)ethane, 1,2-di(4-pyridyl)ethane, 1,3-di(4-pyridyl)propane, 1,2-bis(2-pyridyl)ethylene, 1,2-bis(4-pyridyl)ethylene, 1,2-bis(4-pyridyloxy)ethane, 4,4′-dipyridyl sulfide, 4,4′-dipyridyl disulfide, 1,2-bis(4-pyridyl)ethylene, 2,2′-dipicolylamine and 3,3′-dipicolylamine.

Examples of the quaternary ammonium hydroxide include tetramethylammonium hydroxide, tetraisopropylammonium hydroxide, tetrabutylammonium hydroxide, tetrahexylammonium hydroxide, tetraoctylammonium hydroxide, phenyltrimethylammonium hydroxide, (3-trifluoromethylphenyl)trimethylammonium hydroxide and (2-hydroxyethyl)trimethylammonium hydroxide (so-called “choline”).

A hindered amine compound having a piperidine skeleton as disclosed in JP 11-52575 A1 can be also used as the quencher.

In the point of forming patterns having higher resolution, the quaternary ammonium hydroxide is preferably used as the quencher.

When the basic compound is used as the quencher, the present resist composition preferably includes 0.01 to 1% by weight of the basic compound based on the total amount of the resin (A), the polyhydric phenol compound and the acid generator.

The present resist composition can contain, if necessary, a small amount of various additives such as a sensitizer, a dissolution inhibitor, other polymers, a surfactant, a stabilizer and a dye as long as the effect of the present invention is not prevented.

The present resist composition is usually in the form of a resist liquid composition in which the above-mentioned ingredients are dissolved in a solvent and the resist liquid composition is applied onto a substrate such as a silicon wafer by a conventional process such as spin coating. The solvent used is sufficient to dissolve the above-mentioned ingredients, have an adequate drying rate, and give a uniform and smooth coat after evaporation of the solvent. Solvents generally used in the art can be used.

Examples of the solvent include a glycol ether ester such as ethyl cellosolve acetate, methyl cellosolve acetate and propylene glycol monomethyl ether acetate; a glycol ether such as propylene glycol monomethyl ether; an acyclic ester such as ethyl lactate, butyl acetate, amyl acetate and ethyl pyruvate; a ketone such as acetone, methyl isobutyl ketone, 2-heptanone and cyclohexanone; and a cyclic ester such as γ-butyrolactone. These solvents may be used alone and two or more thereof may be mixed to use.

A resist film applied onto the substrate and then dried is subjected to exposure for patterning, then heat-treated to facilitate a deblocking reaction, and thereafter developed with an alkali developer. The alkali developer used may be any one of various alkaline aqueous solution used in the art. Generally, an aqueous solution of tetramethylammonium hydroxide or (2-hydroxyethyl)trimethylammonium hydroxide (commonly known as “choline”) is often used.

It should be construed that embodiments disclosed here are examples in all aspects and not restrictive. It is intended that the scope of the present invention is determined not by the above descriptions but by appended claims, and includes all variations of the equivalent meanings and ranges to the claims.

The present invention will be described more specifically by way of examples, which are not construed to limit the scope of the present invention. The “%” and “part(s)” used to represent the content of any component and the amount of any material used in the following examples and comparative examples are on a weight basis unless otherwise specifically noted. The weight-average molecular weight of any material used in the following examples is a value found by gel permeation chromatography using polystyrene as a standard reference material.

Monomers used in the following Synthetic Examples are following monomers A, B, C, D and E.

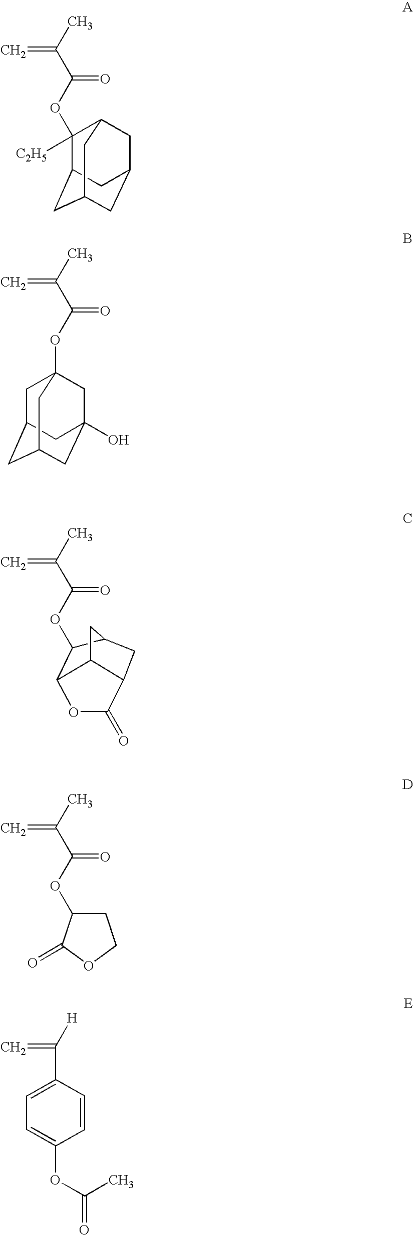

### Synthetic Example 1

Into a flask, 15.00 g of monomer A, 4.89 g of monomer B, 11.12 g of monomer C and 8.81 g of monomer D were added (monomer ratio; monomer A:monomer B:monomer C:monomer D=35:12:23:30) and 1.5 times amount of 1,4-dioxane as much as the amount of all monomers to be used was added thereto to prepare a solution. To the solution, 2,2′-azobisisobutyronitrile and 2,2′-azobis(2,4-dimethylvaleronitrile) was added as an initiator in a ratio of 1 mol % and 3 mol % respectively based on all monomer molar amount, and the resultant mixture was heated at 77° C. for about 5 hours. The reaction solution was poured into a large amount of mixture of water and methanol to cause precipitation. The precipitate was isolated and dissolved in 1,4-dioxane. The solution was poured into a large amount of mixture of water and methanol to cause precipitation. The precipitate was isolated. The operation wherein the precipitate was isolated and dissolved in 1,4-dioxane to obtain a solution, and the solution was poured into with a large amount of mixture of water and methanol to cause precipitation, and the precipitate was isolated was repeated twice. As a result, resin having a weight-average molecular weight of about 8,100 was obtained in a yield of 78%. This resin had the following structural units. This is called as Resin A1.

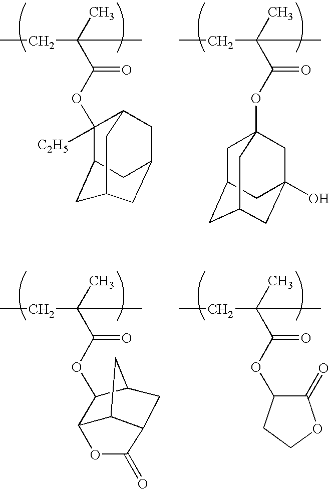

### Synthetic Example 2

Into a flask, 39.7 g of monomer A, 103.8 g of monomer E and 265 g of isopropanol were charged to prepare a solution. The solution was heated to 75° C. under a nitrogen atmosphere. To the solution, a solution prepared by dissolving 11.05 g of 2,2′-azobis(2-methylpropionate) in 22.11 g of 1,4-dioxane was added dropwise. The resultant mixture was stirred for 12 hours under reflux. The reaction mixture was cooled and then, was poured into a large amount of methanol to cause precipitation. The precipitate was isolated by filtration to obtain 250 g of a copolymer including methanol.

The obtained copolymer was mixed with 10.3 g of 4-dimethylaminopyridine and 202 g of methanol and the resultant mixture was refluxed for 20 hours. The reaction mixture was cooled and then, was neutralized with 7.6 g of glacial acetic acid. The resultant mixture was poured into a large amount of water to cause precipitation. The precipitate was isolated by filtration and dissolved in acetone. The solution was poured into a large amount of water to cause precipitation. The precipitate was isolated by filtration. The operation wherein the precipitate was dissolved in acetone, the solution was poured into a large amount of water to cause precipitation and then, the precipitate was isolated by filtration was repeated two times to obtain 95.9 g of a resin having a weight-average molecular weight of about 8,600. This resin had the following structural units, and a molar ratio of the structural unit derived from monomer A to the structural unit derived from p-hydroxystyrene (the structural unit derived from monomer A/the structural unit derived from p-hydroxystyrene) was analyzed with ¹³C-NMR and it was about 20/80. This is called as Resin B1.

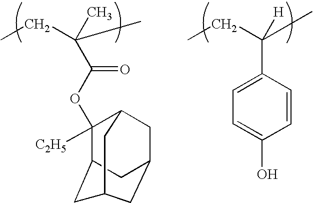

### Synthetic Example 3

One hundred two point eight grams of a copolymer having a weight-average molecular weight of about 8,200 was obtained according to the same manner as that of Resin Synthetic Example 2, except that 59.6 g of monomer A and 90.8 g of monomer E were used in place of 39.7 g of monomer A and 103.8 g of monomer E. This resin had the following structural units, and a molar ratio of the structural unit derived from monomer A to the structural unit derived from p-hydroxystyrene (the structural unit derived from monomer A/the structural unit derived from p-hydroxystyrene) was analyzed with ¹³C-NMR and it was about 30/70. This is called as Resin B2.

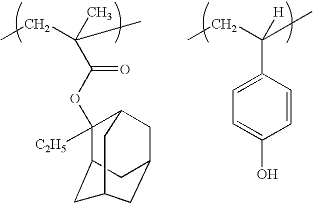

### Synthetic Example 4

Ten grams of 2,6-bis[4-hydroxy-3-(2-hydroxy-5-methylbenzyl)-2,5-dimethylbenz yl]-4-methylphenol (hereinafter, simply referred to as M2) was dissolved in 100 g of N,N-dimethylformamide. To the resultant solution, 6.8 g of potassium carbonate was added. To the obtained mixture, a solution obtained by mixing 7.9 g of 2-methyl-2-adamantyl chloroacetate with 40 g of N,N-dimethylformamide was added dropwise below 50° C. To the obtained mixture, 0.6 g of potassium iodide was added, and the resultant mixture was stirred at 50° C. for 5 hours. The reaction mixture was cooled, diluted with 1% aqueous oxalic acid solution and then extracted with ethyl acetate. The organic layer obtained was mixed with magnesium sulfate and activated carbon to dry and decolorize. The mixture obtained was filtrated and the filtrate obtained was concentrated to obtain 15.3 g of brown solid, which is called as M1. Yield: 92%.

M1 was analyzed by liquid chromatography to find that three polyhydric phenol compounds represented by the following formulae (a) to (c):

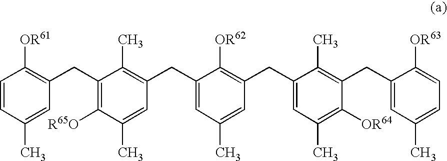

wherein any one of R⁶¹, R⁶², R⁶³, R⁶⁴ and R⁶⁵ is the following group:

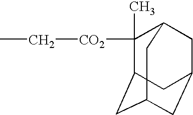

and the other four groups are hydrogen atoms (hereinafter, simply referred to as COMPOUND (a)),

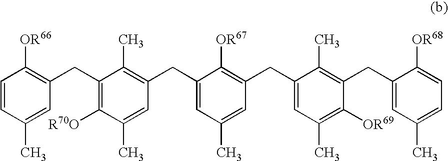

wherein any two of R⁶⁶, R⁶⁷, R⁶⁸, R⁶⁹ and R⁷⁰ are the following groups:

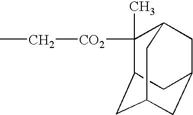

and the other three groups are hydrogen atoms (hereinafter, simply referred to as COMPOUND (b)),

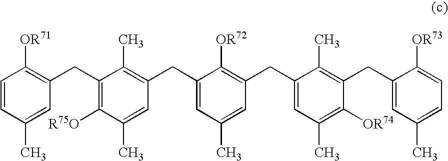

wherein any three of R⁷¹, R⁷², R⁷³, R⁷⁴ and R⁷⁵ are the following groups:

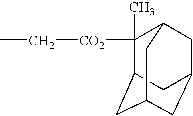

and the other two groups are hydrogen atoms (hereinafter, simply referred to as COMPOUND (c)) were contained in M1.

The content ratio of COMPOUND (a), COMPOUND (b) and COMPOUND (c) in M1 (COMPOUND (a)/COMPOUND (b)/COMPOUND (c)) is 4/92/4. Herein, “the content ratio” means a ratio of values of each compounds calculated by a liquid chromatography area percentage method. Liquid chromatography mass spectroscopy;

COMPOUND (a): [M+K]⁺=861.4 (M⁺=822.45)

COMPOUND (b): [M+K]⁺=1067.4 (M⁺=1028.58)

COMPOUND (c): [M+K]⁺=1273.6 (M⁺=1234.71)

### Examples 1 to 4 and Comparative Examples 1 and 2

| <Acid generator> | | |
|---|---|---|
| Acid generator P1: triphenylsulfonium | | |
| 4-oxo-1-adamantyloxycarbonyl- | | |
| difluoromethanesulfonate | | |
| <Resin> | | |
| Resin A1 | | |
| Resin B1 | | |
| Resin B2 | | |
| <Polyhydric phenol compound> | | |
| M1 | | |
| <Quencher> | | |
| Q1: 2,6-diisopropylaniline | | |
| Q2: tetrabutylammonium hydroxide | | |
| <Others> | | |
| M2 | | |
| <Solvent> | | |
| S1: propylene glycol monomethyl ether acetate | 390 | parts |
| propylene glycol monomethyl ether | 60 | parts |
| γ-butyrolactone | 5 | parts |

The following components were mixed and dissolved, further, filtrated through a fluorine resin filter having pore diameter of 0.2 μm, to prepare resist liquid.

Resin (kind and amount (part) are described in Table 1)

Acid generator (kind and amount (part) are described in Table 1)

Polyhydric phenol compound (kind and amount (part) are described in Table 1)

Quencher (kind and amount (part) are described in Table 1)

Others (kind and amount (part) are described in Table 1)

Solvent (kind is described in Table 1)

TABLE 1

| | | Acid | | Polyhydric | | |
|---|---|---|---|---|---|---|
| | | gener- | | phenol | | |
| Ex. | Resin | ator (a- | Quencher | compound | Others | Sol- |
| No. | (amount) | mount) | (amount) | (amount) | (amount) | vent |
| Ex. 1 | A1 (5) | P1 (1.2) | Q1 (0.04) | M1 (2.5) | M2 (2.5) | S1 |
| | | | Q2 (0.01) | | | |
| Ex. 2 | A1 (2.5) | P1 (1.2) | Q1 (0.04) | M1 (5) | None | S1 |
| | B1 (1.25) | | Q2 (0.01) | | | |
| | B2 (1.25) | | | | | |
| Ex. 3 | A1 (2.5) | P1 (1.2) | Q1 (0.04) | M1 (2.5) | M2 (2.5) | S1 |
| | B1 (1.25) | | Q2 (0.01) | | | |
| | B2 (1.25) | | | | | |
| Ex. 4 | A1 (4.5) | P1 (1.2) | Q1 (0.04) | M1 (1) | None | S1 |
| | B2 (4.5) | | Q2 (0.01) | | | |
| Comp. | A1 (10) | P1 (1.2) | Q1 (0.04) | None | None | S1 |
| Ex. 1 | | | Q2 (0.01) | | | |
| Comp. | B1 (5) | P1 (1.2) | Q1 (0.04) | None | None | S1 |
| Ex. 2 | B2 (5) | | Q2 (0.01) | | | |

Silicon wafers were each contacted with hexamethyldisilazane at 90° C. for 60 seconds on a direct hotplate. Each of the resist compositions prepared as above was spin-coated over the wafers so that the thickness of the resulting film became 0.06 μm after drying. The silicon wafers thus coated with the respective resist compositions were each prebaked on a direct hotplate at 110° C. for 60 seconds. Using a writing electron beam lithography system (“HL-800D” manufactured by Hitachi, Ltd., 50 KeV), each wafer on which the respective resist film had been thus formed was exposed to a line and space pattern, while changing stepwise the exposure quantity.

After the exposure, each wafer was subjected to post-exposure baking on a hotplate at 100° C. for 60 seconds and then to paddle development for 60 seconds with an aqueous solution of 2.38 wt % tetramethylammonium hydroxide.

Each of a resist pattern developed on the organic anti-reflective coating substrate after the development was observed with a scanning electron microscope, the results of which are shown in Table 2.

Effective Sensitivity (ES): It was expressed as the amount of exposure that the line pattern and the space pattern become 1:1 after exposure through 0.10 μm line and space pattern mask and development.

Resolution: It is expressed as the minimum size of space pattern which gave the space pattern split by the line pattern at the exposure amount of the effective sensitivity.

Pattern Profile: The space pattern which gave a line and space pattern at the exposure amount of the effective sensitivity after conducting a lithography process were observed by a scanning electron microscope. When the cross-section shape of the pattern was rectangle, the pattern profile is good and its evaluation is marked by “◯”, and when the upper of the pattern was melted and the pattern became smaller, the pattern profile is bad and its evaluation is marked by “x”.

TABLE 2

| Ex. No. | ES (μC) | Resolution (nm) | Pattern Profile |
|---|---|---|---|
| Ex. 1 | 30 | 50 | ◯ |
| Ex. 2 | 34 | 50 | ◯ |
| Ex. 3 | 32 | 50 | ◯ |
| Ex. 4 | 44 | 50 | ◯ |
| Com. Ex. 1 | 48 | 70 | ◯ |
| Comp. Ex. 2 | 14 | 100 | X |

### Examples 5 and 6

| <Acid generator> | | |
|---|---|---|
| Acid generator P1: triphenylsulfonium | | |
| 4-oxo-1-adamantyloxycarbonyl- | | |
| difluoromethanesulfonate | | |
| <Resin> | | |
| Resin B1 | | |
| Resin B2 | | |
| <Polyhydric phenol compound> | | |
| M1 | | |
| <Quencher> | | |
| Q1: 2,6-diisopropylaniline | | |
| Q2: tetrabutylammonium hydroxide | | |
| <Solvent> | | |
| S2: propylene glycol monomethyl ether acetate | 250 | parts |
| propylene glycol monomethyl ether | 40 | parts |
| γ-butyrolactone | 5 | parts |

The following components were mixed and dissolved, further, filtrated through a fluorine resin filter having pore diameter of 0.2 μm, to prepare resist liquid.

Resin (kind and amount (part) are described in Table 3)

Acid generator (kind and amount (part) are described in Table 3)

Polyhydric phenol compound (kind and amount (part) are described in Table 3)_{.}

Quencher (kind and amount (part) are described in Table 3)

Solvent (kind is described in Table 3)

TABLE 3

| | | Acid | | Polyhydric | |
|---|---|---|---|---|---|
| Ex. | Resin | generator | Quencher | phenol compound | |
| No. | (amount) | (amount) | (amount) | (amount) | Solvent |
| Ex. 5 | B1 (2.5) | P1 (1.5) | Q1 (0.03) | M1 (5) | S2 |
| | B2 (2.5) | | Q2 (0.05) | | |
| Ex. 6 | B1 (0.8) | P1 (1.5) | Q1 (0.02) | M1 (2) | S2 |
| | B2 (7.2) | | Q2 (0.01) | | |

Silicon wafers were each contacted with hexamethyldisilazane at 90° C. for 60 seconds on a direct hotplate. Each of the resist compositions prepared as above was spin-coated over the wafers so that the thickness of the resulting film became 0.08 μm after drying. The silicon wafers thus coated with the respective resist compositions were each prebaked on a direct hotplate at a temperature shown in column “PB” of Table 4 for 60 seconds. Using an EUV exposure system, each wafer on which the respective resist film had been thus formed was exposed to a line and space pattern, while changing stepwise the exposure quantity.

After the exposure, each wafer was subjected to post-exposure baking on a hotplate at a temperature shown in column of “PEB” of Table 4 for 60 seconds and then to paddle development for 60 seconds with an aqueous solution of 2.38 wt % tetramethylammonium hydroxide.

Each of a resist pattern developed on the organic anti-reflective coating substrate after the development was observed with a scanning electron microscope, the results of which are shown in Table 4.

Effective Sensitivity (ES): It was expressed as the amount of exposure that the line pattern and the space pattern become 1:1 after exposure through 0.05 vm line and space pattern mask and development.

Resolution: It is expressed as the minimum size of space pattern which gave the space pattern split by the line pattern at the exposure amount of the effective sensitivity.

Pattern Profile: The space pattern which gave a line and space pattern at the exposure amount of the effective sensitivity after conducting a lithography process were observed by a scanning electron microscope. When the side wall surface of the pattern was smooth or gently undulated, LER is good and its evaluation is marked by “◯”, and when the side wall surface of the pattern was deeply undulated, LER is bad and its evaluation is marked by “x”.

TABLE 4

| | | | ES | Resolution | |
|---|---|---|---|---|---|
| Ex. No. | PB (° C.) | PEB (° C.) | (mJ/cm²) | (nm) | LER |
| Ex. 5 | 110 | 95 | 21 | 34 | ◯ |
| Ex. 6 | 110 | 105 | 12 | 35 | ◯ |

The present resist composition provides good resist pattern in resolution and pattern profile, and is especially suitable for extreme ultraviolet (EUV) lithography and electron beam lithography.

What is claimed is:

1. A resist composition comprising:
(A) a resin being insoluble or poorly soluble in an alkali aqueous solution but becoming soluble in an alkali aqueous solution by the action of an acid,
(B) a polyhydric phenol compound represented by the formula (1): 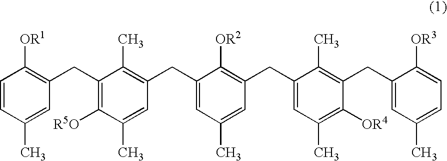
wherein at least one selected from the group consisting of R¹, R², R³, R⁴, and R⁵ is a group represented by the formula (2): 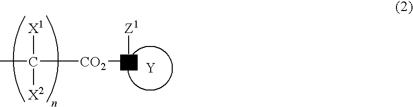
wherein X¹ and X² each independently represent a hydrogen atom or a C1-C4 alkyl group, n represents an integer of 1 to 4, Z¹ represents a C1-C6 alkyl group or a C3-C12 cycloalkyl group, and ring Y represents an alicyclic hydrocarbon group,
and the others are hydrogen atoms, and
(C) an acid generator.

2. The resist composition according to claim 1, wherein X¹ and X² represent hydrogen atoms and n is 1 in the formula (2).

3. The resist composition according to claim 1, wherein a weight ratio of the resin (A) to the polyhydric phenol compound represented by the formula (1) (the resin (A)/the polyhydric phenol compound represented by the formula (1)) is 1/99 to 99/1.

4. The resist composition according to claim 1, wherein a weight ratio of the resin (A) to the polyhydric phenol compound represented by the formula (1) (the resin (A)/the polyhydric phenol compound represented by the formula (1)) is 1/9 to 50/1.

5. The resist composition according to claim 1, wherein a weight ratio of the resin (A) to the polyhydric phenol compound represented by the formula (1) (the resin (A)/the polyhydric phenol compound represented by the formula (1)) is 1/1 to 9/1.

6. The resist composition according to claim 1, wherein the resin (A) is a resin (A1) comprising a structural unit having an acid-labile group in its side chain and a structural unit represented by the formula (1): 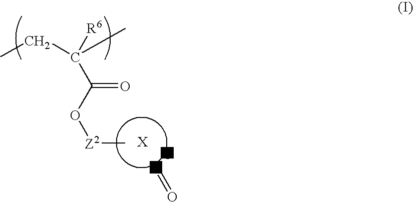
wherein R⁶ represents a hydrogen atom or a methyl group, Z² represents a single bond or —(CH₂)ₖ—CO—O—, k represents an integer of 1 to 4, and ring X represents an unsubstituted or substituted C3-C30 cyclic hydrocarbon group having —COO—.

7. The resist composition according to claim 1, wherein the resin (A) is a resin (A2) comprising a structural unit having an acid-labile group in its side chain and a structural unit represented by the formula (III): 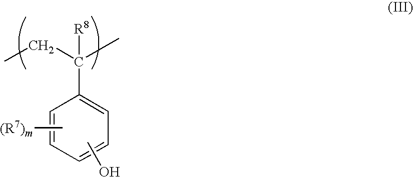
wherein R⁸ represents a hydrogen atom or a methyl group, R⁷ is independently in each occurrence a linear or branched chain C1-C6 alkyl group and m represents an integer of 0 to 4.

8. The resist composition according to claim 1, wherein the resin (A) contains the resin (A1) and the resin (A2).

9. The resist composition according to claim 8, wherein the weight ratio of the resin (A1) to the resin (A2) (the resin (A1)/the resin (A2)) is 1/10 to 10/1.

10. The resist composition according to claim 8, wherein the weight ratio of the resin (A1) to the resin (A2) (the resin (A1)/the resin (A2)) is 1/3 to 3/1.

11. The resist composition according to claim 1, wherein the molecular weight of the polyhydric phenol compound represented by the formula (I) is 730 to 5000.

12. The resist composition according to claim 1, wherein the composition contains at least two kinds of the polyhydric phenol compound represented by the formula (I).

13. The resist composition according to claim 1, wherein the composition further contains a compound represented by the formula (3):

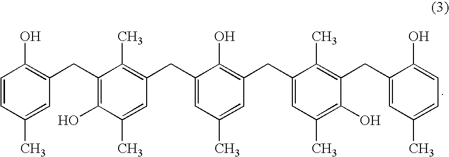

14. The resist composition according to claim 1, wherein the acid generator is a salt represented by the formula (V): 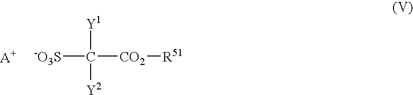
wherein A⁺ represents an organic counter ion, Y¹ and Y² each independently represent a fluorine atom or a C1-C6 perfluoroalkyl group, R⁵¹ represents a C1-C30 hydrocarbon group which may have one or more substituents selected from the group consisting of a C1-C6 alkoxy group, a C1-C4 perfluoroalkyl group, a C1-C6 hydroxyalkyl group, a hydroxyl group and a cyano group, and in which one or more —CH₂— may be replace by —CO— or —O—.

15. Use of the resist composition according to any one of claims 1 to 14 for extreme ultraviolet lithography or electron beam lithography.
